(19) United States
(12) Patent Application Publication
(10) Pub. No.: US 2014/0297206 A1
(43) Pub. Date: Oct. 2, 2014

(54) Universal Smart Energy Transformer Module

(71) Applicant: Lawrence Silverman, Newtown Square, PA (US)

(72) Inventor: Lawrence Silverman, Newtown Square, PA (US)

(73) Assignee: KASPAR LLC, Newtown Square, PA (US)

(21) Appl. No.: 13/853,050

(22) Filed: Mar. 28, 2013

(51) Int. Cl. G01R 31/02

(52) U.S. Cl. CPC G01R 31/027
USPC 702/58

(57) ABSTRACT

A universal smart energy transformer module (USETM) that uses an array of sensors to monitor and measure characteristics of the electrical power delivered and utilized at a location, along with other conditions in the area surrounding the location. The invention then uses the data from these sensors to determine the condition and performance of the transformer (for example, its input and output, power quality etc.) and also to identify any anomalies detected within the local power system that could threaten reliable electric supply on the electric grid, or pose a danger to people. A notification of such condition may be distributed using the secure, uninterruptible communications system.

### CROSS-REFERENCE TO RELATED APPLICATIONS

This application is related to U.S. application Ser. No. 12/471,553, filed May 26, 2009, entitled VARIABLE INCENTIVE AND VIRTUAL MARKET SYSTEM.

### COPYRIGHT NOTICE

Portions of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. The use of company names is for illustrative purposes only, and is not intended to express or convey any ownership in, license or rights to, the subject invention.

### TECHNICAL FIELD

This invention relates primarily to intelligent transformers used on a power distribution grid, particularly such intelligent transformers having self-monitoring, energy management, and communications functionality.

### BACKGROUND ART

In the field of electrical power distribution via a power grid, in which electricity is distributed to numerous customers (also referred to as end-users), various problems arise. One such problem is that of theft of services, in which electricity is used without payment to the utility company that provides the electricity. For example, in some areas of the world, it is not uncommon for persons to tap a power line that provides electricity from a distribution transformer to a paying customer of the utility, so that electricity is used without being accounted for by the meter at the premises of the paying customer.

In addition, there often exist situations in which conditions at or around a distribution transformer need to be monitored so that a repairman who is being dispatched to the area can be aware of the situation. For example, unsafe conditions may exist at the transformer, which must be conveyed to the repairman prior to dispatch.

Finally, there is a need to provide communications facilities to many areas of the world that do not have reasonable communications capabilities.

In a related endeavor, as explained in the '553 application, consumable resources such as electricity, water, natural gas, and oil are in limited supply throughout the world. Many efforts are undertaken to conserve these resources, such as fuel-efficient automobiles and so-called “green” or environmentally-friendly appliances, but there is no generalized system to measure, motivate and reward conservation efforts that can be applied universally, even though the failure to conserve has universal impact. Due to rising costs of these resources, limited supplies, increasing worldwide demand and a desire to preserve the environment, end-use customers are becoming aware of the need to modify their behaviors and conserve energy and other critical resources. However, end-use customers generally lack (a) information on their present, immediate past and predicted future resource consumption, (b) effective means to control and automate the interaction of the complex devices and systems in the resource networks and their interactions (c) timely feedback that reflects the results of modifying their behavior, and (d) a practical program of incentives to encourage actions in support of goals such as resource conservation and reduction of greenhouse gas emissions.

Present technologies do not enable end-use customers to ascertain their resource utilization on an immediate and timely basis and to use this information to intelligently and automatically manage the operation of their resource-consuming devices to meet customer goals locally while participating interactively with the larger community and with the resource provider to optimize the operation of the overall system. For example, in the field of electrical energy field, customers typically have an electric meter at the demarcation point between their residence and the electric grid (which meter is usually located inconveniently outside the customer's premise), that monitors the total amount of electricity consumed at that location over the course of a billing period (generally one month). The customer has no conveniently available access to timely information that can easily and automatically be set-up to achieve a desired customer goals with minimal ongoing customer interaction (“set-it-and-forget-it”), no immediate feedback on the results of changes in operating behavior, no means to implement an effective conservation strategy, and little or no incentive to encourage such behavior.

It is particularly difficult to manage resource conservation in today's market environment, since there are many complex and often inter-related variables that are involved and contribute to the availability and cost of a resource at any given moment, such as the cost of the fuel used in the production of the resource, the market price of the resource at the production or wholesale level, weather conditions that would affect resource usage, resource demand in different parts of the network, transmission constraints between locations on the network, outages at production or delivery facilities, losses due to needed maintenance on the resource network, etc.

In addition, resource markets (such as the electricity markets), and the providers (such as the large Investor-Owned Utilities or “IOUs”) that serve the majority of customers (particularly classes of customers such as residential consumers and small commercial users), are often highly regulated, with the result that customer pricing models and rate structures may not be easily or flexibly be changed without difficult and time-consuming regulatory submissions. These submissions may not necessarily result in approval, due to political and economic influences from outside the industry itself, and they may disproportionately serve the interests of the utilities/providers at the expense of customers, and in conflict with the larger goals of the community or the nation. Thus, the opportunity to make desired modifications in resource utilization, that would result in consequent improvements in the operational efficiency, economy or reliability of the resource system, may be lost to both the customer and the provider. For example, in the case of electricity, even though the cost for a given utility to provide electricity to a customer may be much higher at one time than another (because of increased demand, high fuel cost, unavailability of supply, or a range of other factors influencing cost), the regulatory body that oversees and must approve the rates charged by that utility to its customers may not allow the utility to charge customer rates that vary with the actual cost (these variable rates are sometimes referred to as “Time of Use” or “TOU” rates, “Hourly rates”, “day-ahead rates”, “interval rates” or similar terms). Regulatory filings to amend rates and other market factors are time-consuming processes that take place over periods of months, are expensive, and may require significant involvement by large numbers of staff, lobbyists, attorneys and witnesses, and deferral of investment in the system due to uncertainty about the regulatory treatment of those investments may result in large losses in the interim. Thus, the utility and/or resource provider is unable to provide a “natural” market-based incentive (i.e. based on market dynamics that transparently reflect the interaction between supply and demand), in the way that time-variant pricing reflects the actual changing cost of the resource. In this example, the electricity resource provider is thus unable to encourage and reward a customer to operate an electricity-consuming device at one time (when the supplier's electricity cost is low) rather than at another (when that cost is higher). Similarly, the customer is denied the advantage of a financial incentive or reward for changing their schedule of use to take advantage of a variation in price or other economic or other incentive. This distorts the economics and operations of the system, and may consequently result in undue strain on system devices and components, reduced reliability, waste of the resource itself, and other undesirable conditions on the resource network or the environment. For example, a customer on a flat-rate regulated pricing structure, who turns off an air conditioner at night in the summer, may realize the same dollar savings as he would by turning it off during the peak-use period on a hot afternoon, even though the cost of electricity at low-demand nighttime hours is relatively much lower than at peak-demand afternoon hours.

Thus, under a flat-rate pricing scheme, there is no practical method to provide an effective and flexible pricing incentive for a customer to shift the air-conditioning use from a high-cost/high-demand period to a lower one, or to implement a “pre-cooling” strategy whereby the temperature is lowered beyond the customer's normal setting during an earlier period of lower-cost/lower-demand, and the air-conditioning use is then reduced when the customer enters the period of higher-cost/higher-demand, but comfort is maintained for a longer time interval, since the actual temperature will drift upward from the lower “pre-cool temperature” to the originally-desired temperature over a period of time.

One method of the present invention to achieve optimal operating efficiency is to develop an individual “thermal profile” of each air-conditioned zone by switching the compressor or a/c unit off and on at different intervals and inside/outside temperature differentials, observing the temperature rise time in each instance, and using that data to calculate and implement the optimal operating procedure under the corresponding conditions—including conditions locally, on the grid and in the market. As the system accumulates more data under different conditions, it becomes “smarter” and is able to continually improve optimization over time. It is also able to measure sudden changes in operation that may indicate a need for service, and notify the customer and/or a service agency.

The (psychophysical) feeling of comfort can be further maintained by keeping the fans on the air-conditioner operating (consuming little power), while the compressors are switched off or cycled. The problem is to provide a flexible, timely and widely-applicable incentive system that will encourage such behavior where the existing market and pricing system is unable to do so. The award of variable incentive points acts as an indicator of the overall value of a specific behavior by the individual and the aggregated community, evaluated across all system participants.

It is therefore an object of the present invention to provide a method and system to incentivize the conservation of any consumable resource. The method and system is intended to provide variable incentives that directly and positively impact (a) the ongoing operations of the elements of the resource network itself, and (b) the related resource markets and their derivative markets, in a more immediate and actionable manner than is presently possible, in order to better manage and coordinate the interdependent needs and requirements of the resource generator and supplier, the resource network itself, the devices operating on the resource network, the customer and/or groups of customers, and the environment. The present invention further provides a method for aggregating customers and creating a “market” (in this case, a market that is conservation-oriented) that will overlay on top of the existing market and pricing system. The present invention provides an incentive-based system that will flexibly and accurately reflect, encourage and reward the economic and societal value of certain behaviors (e.g. conservation), and create an “incentive market” based on points, that enables the goals of providers (utilities), consumers and society to be converged, and the benefits of achieving such goals to be shared among the participants. This may be accomplished independent of the state of the existing underlying regulatory or rate structure then in effect.

Even time-variant rate structures, such as TOU and Day-ahead hourly rates, etc., do not provide continuously-variable rate incentives, and typically incentivize meeting the goals of utilities (generally “Demand Response” or peak reduction during approximately 80 hours in a given year) but fail to address the goals of most consumers (typically overall “Conservation” or savings 24×7 throughout the year).

The objective is to create a solution (a Variable Incentive Points Program or “Resource Points Program”) comprised of inter-operating hardware, software, communications and applications, that (a) is compatible with existing resource networks, (b) operates within the bounds of the various regulatory constraints and market conditions affecting that network, and (c) has the capability to incentivize (reward or penalize) behaviors by participants in the resource network that tend to achieve goals established by the administrators of the Resource Points Program and by the participants themselves. In general, the invention is aimed at creating Variable Incentive Points Programs to incentivize conservation of particular resources, reduction of greenhouse gas emissions, and other goals which the existing devices and networks, industry and market structures, and regulatory procedures are unable to address.

It is an objective of the present invention to instruct users to establish a set of simple goals, or policies, that define the user's goals and priorities, and are designed to provide sufficient information for “set-it-and-forget it” operation of basic functions after that. Customer goals are used to configure operating algorithms that use parametric data in a database to manage, maintain and progressively improve the efficiency of the system and move the user towards their goals. A simple graphic interface, available on a range of display devices (such as cellphones, TVs, Computers, thermostat displays or other information display devices) informs each user how they are doing towards achieving their goals, and shows how much they are saving, how much they are reducing their individual carbon footprint, and how they are contributing to creating a “green community”. The points system is designed to provide an additional set of consumer incentives that can be used to further influence system operation, and to provide consumers with concrete rewards that provide specific targets to direct the operation of the system and reinforce the value of the results achieved.

It is a further object of the invention to provide such a method and system that enables detailed, specific and timely monitoring and control of the utilization of resources by the suppliers and customers, and manages their interactions in a participatory network that incentivizes participants to implement specific behaviors, such as those that favor increased conservation of scarce consumable resources, reduction of greenhouse gas and carbon emissions, general improvement in the efficiency and reliability of the resource delivery network, and other individually, economically and socially desirable goals.

It is a further object of the invention to provide an incentive for such conservation measures in the form of variable credits or reward points that are awarded to the participants (and in particular, individuals or aggregated groups of customers) for carrying out certain resource utilization behaviors, that may, for example, result in the conservation of that particular resource, and which points may be subsequently redeemed by the participants as desired.

The object is to influence participant behavior through a method that complements whatever prevailing price- or rate-structure that may be in place, in order to rapidly and flexibly implement a system of incentives that is based on immediate measurement, control and feedback, and that can motivate and reward behavior by participants that is favorable to the conservation or other goals of the Program.

The present invention includes a means to aggregate participants in a program, and a means for those participants to set both individual and collective goals, and to automate their local systems so as to operate in ways that achieve those goals.

It is a further objective of the present invention to aggregate end-users to implement collective energy and resource utilization strategies, for example those that result in conservation and reduction of greenhouse gas (carbon) emissions. It is a further objective of the present invention to provide an easily-understandable and objective system of incentive credits (points) and create exchanges for the future use, exchange and/or redemption of such credits (points).

The present invention also contemplates the use of data gathered about device performance to assess the operating efficiency and requirements for maintenance, to advise the customer, and further to provide the customer with links and other information for one or more repair facilities that can perform required service (thus providing an advertising opportunity within the platform). If the system is used by a supplier, this function may be employed to locate, notify and dispatch repair crews for remedial or preventive maintenance.

The present invention also contemplates a series of inter-operable Resource Conservation Incentive Points Programs in different locations and applying to different resources, that may reflect differences between various geographic regions such as local availability of the resource, ability to deliver the resource from outside the location, and other differentiating factors, as determined by the Administrator for that specific Points Program. The subject invention also contemplates a “Points Exchange” that will be established to manage the interchange and exchange of points between and among the various Points Programs, to create an overall inter-market exchange for points trading or redemption.

### SUMMARY OF THE INVENTION

In a first major aspect of the invention, provided is a universal smart energy transformer module (USETM), also referred to herein interchangeably as a master meter and communications center (MMCC). Three major embodiments of the transformer are provided; a pole mounted transformer that is mounted above ground (i.e. on a utility pole), a vault-mounted transformer that is located underground, and a pad mounted transformer that is mounted above ground (but not on a utility pole). Although each of these operating environments may have differing requirements, the present invention contemplates a single universal transformer monitor that may be used to satisfy the objectives for each embodiment. In addition, it may be applied to transformers located in power supplies inside of individual pieces of equipment connected to the electric grid, such as computers, ATM machines and the like.

One aspect of thr present invention is the use by an electric utility to detect and locate “theft of service”. The universal smart energy transformer module of the present invention implements the ability to determine energy that is being misappropriated without payment, by monitoring power that is output by the transformer, receiving energy meter usage data from each of the users to whom power is being distributed, comparing the total amount of energy meter usage data received from all of the users to the measured power output, and determining the misappropriated energy from the results of the comparison.

The universal smart energy transformer module of the present invention in another aspect provides for time-based load control of the energy being output (including “negative output” that represents a contribution from local renewable sources located on the user side of the transformer), by monitoring the energy being output at various times of the day, determining when the energy loads exceed a predetermined threshold for a given time period, and generating load control signals that are transmitted to selected end users premises that control selected energy consumption devices at the premises to reduce or eliminate the load at that premises for a predetermined time period. As a result, the transformer can control the total load placed on it by instructing various individual loads to shut down for certain time periods, thus reducing undesirable overloads and locally balancing supply with consumption.

The universal smart energy transformer module of the present invention in another aspect provides for controlling the energy (or “negative output”) that is being fed back into the power grid by distributed generation contributed by various end users, by monitoring various operating parameters of the transformer, analyzing if feed-in energy must be controlled as a result of those measurements, and controlling a transfer switch or control that allows or disallows energy to be fed back to the grid based on the results of that analysis.

The universal smart energy transformer module of the present invention in another aspect provides for implementation of various sensors (including sensors external to, mounted on or inside the transformer) to monitor local conditions such as case temperature, humidity, smoke, ozone, motion, vibration, battery charge and the like, information generated by probes inside the transformer, as well as a video and/or still camera. Additionally, various types of communications modules are provided for communicating to a central station the local conditions as determined by these sensors.

In a second major aspect, as discussed in the '553 patent application, disclosed herein is a method of and system to provide an incentive program for conserving a consumable resource such as electricity, natural gas, oil, or water, etc. The present invention includes a collection of hardware (including equipment already deployed on the existing resource systems as well as new equipment described herein), software, and applications that create an information and control network to monitor utilization of a resource at a location associated with a participant in the program, and then determines a quantity of a one or more types of “resource points” to be provided to an account associated with that participant. The type and quantity of these points are determined according to a set of “rules”, established by the program administrators, and embodied in a “rules engine” that performs calculations to determine the award of these points based on the behavior of that participant and other conditions as described herein. In general, these rules are based on an analysis of the monitored resource utilization with respect to a plurality of time-variant and location-variant parameters, and other such factors that the program administrator may designate. The type and quantity of points related to the utilization of the resource are defined by the program administrators, and are calculated according to a set of rules that establish the relationship (expressed mathematically as formulas and/or algorithms) between the parameters and the points to be awarded. This calculation is based on a set of overall “Resource Points Market” rules that are established by a “Program Administrator” and calculated and dispensed by a “Points Engine”, a system that executes mathematical calculations and algorithmic operations to determine the type and quantity of Resource Points to be awarded for a particular behavior at a particular time under a particular set of circumstances, based on information about the behavior of the particular Program participants with respect to goals established for the Program. The resource points are then stored in an account associated with the location or with a participant for future redemption.

Examples of rules that may be implemented to incentivize energy-conserving behavior include (but are not limited to) the following: (a) points resulting from actual changes in operating behaviors on the resource network, (b) points awarded as a result of an agreement between a supplier and a customer to implement certain resource utilization behaviors at a future time, and (c) points awarded with the purchase or installation of a device or product that has certain resource conservation and/or resource utilization characteristics.

In general, Program Rules are established that employ the award of (positive) points to provide an incentive for actions and utilization behavior favorable to an overall desired outcome, such as conservation of a resource, and/or to its reliable and efficient production, delivery, storage and/or use. Points may also be awarded to provide an incentive for utilization behavior that reduces harmful or detrimental effects on the resource delivery network, the surrounding environment, or participants in the resource conservation program or others, including non-participants, associated with or resulting (either directly or indirectly) from changes in Resource Utilization behavior by program participants (for example, reflecting the reduction in greenhouse gas emissions achieved by reduction of electricity use). Points may also be awarded as a result of the purchase and/or installation of resource utilization devices, where the quantity of points is a function of a device's efficiency, impact on the resource network, or on the environment (these may be referred to as “Resource Device Purchase Points”).

The present invention is a method to provide incentives through a program (a “Variable Incentive Program”) that encourages behavior to achieve certain complex goals, such as the improved management of utilization (production, transmission, transformation, storage or consumption) of a resource such as electricity, water, natural gas, oil and others, that result in the conservation of such a resource.

The present invention is a method to establish such a Program that can be independently implemented to supplement the regulatory or economic structures that may otherwise govern the provision and sale of a resource, particularly when such regulatory or economic structures are insufficient to provide practical incentives that encourage a desired behavior aimed at improving the utilization or conservation of such resource. This invention is a method to provide a variable incentive system that will define and compute a type and quantity (positive or negative) of credits (“Points”), based on parameters that measure the utilization of a resource, or other effects resulting from such utilization (such as a reduction of carbon emissions that may result from a reduction in electricity demand), and where such Points will be awarded to Program participants for behaviors or actions that are favorable to the achievement of defined goals with respect to the utilization and/or conservation of that resource.

This invention is a method to compute, predict, report and store the results of utilization and conservation behaviors by Program participants, and to also compute, predict, report and store the consequent award of Points to such Program participants as a result of such behaviors.

The present invention is a method to establish one or more separate and distinct incentive Programs that reflect differences in resource utilization between different geographic regions, classes of participants, types of resources or other differentiating characteristics, and, in so doing, to aggregate groups of users into “communities”, both physical communities (e.g. municipalities, co-operatives, public power utilities or “green cities”) or geographically-diverse “virtual” communities (such as “virtual commercial communities” e.g. chain retailers, hotels companies, military facilities, or other centrally-owned and/or operated user locations, as well as “virtual residential communities” e.g. apartment buildings, groups or complexes, “green developments”, off-base military housing, etc.). This invention is a method to aggregate such communities of users through Programs, to influence and incentivize the behavior of such communities and their members using Variable Incentives that change in response to key parameters and other inputs (processed within the “Points Engine”) that are received from a variety of time-variant sources, and that affect the price, availability and reliability of the resource. Data is received and variable points awarded in as close to real time as practical, to provide timely feedback to users and reinforce the value to them of the solution.

This invention is a method to create an information and control network that will measure, monitor and interactively modify the operation of devices (including software “objects” and “agents” that may represent such devices mathematically) that utilize a resource, and consequently to provide a base of data and information that is used in the operation of a Program. The Variable Incentive system creates a “virtual market” for the resource that is based in part on the “real” market for that resource. However, the Virtual Market addresses the limitations and inefficiencies of that real market resulting from regulatory, technological and political influences that impact and distort the market so that it is no longer “free” or “transparent”. Customer Community Aggregation and Virtual Inter-Market trading systems enable consumers in aggregated communities to participate in the real markets in order to share in the value created by their behavior through the award and redemption of points. The offer of an award of points for a specific action or behavior by specific customer(s) at a specific time may be used to proxy for a real-time price signal that may not be able to be otherwise implemented in that region.

This invention further includes a method to modify or augment existing or “legacy” resource measurement (e.g. meters) and/or utilization devices, that may already be installed by Program participants, so that such existing devices can be incorporated into such an information and control network, and a method to integrate such existing devices with additional new devices added to such a network, in order create a comprehensive combined and integrated information and control network that will monitor and automate the utilization of a resource throughout the overall network (which may be a “virtual network” in that the devices are not physically interconnected, but may be inter-operated using control algorithms that consider information about the devices).

The invention is a method to link such an integrated information and control network to the Internet, and to provide secure and authenticated access to interact with such a network via the Internet using a conventional web-browser.

This invention is a method to utilize such a Program to aggregate groups of participants located in a specific region, or with certain shared characteristics, into a “community of interest” (a “Community”), in order to establish and to achieve common goals for that Community with respect to resource utilization and conservation behaviors, and a method to provide incentives to such aggregated Communities in a Program.

The present invention is a method to compute incentive Points that provides a basis for automating control of the utilization of a resource, in order to achieve a set of Community goals established in a Program, as well as specific individual goals that may be set by suppliers, consumers and other Program participants, and, in addition, a method to mediate conflicts that may occur between and among such Community goals and the goals of individual participant with respect to the objectives of a Program.

This invention is a method to diagnose the operating status and maintenance requirements of devices in the resource network, including devices in participants' and Community local networks. The data from the SETM will link such participants with providers of products, maintenance and other services to appropriately fulfill such requirements, which fulfillment may include the issue or exchange of points.

This invention is a method to establish one or more exchanges whereby incentive Points awarded in a Program may be stored, aggregated, redeemed and/or traded, within a particular Program or between different Programs.

### Device (or Resource Device)

### Resource Utilization Device (122)

### Resource Generating Device (302)

### Resource Storage Device (304)

### Resource Transformation Device (306)

### Resource Transmission Device (308)

### Resource Consuming Device (310)

### Combined Utilization Devices

### Resource Control Device (126)

### Resource Sensor Device (124)

Communicating Sensors (124a)
Smart Sensors (124b)
Smart Communicating Sensors (124c)

### Device Profile (312)

### Market

### Resource Markets

### Points Markets

### Points Engine (216)

### Program Administrators (110)

### Program Operators (112)

### Program Participants

### Psychophysical Conditions

### Resource

### Resource Location (or Location) (108)

### Resource Network (106)

### Resource Network Profile—

### Resource Parameters

### Resource Demand—

### Resource Supply—

### Resource Market Factors—

### Resource Transmission Parameter—

### Resource Parameter Threshold

### Resource Parametric Signal (226)

### Resource Points

### Primary (or First-order) Resource Points

Derivative (Second-order and higher-order derivative) Resource Points

### Efficiency Operating Points

### Resource Device Purchase Points

### Award of Points in the use of Renewable Electricity Sources

### Positive Points—

Negative points

### Resource Points Goal

Resource Points Program (or “Program”)—
Resource Provider (104)—
Resource Utilization—

### Resource Utilization Agreement—

### Resource Utilization Efficiency—

### Resource Utilization Parameters.

### Resource Transformation:

### Rules

### Program Rules (114)

Local Rules (220):

### Environment—

### Global Environment

### Surrounding Environment:

### Verification

### BRIEF DESCRIPTION OF THE DRAWING

FIG. 1a is a block diagram of the smart energy transformer module of the present invention.

FIG. 1 illustrates a high level logical block diagram of the present invention.

FIG. 2 illustrates a top-level block diagram for an End-User Resource Location used in the present invention.

FIG. 3 illustrates a more detailed block diagram of the Resource Utilization Device of FIG. 2.

FIG. 4 is a basic block diagram of the logical analysis undertaken by the Points Engine with respect to the Resource Points of the present invention

FIG. 5 is a detailed illustration of the logical analysis undertaken by the Points Engine with respect to the Resource Points of the present invention.

FIGS. 5(a)-1 and 5(a)-2 show the dashboard and the goal set up screen.

FIG. 6 is an illustration of a typical prior art electrical power distribution system.

FIG. 7 is an alternative illustration of a prior art electrical power distribution system.

FIG. 8 is a further alternative illustration of a prior art electrical power distribution system.

FIG. 9 is an illustration of the regional electricity areas in the United States.

FIG. 10 is an illustration of an embodiment of the present invention.

FIGS. 11-17 are web pages for the User Interface of a first illustrative embodiment of the present invention.

FIGS. 18-21 are web pages for the Admin Interface of a first illustrative embodiment of the present invention.

FIGS. 22-33, 33(a), 33(b), 34, and 35 are end-user participant screens in a second illustrative embodiment of the invention.

FIGS. 36-45 are operator/suppler/aggregator participant screens in a second illustrative embodiment of the invention.

FIGS. 46-58 illustrate various components of the UNIPLEX platform of the present invention, in particular:

FIGS. 46-50 illustrate the transitional intelligent metering (“xIP”) aspect of the invention.

FIGS. 51-52 illustrate a communication module (“2COMM”) of the present invention.

FIG. 53-54 illustrate a personal information peripheral (“PIP”) of the present invention.

FIG. 55 illustrates the master meter and communications center of the present invention.

FIG. 56 illustrates a modular automation computer (“C2K2”) used in the present invention.

FIG. 57 illustrates a thermostat collar and temperature sensor used in the present invention.

FIG. 58 illustrates a load control module and sensor of the present invention.

FIG. 59 illustrates an alternative embodiment of the present invention.

FIG. 60 illustrates a further alternative embodiment of the present invention using gas and water meters.

FIG. 61 illustrates an alternative view of the system of the present invention.

FIG. 62 illustrates an exemplary system architecture of the present invention.

FIG. 63 illustrates the modular architecture included in the embedded computer and other elements of the present invention.

FIG. 64 is a component overview of the resource management system of the present invention.

FIG. 65 is an illustrative sequence diagram of the resource management system of the present invention.

FIG. 66 is a logical flow diagram for one implementation of the present invention.

### DETAILED DESCRIPTION OF THE INVENTION

The following detailed description is comprised of two main sections. The first section describes the functionality and operation of the universal smart energy transformer module. The second section describes a variable incentive and virtual market system in which the smart energy transformer module is implemented (also referred to in that section as a master meter and communications center (MMCC)), which was also previously described in my patent application Ser. No. 12/471,553 filed on May 26, 2009, entitled VARIABLE INCENTIVE AND VIRTUAL MARKET SYSTEM.

I) Universal Smart Energy Transformer Module

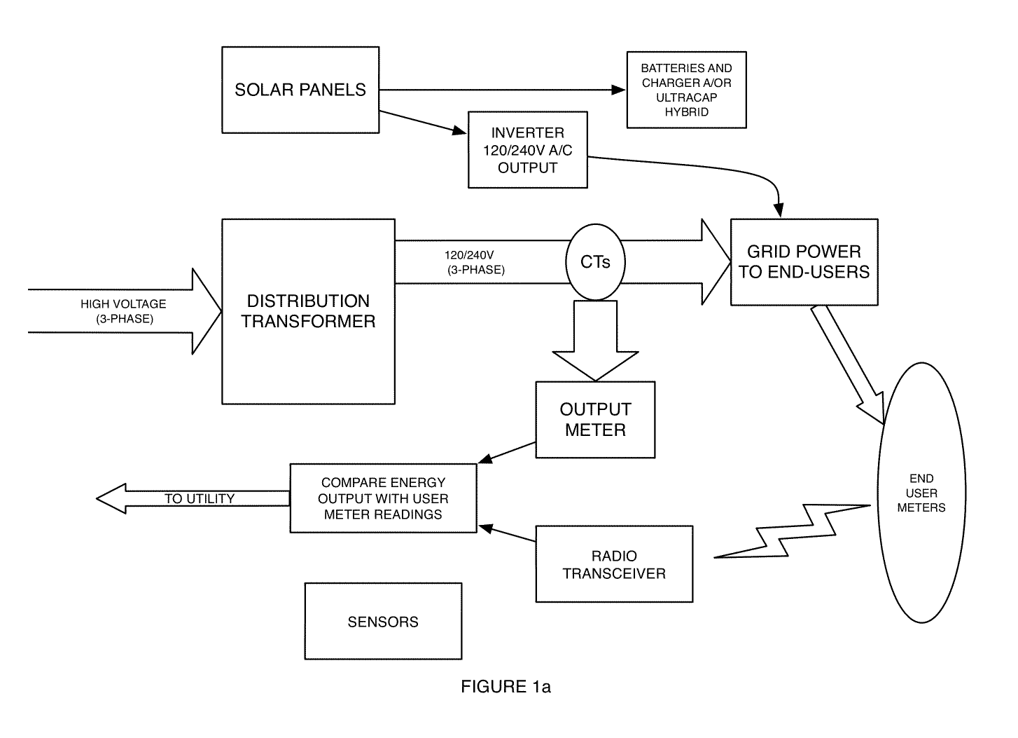

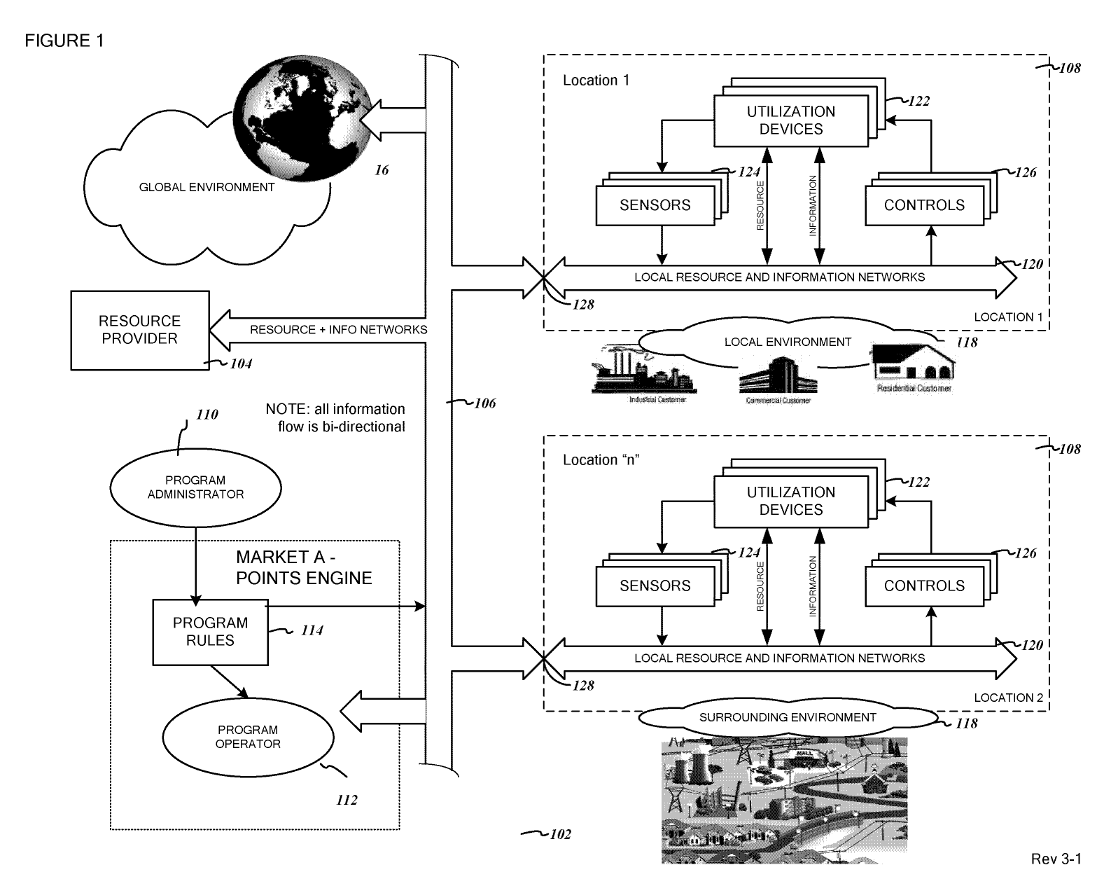

FIG. 1a is a block diagram of the universal smart energy transformer module (USETM) as will be described herein. A distribution transformer is shown, which operates substantially as in the prior art to take high-voltage electricity from the wide area electrical grid in three-phase format for distribution at a local level to various end-user premises. High voltage three phase power is input to the distribution transformer, which then will output lower voltage (120/240V) three phase power to a local grid of end-users. The distribution transformer shown in FIG. 1a may be pole mounted, vault mounted, or pad mounted, as described above.

Current transformers (“CTs”) are used to monitor the power output from the distribution transformer to the end users as shown in FIG. 1a. An output meter monitors the power with the current transformers and stores it in local memory. A radio transceiver is also shown which receives wireless RF signals from each of the end user meters that located at the customer premises that receive the power from the local grid. The local meter is adapted to provide this data by implementing a wireless RF transmitter powerful enough to communicate with the radio transceiver at the smart energy transformer module. The radio transceiver receives data from each end-user meter and provides it to a processor, which stores the data in memory. The processor will aggregate the collected and stored data and determine how much total electricity has been consumed at all of the end user premises based on the local meter readings that have been uploaded to the USETM. That is, only the electricity that has been consumed legitimately at the customer premises will be accounted for in this manner. This total aggregate amount is then compared by the processor to the amount electricity measured as output by the current transformers and output meter described above. Any amount of electricity that was output by the distribution transformer, but not accounted for in the aggregate totals measured by the end user meters, is thereby attributed to being misappropriated somewhere in the local power grid. As a result, the utility company that controls the USETM of the present invention will be informed if there is a theft of electricity in a given part of the grid and can investigate this further. Alternatively, the power dispatched from the transformer can be compared with the total amount of power being billed to the customers that receive power from that transformer, where the difference is attributed to unauthorized (and unbilled) electricity service being taken from the grid.

In another aspect of the invention, the USETM addresses a problem that has arisen with respect to the recent popularity of electric cars. It has been observed that electric vehicle owners are charging their vehicles overnight so they are ready to use the next day. For example, it may take 8 hours to charge an electric vehicle to run 40 miles. As the number of vehicles being charged overnight increases, there is a significant drain on existing distribution transformers during this time that was otherwise used for a cool down cycle. In this aspect of the invention, the load being placed on the distribution transformer is continuously monitored. When it is determined that the current load has exceeded a predetermined threshold, which is set as a function of the time of day, then a control process is invoked at the transformer that will function to reduce the load due to increased charging cycles. This control process will generate a signal for each end-user premises, that is transmitted to the various end-user premises which informs the charger device to only charge at certain times. This would allow the transformer to control the load placed on it due to electric vehicle recharging in a given area. In this embodiment, the electric chargers used at the customer premises would be adapted with communications and intelligence capabilities that would allow it to communicate, via the end user meter, with the USETM. The charger would be adapted to cease, delay or curtail charging operations for a certain time period or until otherwise instructed by the USETM. As such, the USETM can control the charging operations at various end user premises and thereby control the load placed on it during the cooling cycle.

Thus, the USETM provides load management and control for the entire distribution network. The combination of monitoring and real-time notification of excess demand and out-of-spec conditions, in combination with information received from smart meters, and the capability for remote disconnect and load control, enable the obtaining of real-time data about conditions on the distribution grid and making of intelligent decisions to better manage demand and delivery of power, enhancing system reliability and balancing electricity supply with demand, to optimize the efficient operation of the system, and to greatly reduce outages or the necessity for load-shedding.

In yet another aspect of the invention, the USETM provides for controlling the energy that is being fed back into the power grid by various end users, by monitoring various operating parameters of the transformer, analyzing if feedback energy must be controlled as a result of those measurements, and controlling a transfer switch that allows or disallows energy to be fed back to the grid based on the results of that analysis. This is applicable in situations where end users are generating their own electricity locally (e.g. by using solar panels) and then feeding it back to the local grid (for example for selling the electricity to the utility). Problems arise when a large number of end-users attempt to feed electricity back to the grid, since it is generally unregulated and the grid power may undesirably oscillate based on the end-users' activities. In this invention, the intelligent transformer is provided with a controllable transfer switch that can gate or control the power coming back in to the grid from the end users. The transfer switch can be controlled so that power is not let back into the grid when desired. Thus, by taking measurements of frequency, case temperature, etc., the appropriate times for allowing power to be fed back to the grid via the intelligent transformer may be determined.

FIG. 1a also illustrates one or more solar panels that are arranged in a strategic location on the outside part of the casing for the intelligent transformer. For pole mounted transformers the solar panels may be a part of or attached directly to the case; for underground pad mounted and vault mounted transformers the solar panels must be placed in a location above ground and wired appropriately to the (underground) transformers. These solar panels are used for two purposes. First, DC power may be obtained from the solar panels and used to recharge one or more rechargeable batteries and or an ultracapacitor as shown. Second, the DC power from the solar panels may be converted by the A/C converter, and the resulting A/C power may be fed back into the end-user power grid. By implementing a local power store in the rechargeable battery/ultracapacitor hybrid as shown, the intelligent transformer will have local power in the event of a grid failure. This will enable the intelligent transformer to continue to provide radio communications back to the utility and transmit data, whereas in prior art systems this would not be possible.

The universal smart energy transformer module of the present invention in another aspect provides for implementation of various sensors to monitor local conditions such as case temperature, humidity, smoke, ozone, motion, vibration, battery charge and the like. These sensors are placed strategically inside and outside the case of the transformer as may be appropriate to monitor local conditions. A camera may be installed so that images may be recorded (still or moving) of the area around the transformer, and then stored locally and/or transmitted back to the utility for analysis. For example if an unauthorized person has tampered with the transformer in order to cause a failure and render that part of the grid inoperative, the camera may capture an image of this person and transmit it back to the utility. An alarm may be triggered if the unauthorized person is not recognized, or police or private security may be dispatched to the area, etc.

Thus, this invention provides the capability for camera monitoring at substations and other important utility installations and other assets, using either wi-fi-enabled or other remote-communicating cameras. By connecting with a secure broadband network, camera locations are not limited to fixed locations on the electrical network, but can also be installed in mobile locations such as police and security vehicles. Optional software and servers enable camera pictures to be archived and time-stamped for future reference in the event of a security event.

Additionally, various types of communications modules are provided for communicating to a central station the local conditions as determined by these sensors. The USETM is provided with various slots that can receive a standardized board or module and can be expanded as desired, or based on the particular application or region in which the transformer will be utilized. For example, a baseline configuration may have a GSM communications card loaded into one slot, and an additional card may be added for broadband over power lines, another for satellite communications, etc.

Additionally, in one embodiment a chip such as the SNAPDRAGON chip from QUALCOMM may be used. This could provide cellular, wi-fi and satellite communications capabilities to the transformer. By providing different modes of communications as well as battery backup and local power capabilities such as solar PV, the USETM can provide emergency communications in the event of power failure (i.e. during a disaster such as an earthquake). Optimal coverage would be provided in the particular case of a pole-mounted transformer since the transformer is located high on a pole. By using the backup power, local conditions can be monitored, and important information can be communicated to first responders. As an additional feature, the USETM can create wi-fi hotspot for local residents who would otherwise have no way to communicate with first responders.

Outage and tamper detection may be provided by the USETM with alarming for expedited service restoration. The USETM and end-user smart meters can provide notification of outages and tampering through notification alarms delivered over the communications network. Since each mesh wi-fi location has a unique serial number identifier, these may be mapped to the physical distribution grid, to enable immediate dispatch of crews to the precise location of any problem.

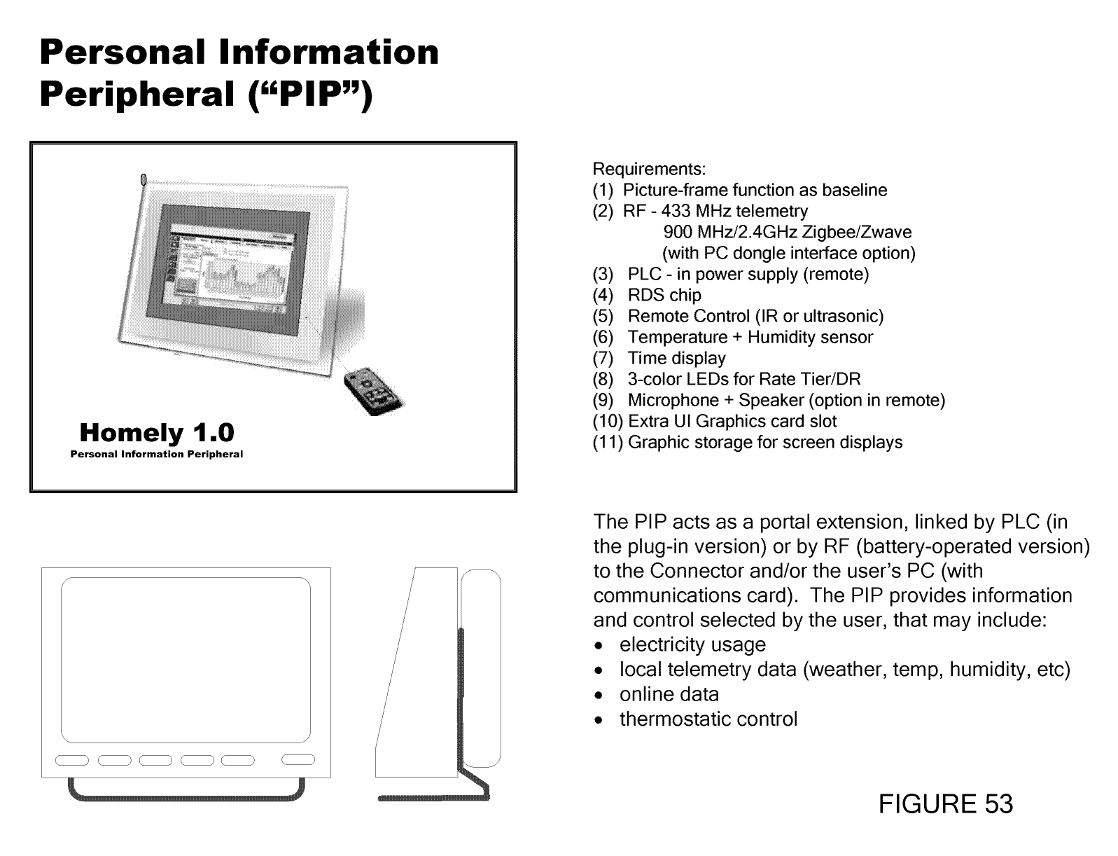

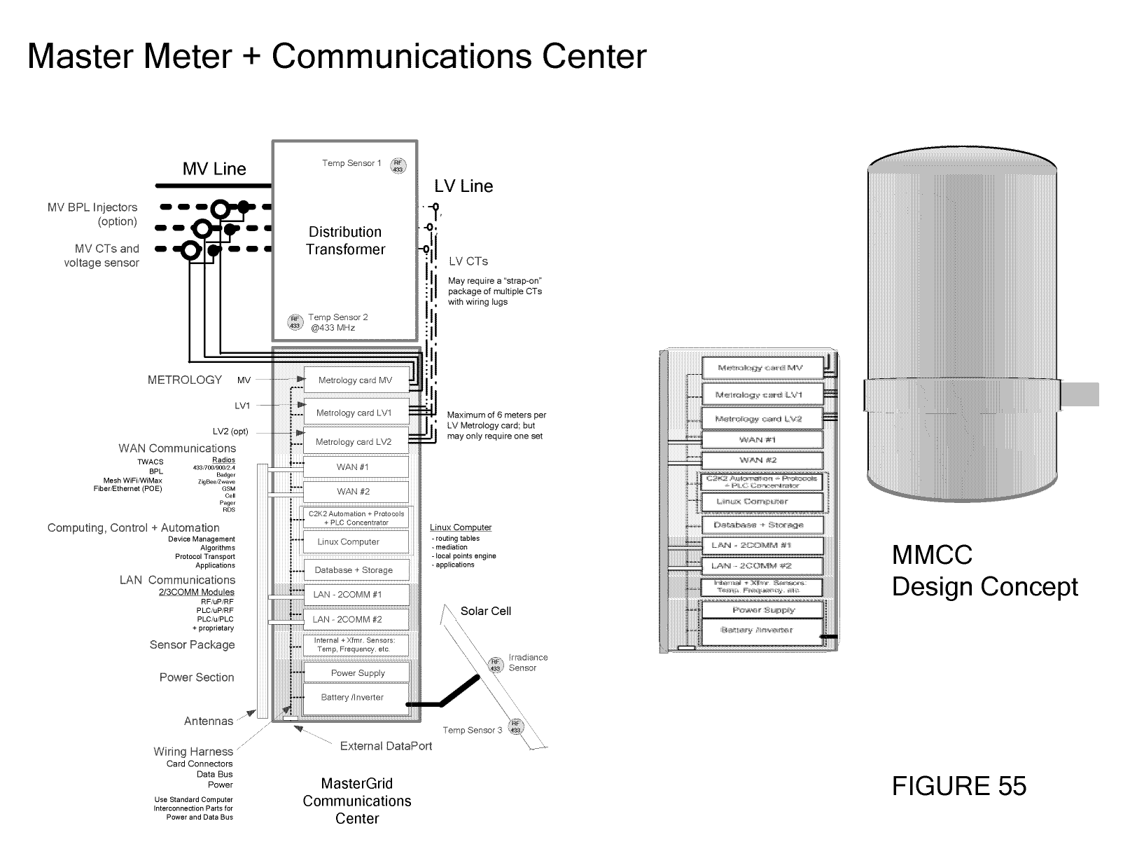

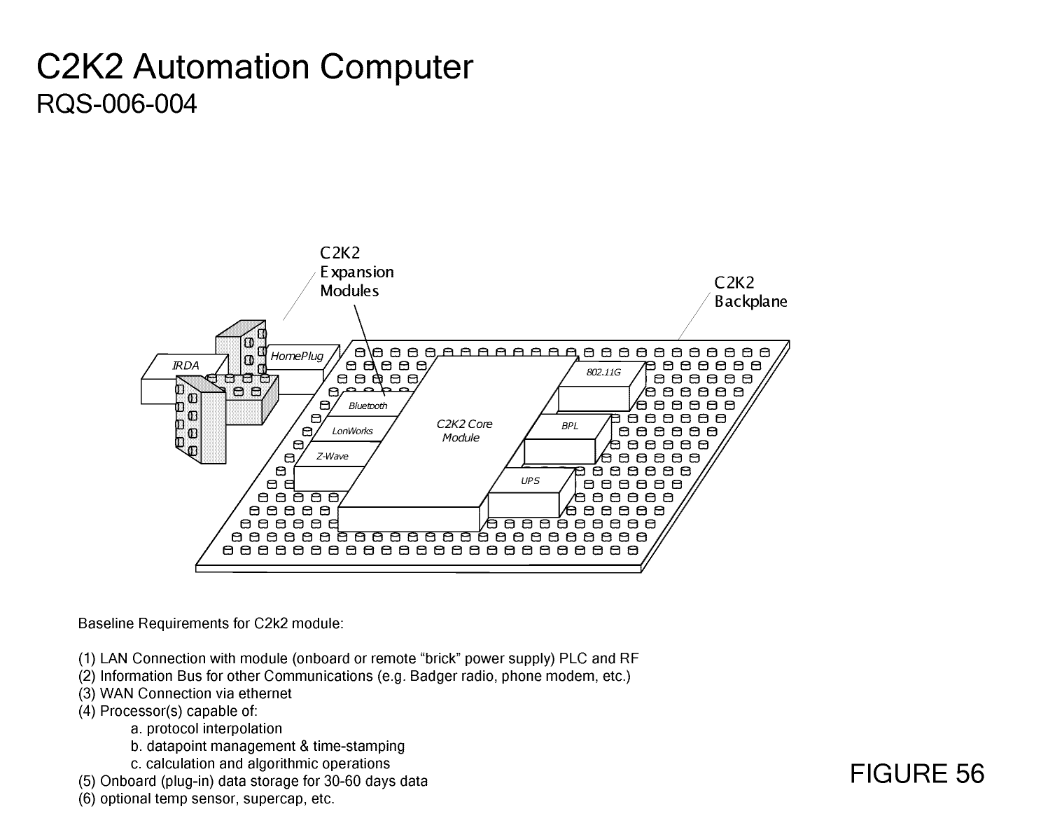

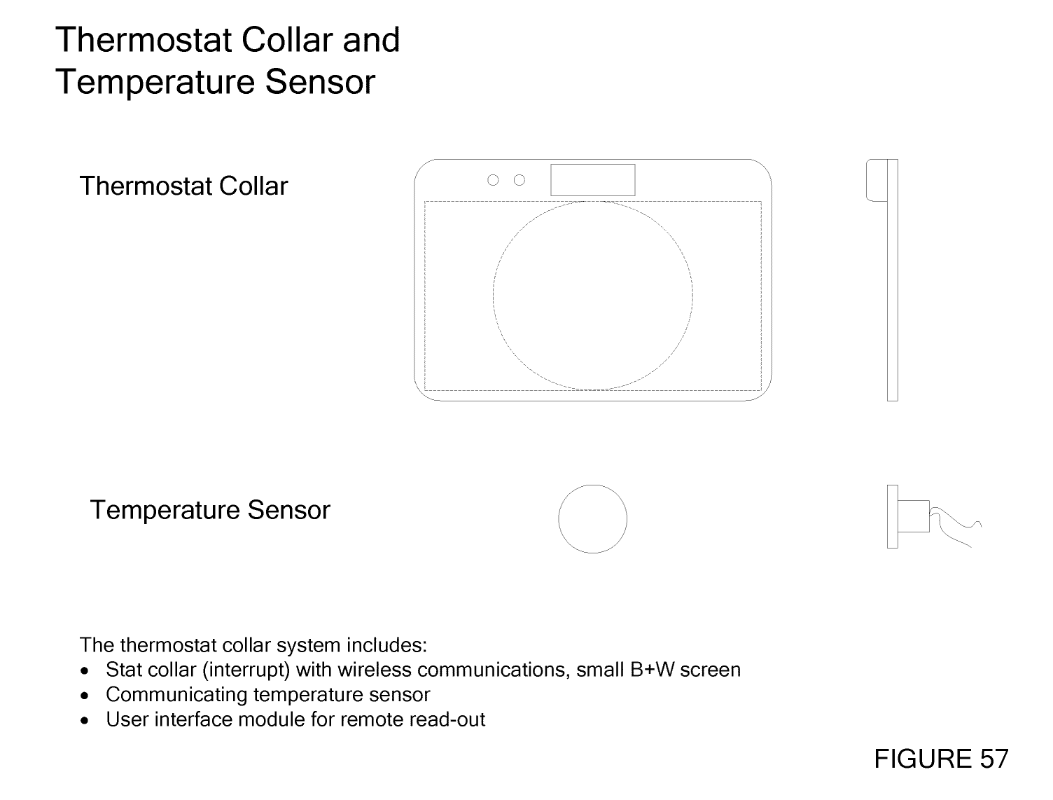

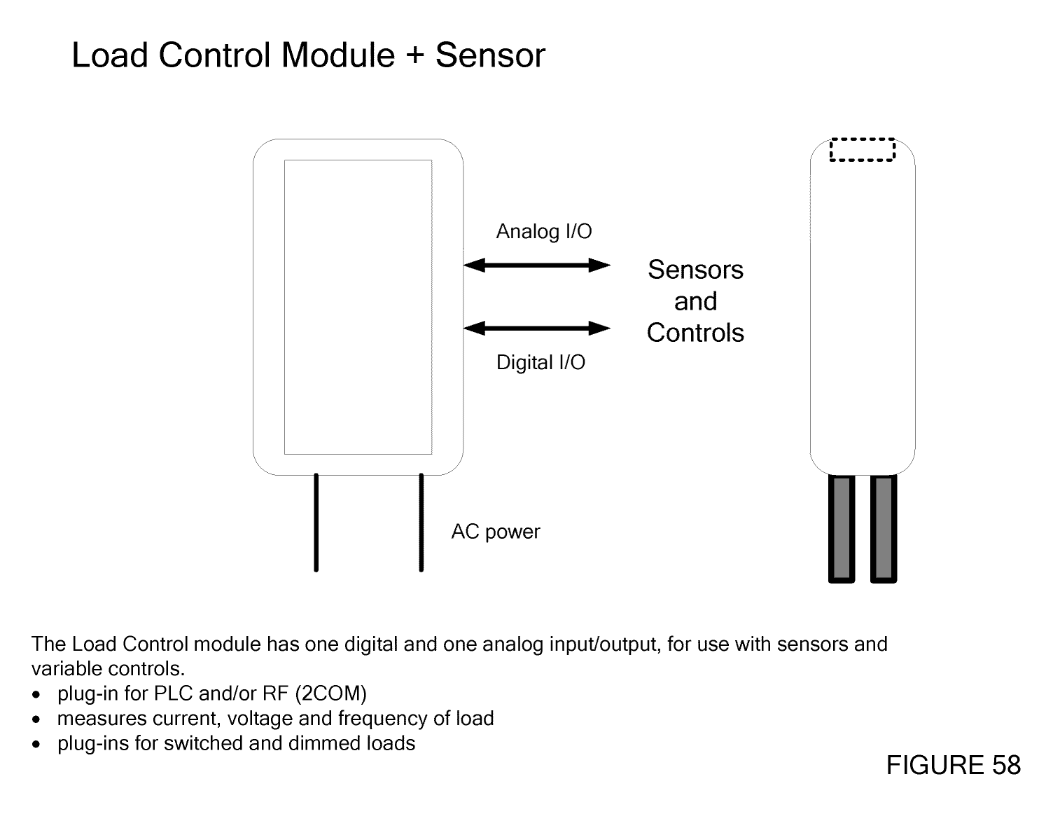

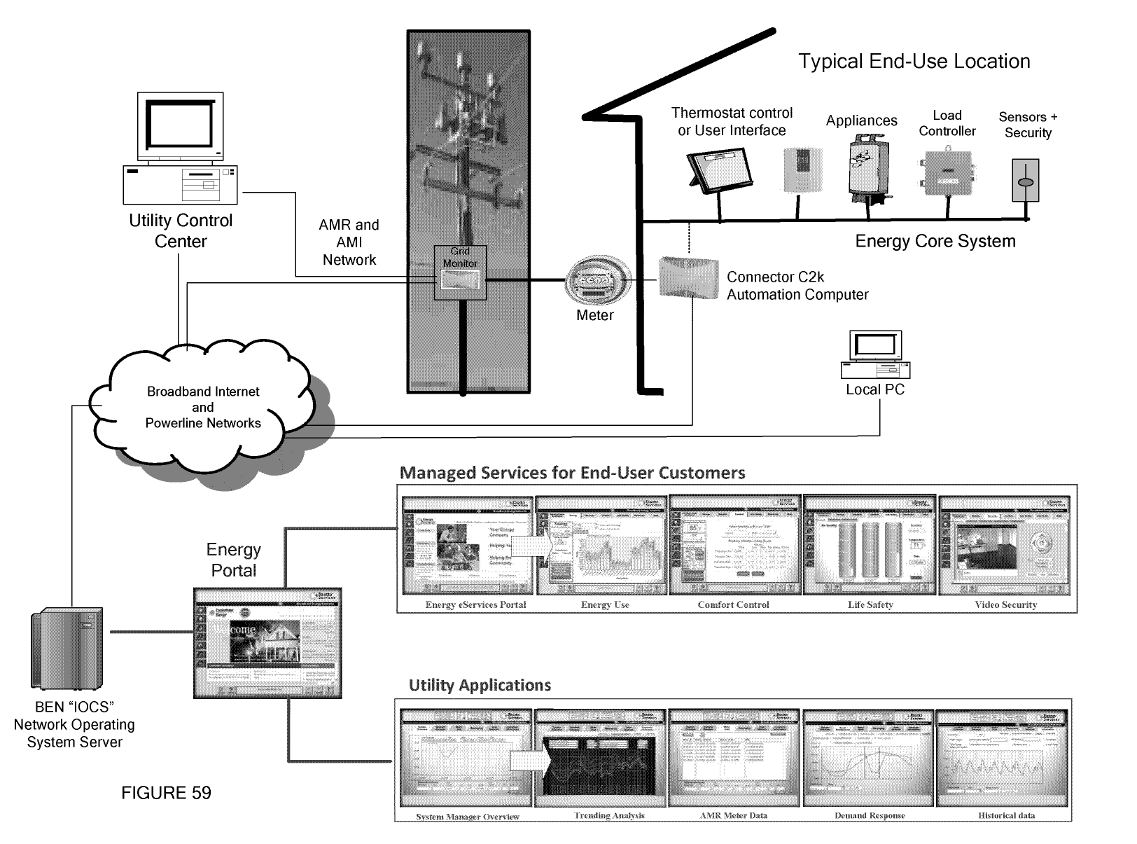

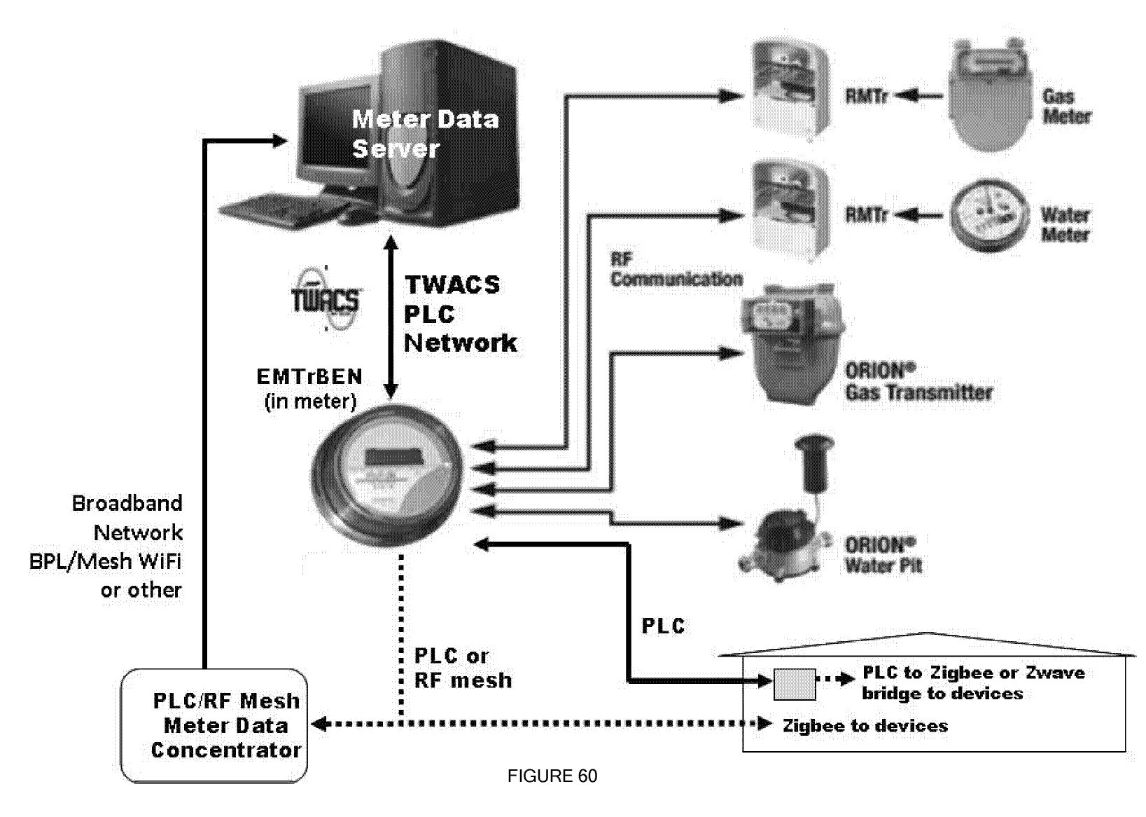

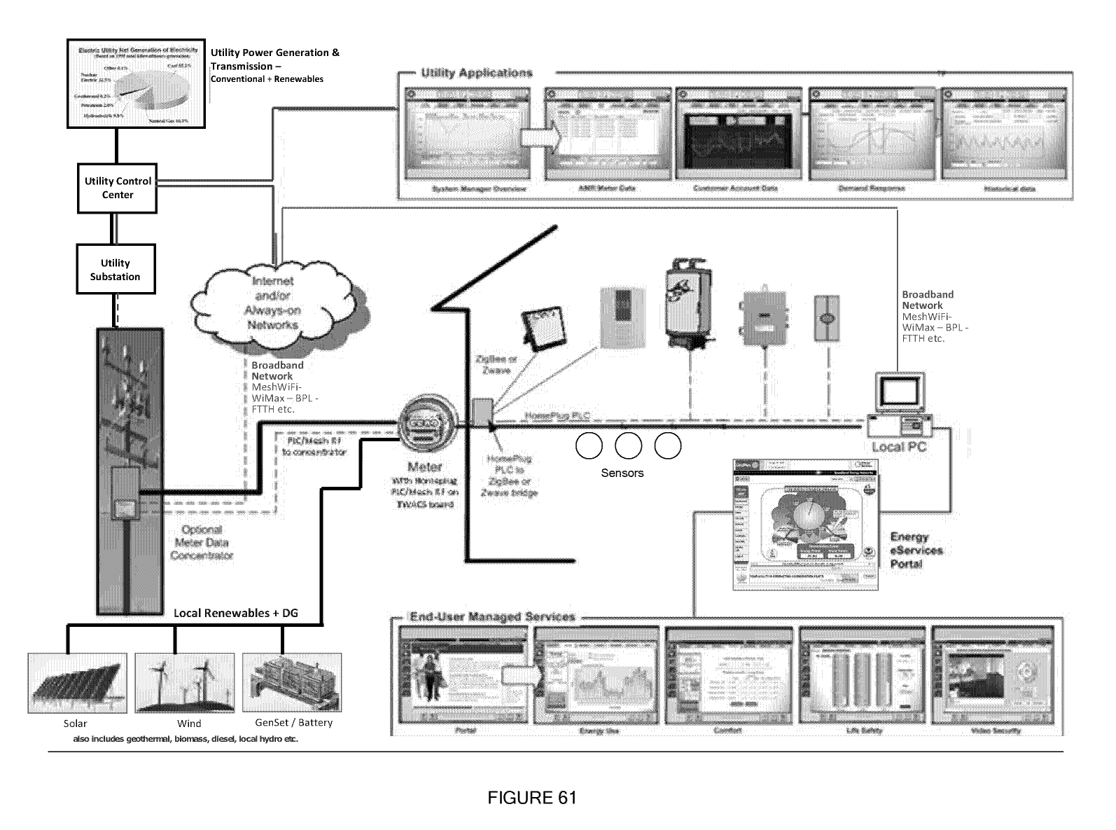

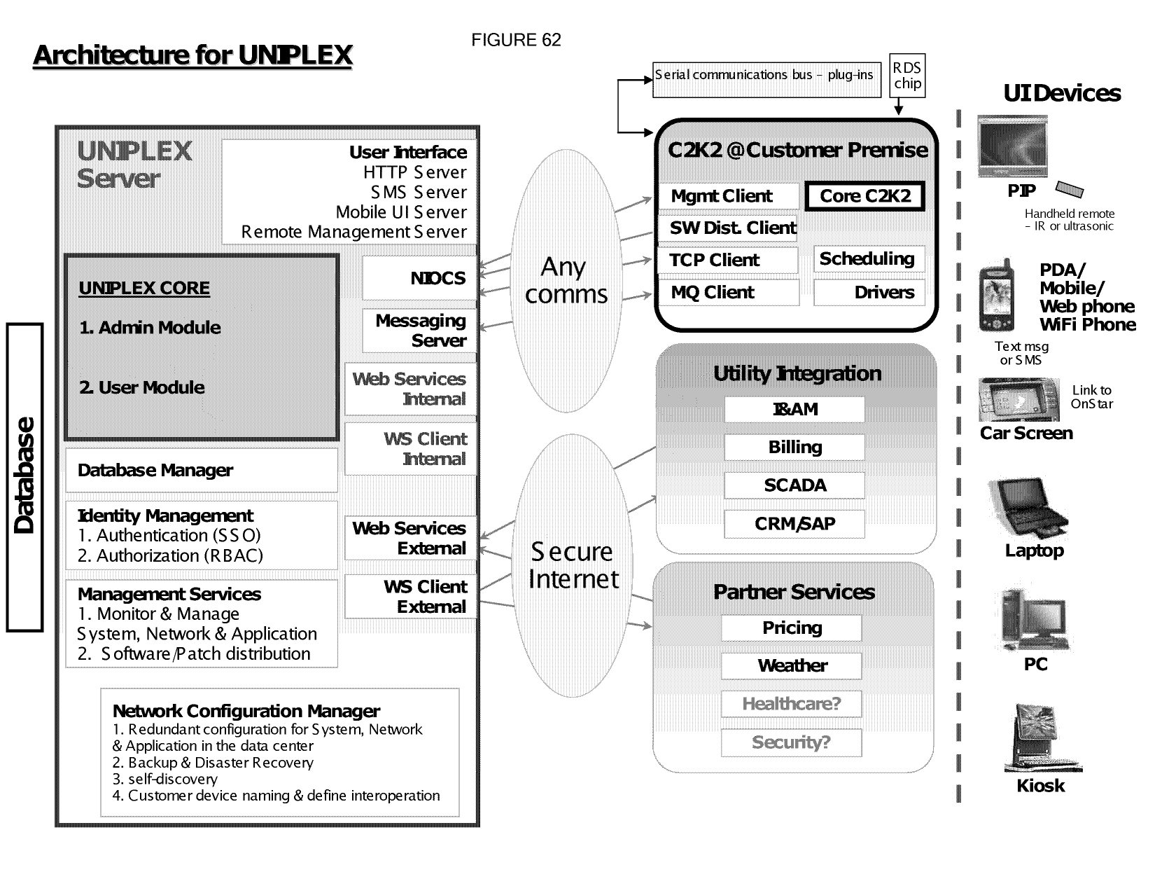

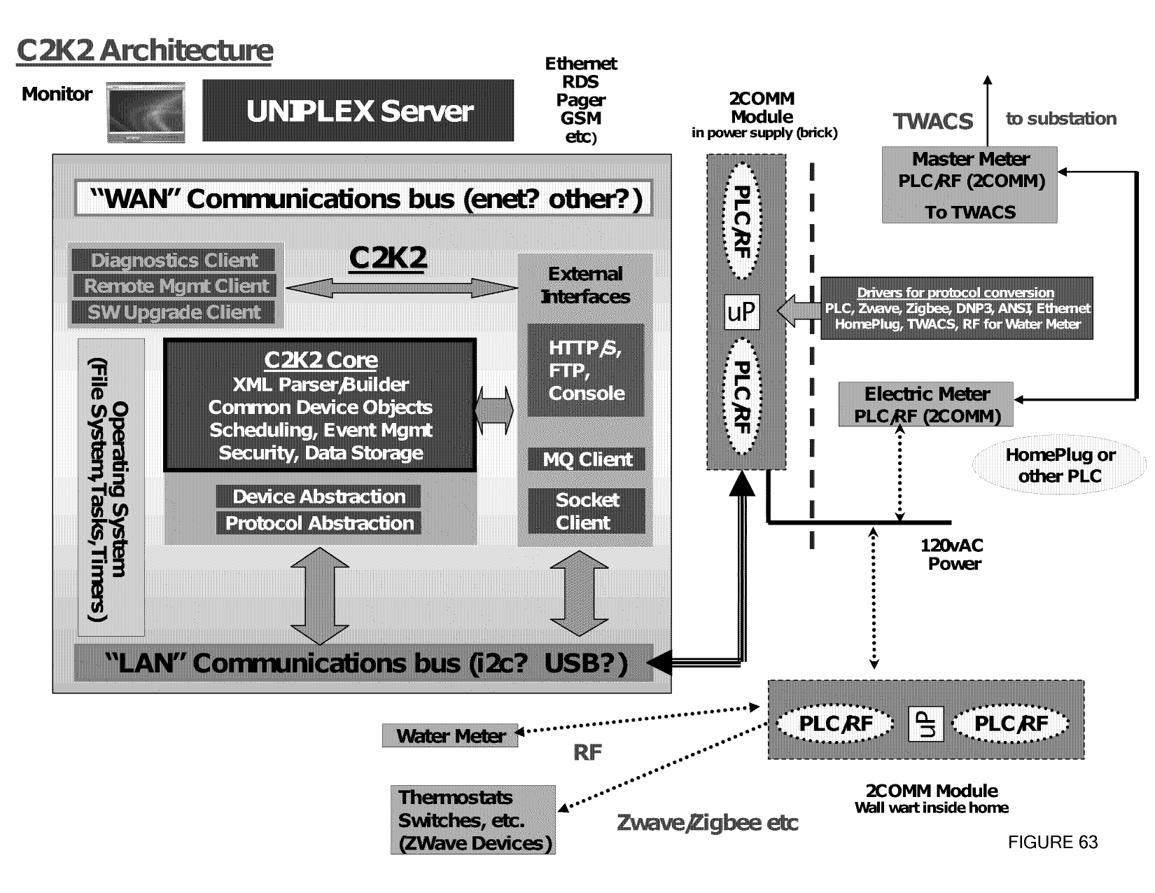

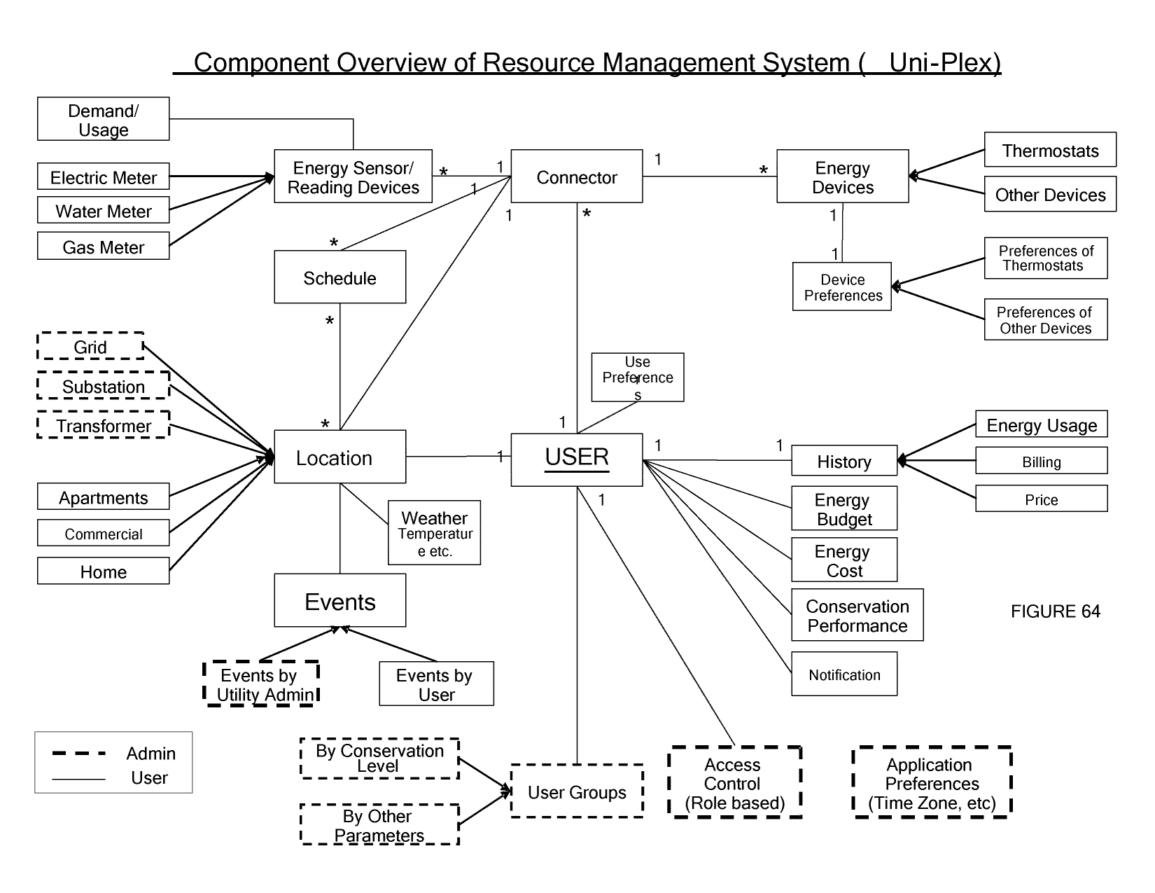

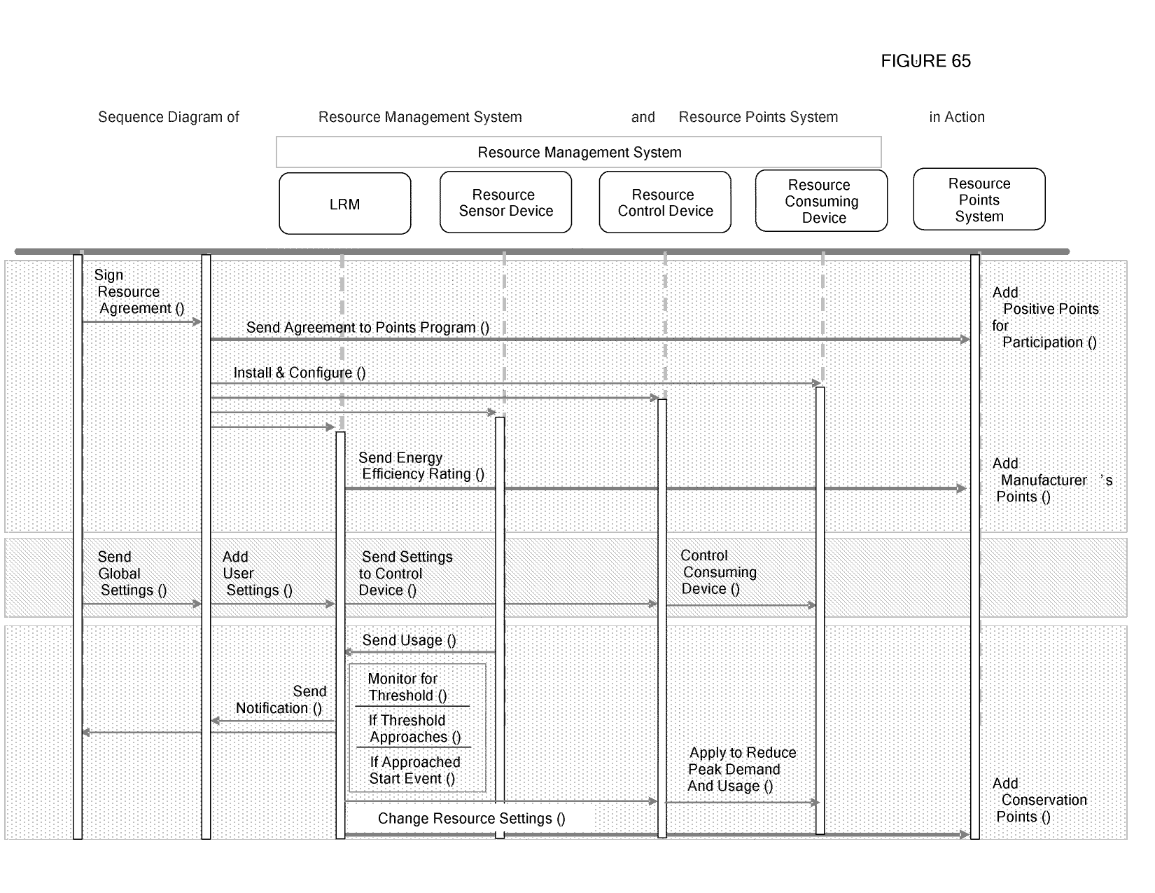

In FIG. 55, the device is referred to as a “Master Meter and Communications Center” that is mounted at or near a Transformer, and monitors the Transformer (Resource Transformation Device) in order to measure and monitor the efficiency and performance of the transformer, and also to detect theft-of-service on the Resource Network between the Transformer and End-User Meters. The Master Meter and Communications Center also provides communications links to a wide-area network, as well as to local information networks for end-users. FIG. 53 shows a display device that is linked to the meter and also to other sensors, as well as containing sensors of its own. It can provide timely information and control interface for the Local End-User. This is described further in the '553 application and provided below.

II) Variable Incentive and Virtual Market System

This part of the invention is a system for and method of implementing a Resource Points Program in order to provide incentives for conserving consumable resources such as electrical energy, water, air, natural gas, oil and the like. The Resource Points Program of the present invention provides a methodology for providing users of the system with incentive points for adopting measures to conserve on these natural resources in various manners as described herein.

Elements of the Invention

The following terms are used in the invention and the specification and are defined as follows. Reference numerals as used in the drawings are indicated in parentheses where applicable.

Device (or Resource Device)—an apparatus that directly or indirectly utilizes (i.e. generates, stores, transforms, transmits and/or consumes), monitors or controls a Resource, or the Surrounding Environment affected by the Resource Device. Resource Devices may be described mathematically by object models, which are standardized software representations of the operating characteristics of the Resource Devices; these software objects are also sometimes referred to as Device Profiles. The interactions between Resource Devices, the Resource Network and other Program Participants may be conducted directly, either manually or automatically under direct algorithmic computerized control, or indirectly through interactions between software agents representing the Resource Devices, Resource Network and the Program Participants (and/or their corresponding object models), which then communicate the result of their interactions to the Resource Control Devices for implementation. In all cases, the interactions will be governed by a set of Rules (e.g. formulas or algorithms) determined by the Program Administrator and implemented by the Program Operator. Resource Control Devices and Resource Sensors may be incorporated into Resource Utilization Devices, or they may be packaged independently and interconnected by a variety of methods (wired, wireless, inductively coupled, etc.) Resource Devices include, but are not limited to:

Resource Utilization Device (122)—equipment that generates, stores, transforms, transmits and/or consumes a Resource:

Resource Generating Device (302)—equipment that generates a Resource, such as a gasoline-fired generator or a nuclear power plant; Resource Generating Devices may be central (as a power plant serving many customers) or local (serving an individual or small number of users).

Resource Storage Device (304)—equipment that stores a Resource, such as a bank of batteries, pumped water system, etc.

Resource Transformation Device (306)—equipment that transforms a Resource, such as a transformer that changes the voltage, or an inverter, that changes direct current into alternating current, or an ice-storage system that transforms water into ice for cooling use

Resource Transmission Device (308)—equipment that transmits a Resource at or to a location. Points may reflect the efficiency (losses), stability or capacity (congestion) in the transmission system

Resource Consuming Device (310)—equipment that consumes a Resource, such as an air conditioner.

Combined Utilization Devices—some devices may both produce and consume a resource, such as a conventional co-generation system, or a storage system that pumps water up a hill into a tank, then releases it in time of need for power and uses it to turn a generator (transformation and generation).

The items noted herein constitute some, but not all, of the elements that may be included in a Resource Network and included in the operation of the incentive program described in the present invention.

Resource Control Device (126)—equipment that directly or indirectly produces a change in the delivery of a Resource over the Resource Network, or in the Resource Utilization by a Resource Utilization Device. Resource Control Devices are devices in the network that can cause a change in the quantity or quality of the supply of a Resource and/or Resource Utilization, in response to commands provided manually or via a computer (that may be remote or embedded in the Resource Control Device), and which may contain feedback concerning the change caused in elements of the local network, or the overall network, through links with sensors, and having the ability to use this feedback to further and adaptively modify its operation in order to more closely achieve performance goals established by the Program Administrator, Operator or by the Program Participant (such as an End-Use Program Participant, e.g. a home owner) and measured by one or more Resource Sensors located in the Resource Network or the Surrounding Environment. Resource Controls may be independent of Resource Utilization Devices, or embedded in to them. Resource Devices may also be assigned priorities by Program Participants, which may be incorporated into the Program Rules or Resource Parameter Thresholds for Resource Devices in the Resource Network. In some instances, there may be conflicts between the Resource Control priorities of various Program Participants, such as between end-users and those of suppliers, and the Rules established by the Program Administrator will mediate these conflicts. For example, an end-user participant may assign a high-priority to maintaining air-conditioning at all times in a given area, while at the same time the electricity provider may dispatch a Resource Parametric Signal indicating demand exceeding a chosen threshold and calling for reduction in demand—perhaps by implementing an emergency request that would result in emergency cycling of all air-conditioners, as might occur in a grid “emergency” (as might be defined by the Regulatory agency and incorporated by the Points Program Administrators into the Program Rules), wherein customers are not permitted to override the cycling function. Thus, the Program Administrator may choose to establish a Program Rule that an electricity provider defined “emergency” takes precedence over the preferences of the end-user, unless an emergency medical certificate has been registered with the Program Operator; this may be done so that the Program provides incentives for Participants that support the Regulations, but provide an additional incentive for the desired behavior. Thus, conflicts between participants (including their software agents) are mediated by Rules or procedures created by the Program Administrator and implemented by the Program Operator.

Resource Sensor Device (124)—equipment that directly or indirectly measures, monitors or calculates the value of one or more parameters associated with a Device, including both parameters related to the instantaneous utilization or to a change in utilization over time of one or more resources by a Device, or those related to the environment in the area of the Device. For example, an electricity meter is a Resource Sensor that measures parameters associated with the delivery of electricity to or from an End-Use location. Some Resource Sensors may measure parameters associated with other Resource Sensors, such as a temperature sensor that monitors the temperature at an electricity meter. Additional classes of Resource Sensors include:

Communicating Sensors (124a)—have the wired or wireless ability, using an RF, power line or other transmitter, transponder and/or transceiver, or other communications technology, such as wire, coaxial cable, fiber-optic or other physically connected medium, to deliver or receive data to or from a remote location, or to relay data from another sensor or Resource Device, as in a “mesh network” that moves information between a variety of sensors and devices.

Smart Sensors (124b)—incorporate a digital computer or processor, that can measure one or more Resource Utilization Parameters and compare that against a threshold that has been set for that Resource Utilization Parameter or other threshold that is calculated based on that parameter (such as when the parameter is a temperature and the calculated parameter is the rate of change of that temperature), and as a result of that measurement, calculation and comparison, will communicate a signal to a Resource Control to implement a change in Resource Utilization. Such an algorithmically-driven action may result in the award of Resource Points.

Smart Communicating Sensors (124c)—These are sensors that act as both a Smart Sensor and a Communicating Sensor.

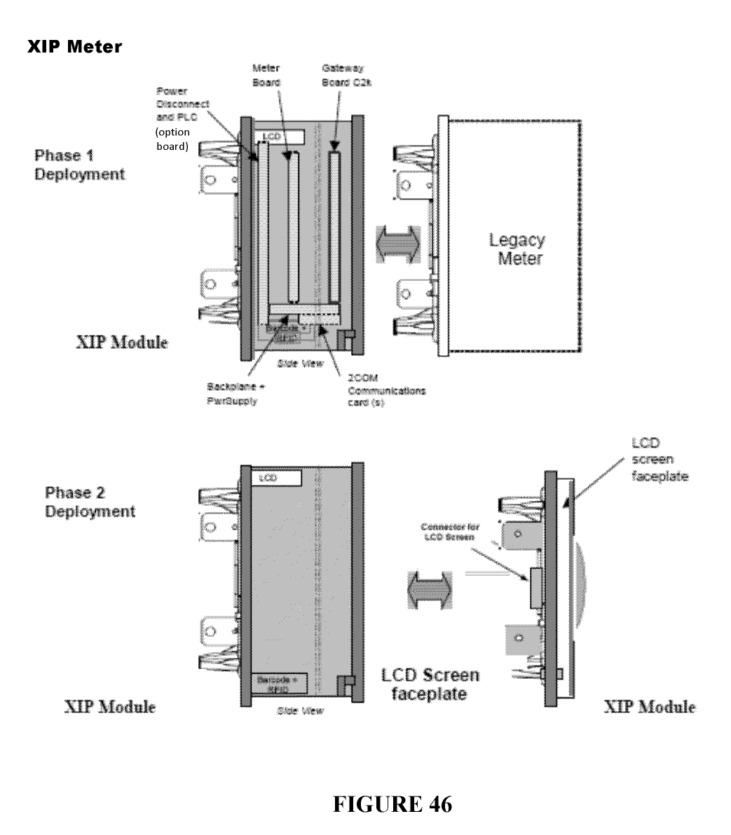

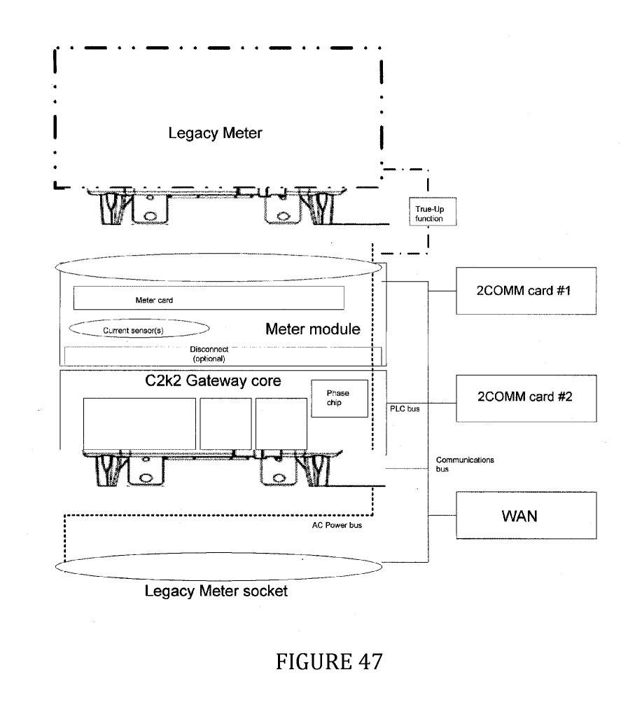

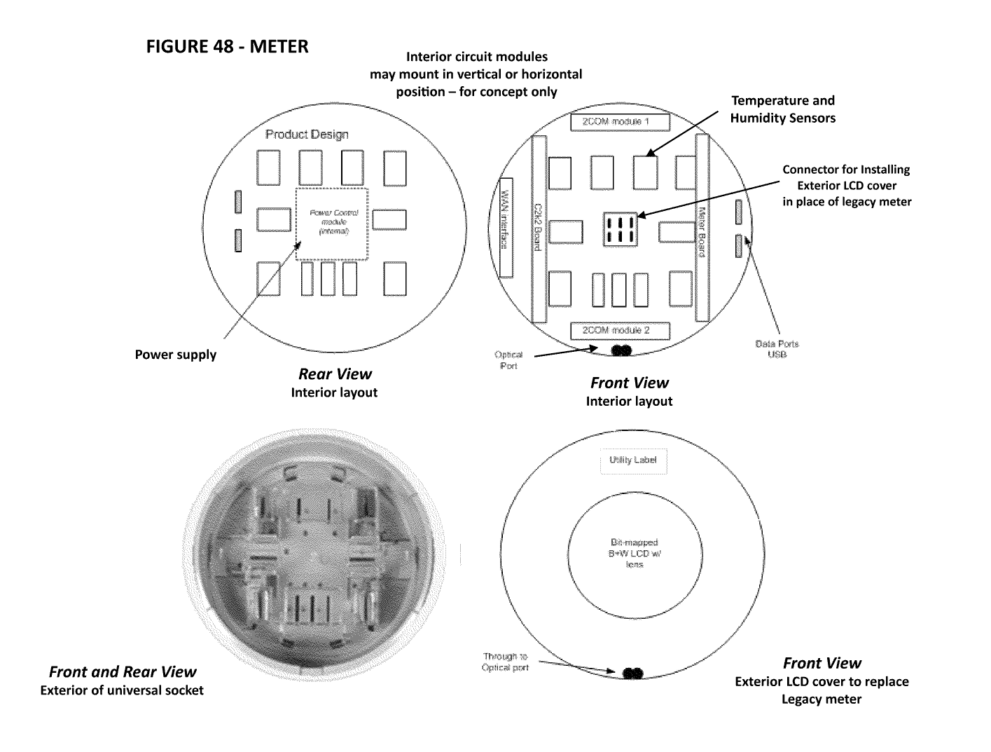

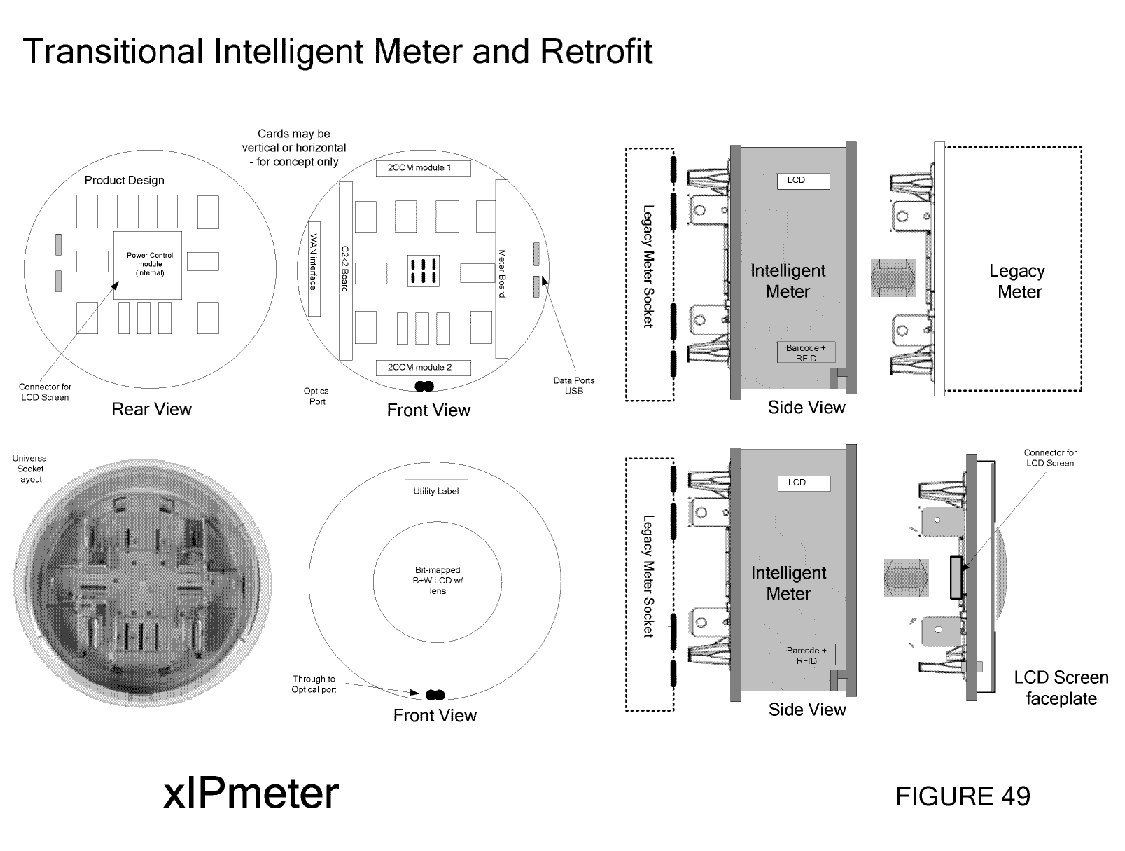

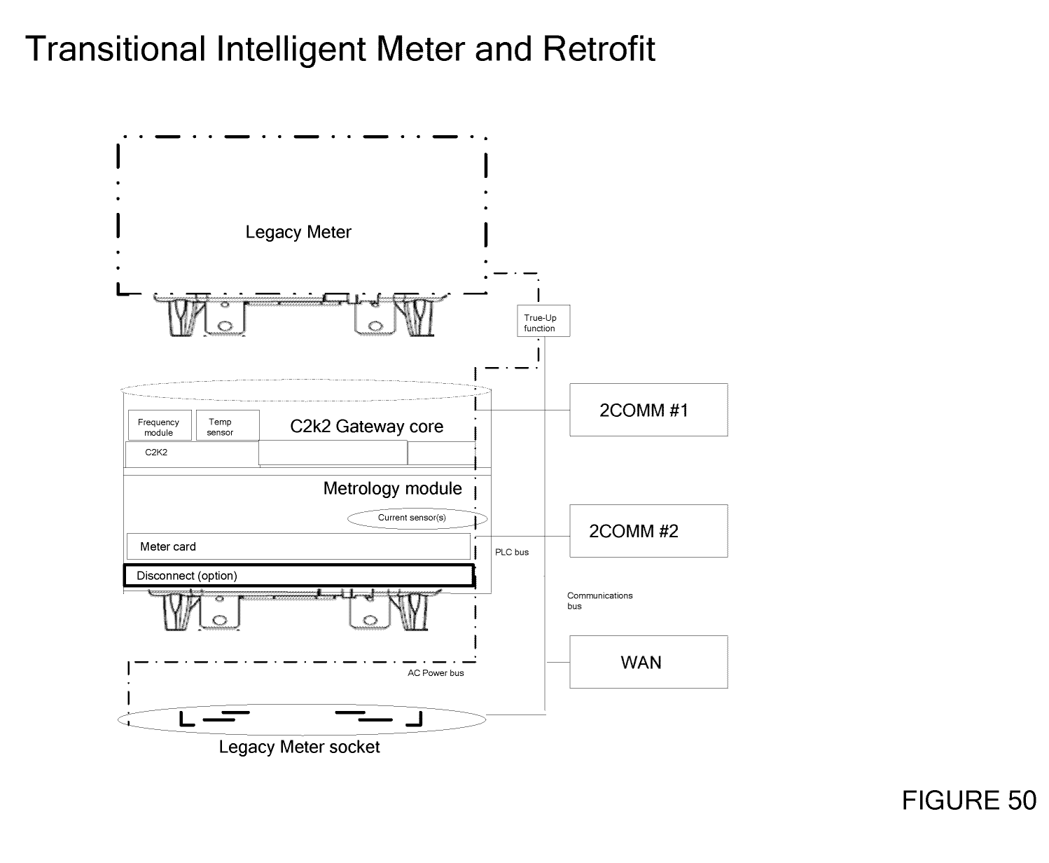

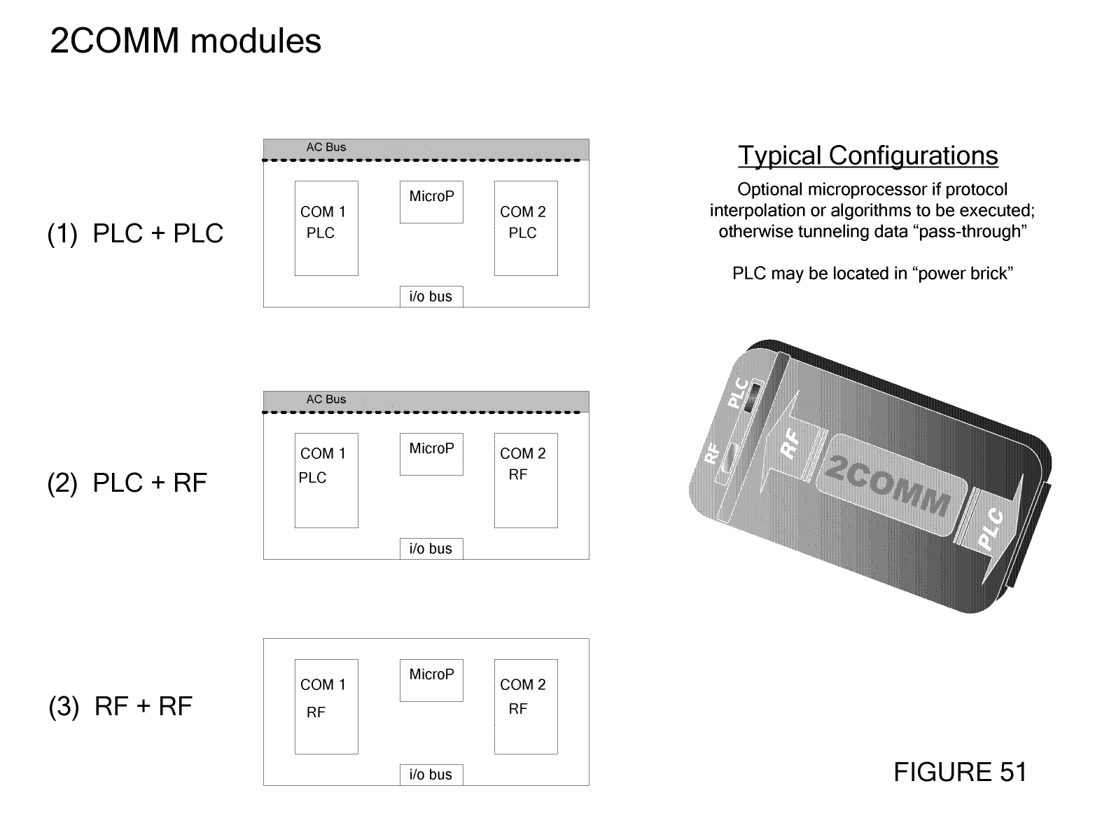

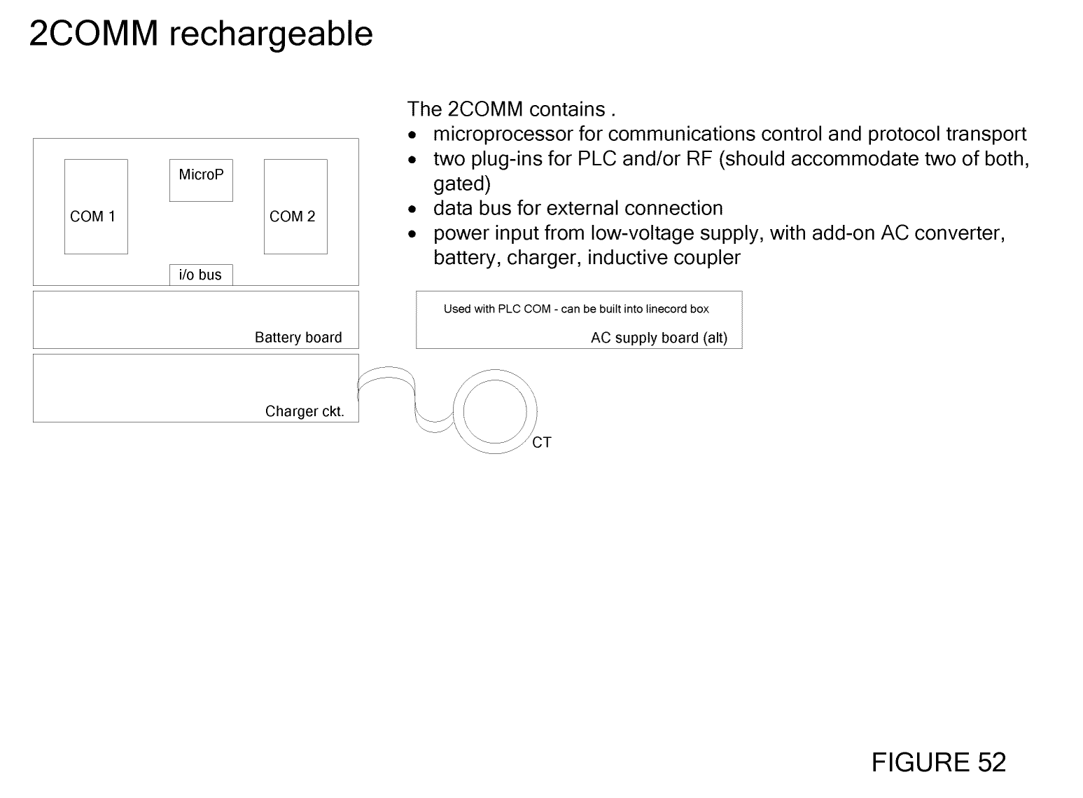

Examples of Resource Sensing Devices are shown in FIGS. 46-50 and 55. In FIG. 46, the device is an electric meter that provides Resource Utilization information both to the provider and to the end-use customer. In FIG. 55, the device is a “Master Meter and Communications Center” that is mounted at or near a Transformer, and monitors the Transformer (Resource Transformation Device) in order to measure and monitor the efficiency and performance of the transformer, and also to detect theft-of-service on the Resource Network between the Transformer and End-User Meters. The Master Meter and Communications Center also provides communications links to a wide-area network, as well as to local information networks for end-users. FIG. 53 shows a display device that is linked to the meter and also to other sensors, as well as containing sensors of its own. It can provide timely information and control interface for the Local End-User.

Device Profile (312)—a set of parameters associated with a Device that describe the Resource Utilization by a Resource Utilization Device. These parameters may be a combination of one or more of the following: Parameters determined by the manufacturer or seller of the Device according to a recognized standard (for example the EER or Energy Efficiency Rating), of a Resource Consuming Device such as an air conditioner; Parameters determined by the Program Administrator or Program Operator; Parameters determined by the end-use Participant. The Device Profile may be encapsulated in a software object that represents the Device, and/or in a software agent that represents the Device in goal-seeking interactions with other Devices and the Resource Network.

Market—a Market may be a Resource Market (or a Derivative Market), or a Points Market, any of which may vary by location and/or time:

Resource Markets—external markets in which Resources are bought, sold or traded. Time-variant conditions in the Resource Market may be incorporated into the Program Rules (algorithms) that are established by the Program Administrator or as implemented by the Program Operator for the award of Resource Points. The underlying Resource Market may also be linked to the value of points as measured against other commodities (e.g. resources, dollars, carbon credits, etc.). Resource Markets may include the trading of present supply (“spot”), long-term contracts (“future”), or “derivatives” (such as weather derivatives, that reflect the fact that weather has a great impact on electricity use, and weather derivatives may therefore be traded in connection with electricity contracts). Similar extensions may be made to similar resource markets such as natural gas, water, carbon credit, etc.

Points Markets—secondary markets for the buying, selling, or trading of Resource Points, which may include conversion value or exchange of such points for other commodities, such as in exchange for one or more resources, for “prizes”, or for cash. Points Markets may include one or more Points Programs, and will determine the interactions and exchanges between them.

Points Engine (216)—A collection of mathematical formulas, software algorithms, procedures, policies and rules, that interoperate on a platform of computing and communications hardware and software, that receive and process various information about the status and behavior of Program Participants, including Resource Devices, Suppliers and Customers, Market Parameters, Environmental parameters, various software “objects” and/or “agents” that may represent these Program Participants in order to calculate Resource Points to be awarded in response to changes in behavior by these participants, in order to incentivize certain behavior or to be used to effectively mediate conflicts between behavior (for example, by “trading” of points between participants) to achieve goals such as increased conservation, reduction of greenhouse gas (carbon) emissions, or achieving improved Resource Network stability, as such goals may be established in conjunction with a system of Program Rules, Local Rules, and End-User Agreements and other policies and criteria established by the Program Administrator(s).

Program Administrators (110)—the Program Administrators define the type, measurement, formulas and calculation methods for parameters related to the various resources considered in the Resource Points Program, and determines the Program Rules governing the type and quantity of Resource Points awarded to Participants for various activities. The Program Administrators also set Program Rules governing the interactions between participants, and the mediation of conflicting Resource Utilization requirements from resource production and delivery systems, consuming devices, end-users, and their respective agents, such as agent software programs operating interactively on behalf of Program Participants, that model their behavior, requirements and/or goals. Different geographic or demographic groups may have separate Points Programs, and each Points Program may have its own Program Administrators setting independent rules of Program operation. Negotiations between Program Administrators for different programs, or decisions by an overall Inter-Program Administrator, may determine the relative value for exchanges, and equivalence of points, to enable the separate Points Programs to interoperate within a single overall Points Market.

Program Operators (112)—The Program Operators operate the Resource Points Program in a location in accordance with the Program Rules established by the Program Administrators for that specific Points Program.

Program Participants—Program Participants include persons, entities, locations, devices, and automated software object and/or agents that act on their behalf, to receive, trade, provide, aggregate, sell (and/or resell) or purchase Resource Points (and/or the underlying Resources associated with the award of those Resource Points). Program Participants also include the Program Administrator and Program Operator. An “End-Use Program Participant” is a Program Participant who or which is an end user (e.g. customer) of the Resources under the Resource Program, such as a home owner, building manager, business operator, etc.

Psychophysical Conditions—qualitative human perceptions that may have some relationship to one or more measurable physical, biometric and/or environmental parameters, but also involve psychological elements of the particular individual, cannot be calculated deterministically from sensor measurements alone. For example, the psychophysical condition of “comfort” is related to present ambient temperature and also to the change in that temperature over time, as well as being a function of humidity, movement of air, barometric pressure, baseline body temperature, physical activity, individual's health, etc. Such psychophysical condition variables may be approximated and included in Rules algorithms either directly, by choosing one or more parameters as primary indicators of a Psychophysical Condition, or indirectly, through calculations using “fuzzy logic” and/or non-deterministic algorithms applied to one or more parameters.

Resource—A Resource may be (but is not limited to) a consumable, generatable, storable, transmittable or transformable form or source of energy or one or more other consumable resources that are essential for the operation of Devices, such as electricity, water, oil, and natural gas, etc., and may be included in the Resource Conservation Points Program. In addition, some “resources” may not be strictly consumable, but still are essential to the sustaining life or productive human activity, such as secure access or air quality; these may be provided with other types of Resource Points created by the Program Administrator.

Resource Location (or Location) (108)—the specific geographic location on the Resource Network where a Resource is utilized, such as a home, office building, campus of buildings, utility substation, pole-mounted transformer, capacitor bank, circuit switch, etc. A Location may participate in more than one Points Program if configured to do so.

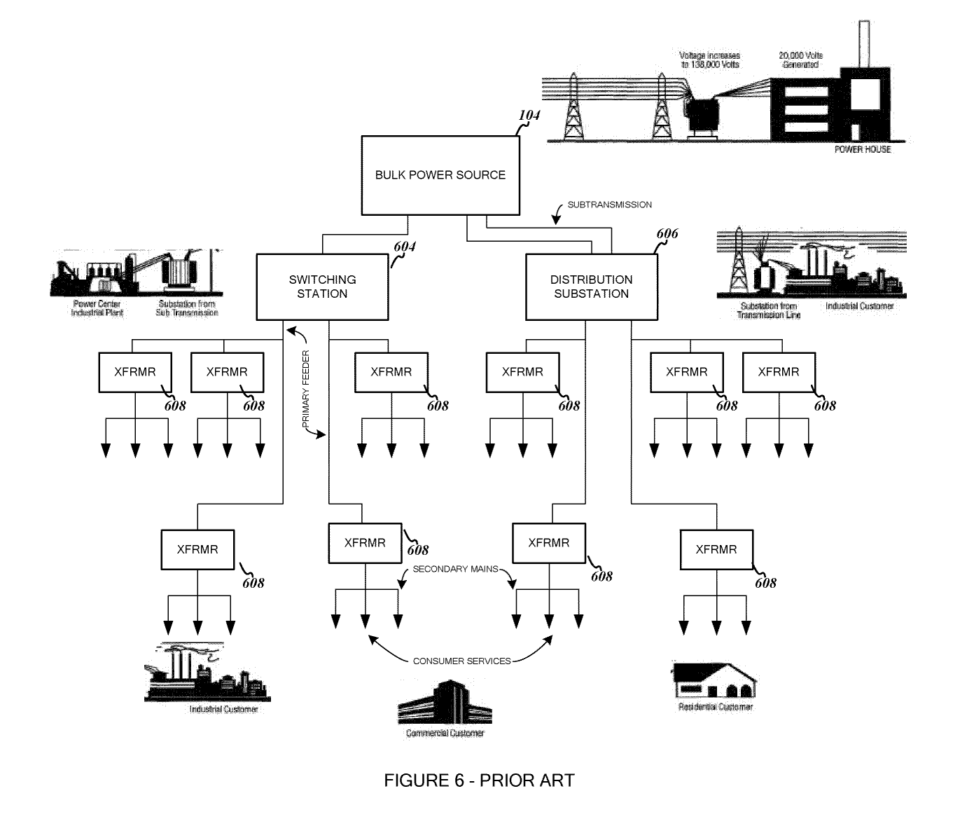

Resource Network (106)—(see FIGS. 6-8)—a transport system established and operated to deliver a Resource to, from, between or among one or more Resource Utilization Devices. A Resource Network may be local to one or more Resource Locations (and independent of a central Resource Provider), or it may connect one or more such Resource Locations to a central Resource Provider. For example, a Resource Network with a central Resource Provider may be an electric power grid that consists of cabling for transmitting, transforming and distributing electricity from a generating station to many Locations. The Resource Network includes the complete supply and demand system for utilization of a particular resource, such as remote and/or central source of a Resource (e.g. for electricity, a generator), transmission and distribution (e.g. delivery) system, Resource Control Devices, Resource Sensor Devices (e.g. meters) and Resource Utilization Devices (e.g. consumption, storage, transformation and local generation). A Resource Network may incorporate both local Resource Generating Devices (such as a solar system at a home) and delivery of a Resource from a remote location (as over the electrical grid). Parameters related to a Resource Network may be used to reflect the efficiency (losses), stability, capacity (congestion) or other conditions at any given time between locations on that Resource Network, that will, in turn, influence the type and quantity of Resource Points to be awarded for actions by participants at the locations served by that Resource Network

Resource Network Profile—a set of rules, formulas, algorithms and parameters that may vary over time and are associated with a Resource Network. The Resource Network Profile is used to determine the number and/or type of Resource Points to be awarded based on the status of the Resource Network, such that more points are awarded for conservation behavior when certain predefined static or variable conditions on Resource Network are more unfavorable to efficiency or stability, and fewer points are awarded for the same behavior when those parameters are less unfavorable. For example, a Resource Network Profile might establish that more points are awarded for a given conservation behavior that reduces Resource Demand on a particular portion of the Resource Network where the infrastructure is aging or transformers are in need of service. Similarly, a local sensor, using technology that monitors the frequency stability of the local electrical grid, might send a signal indicating a local condition of instability, and a greater number of Conservation Points would be rewarded for a specific Resource Demand reduction in that area and at that time, as compared with Conservation Points issued for an equivalent reduction in an area where the Resource Network is in better condition, and/or where no comparable instability exists.

Resource Parameters may be a measure of:

Resource Demand—parameters that describe the instantaneous requirement (past, present or predicted future) for availability of a Resource for Resource consumption by Devices on a Resource Network;

Resource Supply—parameters that describe the instantaneous availability (past, present or predicted future) of a Resource for Resource consumption by Devices on a Resource Network; matching of Resource Demand with Resource Supply can be particularly important with respect to highly-variable Resource supplies, such as renewables including wind and solar power generation systems;

Resource Market Factors—market-based indexing parameters that describe a value such as price (past, present or predicted future) in the wholesale, retail or other segments of a market for a Resource; these may vary by location of the Resource Provider, the Resource Network or the Resource Utilization Devices. In general, the parameters of the Resource Market will be a function of the Resource Demand with respect to Resource Supply in a given location—for example, if Resource Demand exceeds Resource Supply in a local segment of the Resource Delivery Network, the Resource Market price for the Resource in that local segment would be expected to increase in response to that condition. For example, in the wholesale market for electricity, this price in the local segment of the Resource Delivery Network is referred to as the “Locational Marginal Price”. Under this condition of increased Locational Marginal Price, the Program Rules for the electricity Resource might establish that more points are awarded to an End-Use Program Participant that decreases their Resource Demand for electricity when the Resource Market price rises in response to greater Resource Demand vs. Resource Supply, and fewer points are awarded to an End-Use Program Participant that increases their Resource Demand for electricity when the Resource Market price rises in response to greater Resource Demand vs. Resource Supply. In Resource Markets where prices are not “free” to respond to factors that would normally influence such pricing, due to the intervention of regulatory agencies or other controlling bodies (i.e. prices in these “Resource Markets” do not respond rationally to the interactions between supply and demand), points may be calculated based on an index to a Resource Parameter such as “Demand” or “Supply”, in place of “Price”, to develop a formula for awarding Resource Points, to proxy for a price-based index that would be found in a free and “rational” market.

Resource Transmission Parameter—a measure of the Resource Network Profile that reflects the ability to deliver a Resource from one location to another. It may consider congestion in the network, when there is more demand for the Resource at one location (the requesting location) that is available at another location (the supplying location), but where the Resource Network has insufficient capacity to deliver the Resource at the time and quantity requested. In this case, Resource Points may be awarded to a participant for behavior that reduces Demand over that portion of the Delivery Network and thereby increases the capacity of the Resource network to deliver the required Resource from the supplying location to the requesting location. Resource Points may also be used to “purchase” transmission capacity between supplying and requiring participants, governed by Rules applied as a function of the Resource Transmission Parameter and other factors operating in a Resource Market.

Resource Parameter Threshold—a level-setting for a variable Resource Parameter applied to the utilization of a Resource that may be predetermined by the Program Administrator, Program Operator, or a Program Participant (such as an End-Use Program Participant), depending on the scope of the utilization and location. When a given Resource Parameter reaches the predetermined Resource Parameter Threshold, a Resource Parametric Signal may be dispatched by the Program Operator or by a Resource Device to notify Program Participants that the Resource Parameter Threshold has been reached, and to request a response from Program Participants that will result in the awarding of Resource Points, depending on the level of response as governed by the Program Rules. Thresholds for various parameters or conditions may be set locally by a Participant, or determined and implemented automatically by a Resource Device according to threshold conditions that have been internally stored in the device. The Resource Device may send a message that will cause the Program Operator to dispatch a Resource Parametric Signal to other participants across the Resource Network. Response to this Resource Parametric Signal by these participants may result in the awarding or Resource Points.

Resource Parametric Signal (226)—a signal communicating the state or value of a Resource Parameter that is communicated to Program Participants and affects the awarding of Resource Points, and may be used to request actions under a Resource Utilization Agreement, or establish an ad-hoc exchange of Points for a specific response to the Resource Parametric Signal. In some cases, such as an emergency condition, the Resource parametric Signal may directly reset the operating condition of a Resource Utilization Device, although in general, it will be used to request a change in accordance with an agreement between the Program Participant and the Resource Provider, or a similar agreement recorded and administered in the Program Rules. The Resource Parametric Signal may be propagated over all, or over a subset, of the Resource Network. The Program Rules would then be applied by the Program Operator to determine the number and/or type of Resource Points to be awarded to (or dispensed by) a Program Participant based on changes in Resource Utilization by that Participant in response to the Resource Parametric Signal. For example, in the case of electricity, a Resource Parametric Signal might be a “price signal” communicated to Program Participants by the Program Operator that reflects the price of electricity in the wholesale electricity market in that location. For example, if the “price signal” is high due to excessive demand, then a reduction in demand by a participant will yield an increased quantity of point, when that demand reduction is provided in response to a “price signal”. The Program Rules may require verification of the demand reduction by a “bracketing measurement” (see “Verification” below).

Resource Points: points (or credits) awarded as a result of the operation of the resource conservation incentive system that is the subject of the present invention. Resource Points may be of various types, and may be either positive or negative. Resource Points are awarded based on the Resource Utilization actions of Program Participants. Resource Points may initially be awarded for an agreement (a “Resource Utilization Agreement”) by a Program Participant to follow certain Resource Utilization Procedures under certain conditions defined by the Program Administrators. Then, additional Points may be awarded on an ongoing basis when those Procedures are implemented; similarly, Points may be deducted if those Procedures are not adhered to. The awarding of Resource

Points received by a Program Participant for a given activity is time-variant—that is, a given Resource Utilization Procedure may result in different types and quantities of Resource Points to be awarded if taken at different times, as defined in the Program Rules. These differences may vary according to formulas that are based on external market, supply and demand, fuel costs and other prices, environmental conditions, and additional parameters and conditions defined in the Program Rules.
The relative classification and number of such points, and other possible classifications of Resource Points, the calculational formulas and/or algorithms governing the relationship between the number of points awarded and the time variant conditions under which they occurred (such as overall demand on the electric grid, or the wholesale price of electricity on the spot market, and other conditions and factors) are governed by Program Rules established by the Program Administrator.
For example, in the case of electricity, first-order “Conservation Points” might reflect the reduction of a participating end-user's demand for electricity from the power grid; however, the same amount of demand reduction would be awarded a greater number of Conservation Points during a period of peak electricity demand (such as on an unusually hot afternoon in August), and a lesser number of Conservation Points during a period of reduced demand (such as at night on that same day after the temperature has dropped substantially and the demand from air-conditioning became much lower).
Similarly, an award of second-order “Green Points” for that same reduction in grid demand would reflect the method by which that reduction was achieved, and might be calculated as a derivative function of first-order “Conservation Points”. In this example, at a given moment, one quantity of Green Points would be awarded for turning off air-conditioning to reduce the demand on the grid by a given amount, a different quantity of Green Points might be awarded if the air conditioning is remains on, but is powered by the substitution of locally stored power from a solar-powered battery storage system to replace that same amount of power that would otherwise be drawn from the grid, while a different (and presumably lower) number of Green Points would awarded for achieving the same reduction in grid demand by turning on an oil-fired local generator (which would result in the production of additional greenhouse gases).

Primary (or First-order) Resource Points are calculated directly from data received from Resource Sensors measuring specific Resource Utilization Parameters. The Program Rules define formulas to calculate the Resource Points to be awarded calculated based on measurements of one or more variable Resource Parameters. For example, in the case of electricity, first-order “Conservation Points” might be awarded for a reduction in Resource Demand by a Program Participant of a certain amount (in the case of electricity, this could be a measure of “demand” in kilowatts or kW). In this case, Conservation Points would be awarded for reducing the electricity being used, or because of the use of a supply of electricity that is locally generated in response to a Resource Parametric Signal, resulting in a reduction in the electricity required from the central Resource Provider, and a consequent reduction in the loading on the Resource Network.

Derivative (Second-order and higher-order derivative) Resource Points are those that are calculated as a derivative of first order Resource Points, using a formula applied to utilization parameters associated with those first-order Resource Points. Additional Resource Utilization Parameters might also incorporated that were not included in the first-order calculation. In the example of an award of Conservation Points resulting from a reduction in Resource Demand by a Program Participant of a certain amount in response to a Resource Parametric signal, second-order Resource Points, e.g. “Green Points”, would be awarded based on how that reduction was accomplished. In the example cited above for first order Conservation Points, the Program Rules might dictate that (a) a lower number of “Green Points” would be awarded if the reduction was accomplished using an oil-burning generator; than if (b) a solar-powered generator and battery bank contributed the same amount of reduction, a larger number of “Green Points” would be awarded. Similarly, if the demand reduction was due to cycling air-conditioners, a lesser number of “Green Points” might be awarded than if lighting were reduced, for the reason that during the time that the air-conditioning is off, the room will heat up, and more electricity will be used once it is turned back on, to cool the room to same the temperature as it was before the conservation event. In the case of turning off lights, when the conservation event is over, the lights may simply be restored at the same level. In some instances, it is possible that the net number of first order Resource Points, e.g. Demand Points, might be zero, but a quantity of second-order points, in this case, “Green Points”, would nevertheless be awarded because the same amount of Demand (no net change in Demand) was transferred from an oil-fired generator to a solar-powered battery bank (being a more “Green” source), producing an overall more favorable effect on the environment and a reduction in carbon or greenhouse gas emissions.

Efficiency Operating Points Efficiency Operating Points are another example of a possible type of Resource Points. For example, the level of the renewable supply (Utilization Parameter) could be measured by a sensor that measures the amount of sunlight incident on the solar cell (the irradiance), or by a sensor that measures the output of the inverter that converts the DC output of the solar cell to AC power. If the two measurements are compared for a particular solar array operating at different times, and the result varies, this would indicate a change in the operational efficiency of the array (e.g. it might be producing less electricity for the same amount and direction of sunlight). This change in efficiency might be reflected in the award of Resource Points.

Resource Device Purchase Points—Points may also be awarded as a result of the purchase and/or installation of resource utilization devices, where the quantity of points is a function of the device's efficiency, impact on the resource network, or on the environment. In general, these points are received only once, in connection with the purchase, installation or activation of that specific Resource Utilization Device. They may be provided in the form of a “Points Certificate” that the purchaser receives for deposit into their account. While the initial award of such points is fixed, additional points (positive or negative) may be awarded in future based on measured changes in performance over time (negative points may reflect a need for service or maintenance).

Award of Points in the use of Renewable Electricity Sources—Resource Points may also be indexed to the availability of power from time-varying renewable sources, such as wind or solar power generation. Let us examine the case of a solar—powered generating system. The Program Rules might specify a quantity of Conservation Points and/or Green Points to be awarded for the use of an intermittent or highly variable renewable resource at a particular time or under a particular set of conditions, in this example, solar-generated electricity. However, additional Resource Points could be added for interactivity established between the Resource Utilization Devices. For example, if solar irradiance is reduced, then a Resource Utilization Parameter would be dispatched to the Control System, and in response the Control System would cause the power consumption by end-user consuming loads to be reduced as well. Thus, the number of Resource Points awarded would reflect the fact that the predictability and reliability of the intermittent renewable is increased by linkage to the Resource control system, using an algorithm that automatically reduces the demand in response to the reduction of renewable supply. The Program Rules might provide that, in this scenario, an total quantity of Conservation Points and/or Green Points would be awarded that would be greater than the total of the two activities independently—the Conservation Points for the reduction of absolute electricity demand, and the Green Points as a result of the linking, and consequent improvement in predictable availability, of the renewable resource. Additional points may be awarded when a Resource Utilization Agreement (such as an Agreement to reduce Demand under certain conditions) is linked to the operation of a variable Renewable Resource Generating Device (such as a wind farm or solar array).
A participant may also receive points of different types awarded for the purchase of renewable energy.

Positive Points—In general, the Program Rules will provide the award of positive Resource Points for Resource Utilization behaviors by Program Participants that result in conservation of the Resource, or have a positive impact on the efficiency, stability or operation of the Resource Network, or improvements in the Surrounding Environment as a direct or indirect result.

Negative points (penalties) may be awarded if a Program Participant violates an established Resource Utilization Agreement to implement a certain mode of operation of their Resource Utilization system under certain conditions, for example, by over-riding a thermostat conservation setting during a period of Demand reduction requested by the Resource Provider.
Resource Points Goal—An example of a simple Resource Points Goal that defines a Local Rule (reflected as a User-established priority) would be “accumulate 10,000 Conservation Points as quickly as possible through reduction of air-conditioning throughout the facility, but do not let room temperature in any area exceed 75 degrees”, or “keep the temperature in zone 1 at 70 degrees unless electricity cost exceeds a certain threshold amount”. Rules may also incorporate dynamic automated interchanges between suppliers and end-users or devices themselves (or their respective software objects and agents), so that a “bidding” situation may be established if, for example, an end-user participant may indicate that he/she will implement a reduction in air-conditioning only if he/she receives a quantity of conservation points in excess of a certain amount, and the Rules Engine will interactively exchange an offer to provide this or another quantity of points; such an exchange may be dynamically iterative between the participant and the Rules Engine, and it may or may not conclude in an “agreement” that results in an award of points.
Resource Points Program (or “Program”)—A Program that applies to a specific Resource in a particular set of locations and/or includes a particular set of Program Participants, and that uses the award of Resource Points to encourage activities and behaviors that result in the achievement of specific goals for improving the utilization of that Resource (e.g. Conservation or improved Efficiency or Reliability), or that provide benefits to the larger community such as to the environment (e.g. reduction of Greenhouse Gas Emissions) as a result of those activities or behaviors. There may be separate Programs for a specific Resource, or a Program may include several Resources. Each Program will have a set of Rules that determine the award of one or more types and quantities of Resource points for various activities; these Rules are established by one or more Program Administrators (they may be permanent or subject to modification in particular circumstances). The Rules are implemented, and Resource Points dispensed through the operation of a “Points Engine” as described herein.
Resource Provider (104)—entity that generates, delivers, sells or resells, or otherwise enables the supply of a Resource to one or more Resource Utilization Devices at one or more locations via a Resource Network. An example of a Resource Provider is an electric utility that distributes electricity for use by Resource Consuming Devices at End-User Resource Locations.
Resource Utilization—generation, transmission, storage, transformation or consumption of a Resource.

Resource Utilization Agreement—an agreement between participants in a Resource Points Program that governs the activities of a Participant's operation of a Resource Utilization Device under certain mutually agreed conditions and/or in response to a Resource Parametric Signal or Resource Parameter Threshold. Resource Utilization Agreements govern the type and quantity of points awarded based on the operation of the Resource Utilization Device under the agreed conditions. The formula used to calculate the award of Resource Points under a Resource Utilization Agreement may be static (fixed), or dynamic (based on an active interchange and negotiation between the parties to the agreement (i.e. “bidding”).

Resource Utilization Efficiency—a parameter associated with a Resource Utilization Device, that is established in the Program Rules by the Program Administrator to represent the efficiency of the Resource Utilization Device as it utilizes a Resource, or is derived from calculations based on data from Resource Sensors that monitor the Resource Utilization Device. For example, if the Resource Utilization Device is an air conditioner, the Resource Utilization Efficiency could represent the air conditioner's relative efficiency. The Program Rules might state that the Resource Utilization Efficiency of the air conditioner would be determined using formula-based calculations on data received from Resource Utilization Sensors, or they might simply be determined by a standardized measurement from a third-party test agency or device manufacturer (as in the case of a standardized appliance EER or energy efficiency rating) or the like. The Resource Utilization Efficiency may be a fixed number, such as a manufacturer's EER rating, or a variable, based on occasional calculations using Resource Utilization Sensor data that would adjust the Resource Utilization Efficiency parameter to reflect changes in the condition of the Resource Utilization Device over time, such as a need for repair, service, or required maintenance. Notification of such changes in efficiency, and suggested methods to increase Resource Utilization Efficiency.

Resource Utilization Parameters: Utilization Parameters describe data measured directly by one or more Resource Sensors, or from calculations derived from data delivered from such Resource Sensors. Resource Utilization Parameters include measurement of one or more specific parameters related (a) to a resource itself, and/or (b) to the manner in which the Resource is utilized by a Resource Utilization Device, and/or (c) to the impact of such utilization to conditions in the Surrounding Environment. These parameters may be recorded as both instantaneous measurements and/or measurements integrated over a past time period, or projected over a future time period. Included in the types of Resource Utilization Parameters are both “first-order” parameters, that reflect the direct measurement of a parameter, and “second-order” parameters, that are calculated based on formula (s) applied to the data in the first-order parameters. Resource Utilization Parameters may be either positive or negative numbers, depending on the rules established by the Program Administrator. For example, in the case of utilization measurement for the consumption of electricity, the resource sensor is referred to as an “electric meter”, the instantaneous consumption parameter is referred to as “demand” and is measured in “kilowatts”, and the consumption parameter integrated over time is referred to as “usage” and is measured in “kilowatt-hours”. Calculated parameters relating to the consumption of electricity may include such things as the amount of greenhouse gas reduction contributed by the reduction of electricity consumption in a given time period. The parameters considered in the present invention may include those on both a local basis (for a particular participant), and/or on an aggregated basis to include all or some portion of the overall resource supply-and-demand system or network for a plurality of participants. The Resource Utilization Parameters considered in the present invention include, but are not limited to, measurements related to: consumption, generation, supply, transformation and/or storage of the particular resource in question.

Resource Transformation: refers to modifying or transforming characteristics and parameters of a Resource in the course of traversing a Resource Network. An example is the transformation of the voltage of electricity as it is transported from a generator over a transmission grid to a substation, then from the substation over a distribution network to a local step-down transformer, and then into a building or home. While the basic Resource transported is always electricity, its voltage and other electrical parameters are transformed during the delivery process. Similarly, an array of solar cell may provide local Resource Generation, but the output of the solar array is transformed from DC power to AC power through being processed by an inverter, which provides Resource Transformation that can be measured by Resource Utilization Sensors, and the efficiency of the transformation may affect the awarding of Resource Points.

Rules: Rules under this invention are classified as either Program Rules or Local Rules:

Program Rules (114)—a set of rules, parameters, formulas and algorithms associated with a Resource established by the Program Administrator that govern the type and quantity of Resource Points to be awarded at any given time to a Program Participant for activities in the Points Program. The Program Rules also determine the relation of those Resource Points to conditions (e.g. Resource Parameters) in the Resource Network, the Resource Markets, and/or the Surrounding Environment. The Program Rules may set limits and guidelines for the operation of automated software agents that operate on behalf of participants, and on the interactions between and among the Resource Network, Resource Devices, Program Participants and/or their corresponding software agents. In general, the Program Rules control the classification and calculation of Resource Parameters and Resource Points, and the dispatch of Resource Parametric Signals. Algorithms may reflect predictions of future conditions in the Resource Network, Resource Markets, Resource Utilization Devices, Resource Locations and the Surrounding Environment, based on historical and other data (such as weather forecasts or weather history). Algorithms may also be adaptive, so that the system will use data accumulated over time to progressively adjust its operation to more effectively attain an operating behavior that will generate a quantity of Resource Points (a “Resource Points Goal”), within guidelines and/or priorities that may be determined by the Program Participant according to the Rules and operation of the Program.
Local Rules (220): a set of rules, parameters, formulas and algorithms regarding the operation of Devices at a given Location that are determined by the Program Participant and are specifically and exclusively associated with that Location. Local Rules may be implemented in order to attempt to satisfy one or more Resource Points Goals established by the Participants.

Environment—the Environment may be a Global Environment or a Surrounding Environment:

Global Environment refers to the environment beyond the borders of a defined location.

Surrounding Environment: areas generally adjacent to the Resource Network and/or affected by its operation.

Verification: the response of a Resource Device to a Resource Parametric Signal (RPS) will be verified by a Resource Sensor. In the preferred embodiment, that sensor will “bracket” the response by performing a measurement immediately on receipt of the RPS and just prior to the response being implemented, and then immediately after the response has been implemented, to verify the change that was implemented and confirm the award of points.

Overall Operation of the Resource Points Program

The Resource Points Program of the present invention will operate to enable detailed monitoring of Resource Utilization and will award certain Resource Points as a function of various time-variant, location-variant and other variables and parameters. Resource Utilization as consumption may be monitored by (1) measuring Resource consumption at a Location when the Resource is dispatched or transmitted from a Resource Provider external to the Location (during the process of transmission the resource may also be transformed, as in the case of electricity, where it goes through a series of transformers that change its voltage at different points in the transmission system), (2) measuring Resource delivery via a Resource delivery system measured at the demarcation line between the Resource Provider and the end-user Location, (3) measuring Resource consumption at one or more Resource Consuming Devices at a Location. Similarly, Resource Utilization as generation may be monitored by measuring (1) Resource generation at the Location when the Resource is transferred from a Resource generating device at the Location to a Resource Provider external to the Location, (2) Resource delivery to a Location via a Resource delivery system external to the Location, or (3) Resource delivery at a Location through local generation and/or local storage. Resources may be utilized under this invention by consuming the Resource at a location, or by generating the Resource at that Location or another Location or when it displaces consumption from an external source or when one type of local generation is substituted for another. For example, electricity (the Resource) may be transferred from an electric utility (the Resource Provider) via the electric power grid (the Resource Network delivery system) to a building (the Location) where it is used by an air conditioner (the Resource Consuming Device). In another example, electricity (the Resource) may be generated by a solar powered generator (the Resource Generating Device) at a building (the Location) and then transferred to the electric power grid (the Resource delivery system) for distribution and use by other customers. In both of these instances, the Resource is being utilized, and the utilization is monitored with respect to a plurality of time-variant conditions in order to ascertain the type and quantity of Resource Points to be provided to the account. Resource Utilization also incorporates the transmission, transformation or storage of a Resource, as defined elsewhere in this document.

The quantity of Resource Points provided may vary as a function of a set of Program Rules established by a Program Administrator. For example, if the resource being delivered is electricity, the Program Rules may indicate that more Resource Points are provided as demand for the electricity decreases, and conversely fewer Resource Points are provided as demand for the electricity increases. Since the demand for electricity (the Resource) will vary over time, this is taken into account in the Program Rules. Negative Resource Points may be created if an individual Location increases its consumption or decreases its generation contrary to its Resource Utilization Agreement to otherwise change those conditions. Similarly, Program Rules may be established by the Program Administrator in order to improve certain operations of the Resource Delivery system. These Rules may indicate that more Resource Points are provided as certain parameters in the electric power grid (the resource delivery system) are favorable, and conversely fewer points are provided as certain parameters in the electric power grid are unfavorable, to the production of the desired improvement.

Furthermore, the quantity of resource points provided may vary as a function of a Resource Utilization Efficiency parameter associated with any particular Resource Consuming Device at a Location. For example, in the case where electricity is the resource, a Resource Consuming device may be an air conditioner. The goal of the Program may be to reduce demand on the Resource Delivery System produced by that air conditioner. The air conditioner would have a Resource Utilization Efficiency parameter assigned to it by the Program Administrator (which could conform to a parameter assigned by a third party, e.g. EER ratings), that would be relatively higher if that air conditioner is energy efficient, and conversely would be relatively lower if that air conditioner is not as energy efficient. Thus, the award of Resource Points can provide an incentive to purchase, install and use energy efficient Devices by enabling a Participant to earn more Resource Points under this invention.

Additionally, the quantity of Resource Points provided may vary as a function of an external condition associated with the Location. For example, sensors may be used to detect weather conditions such as temperature, humidity, etc, at a Location. If these weather conditions are “favorable” (as determined by the Rules), then the quantity of Resource Points will be relatively higher; conversely, if the weather conditions are “unfavorable”, the quantity of Resource Points provided would be relatively lower. That is, for the same reduction in electricity demand, more Resource Points would be provided on an extremely hot day than on a cooler day. In addition, external conditions may be determined by market conditions for the Resource (such as the cost of electricity), etc. which would be provided as required. In another example, a sensor may be used to detect phase anomalies on the electric grid that indicate a potential impending failure condition, and an automatic notification of this condition sent to a control at the end-user Location. Resource Points would be awarded for the timely reduction of electricity use at the end-user's Location in response to such a condition.

In all of the above examples, the Resource Points are positive points whereby the total number of Resource Points is increased as a result of the various measurements and calculations. In addition, the present invention allows for providing negative Resource Points whereby a total number of Resource Points is decreased as a result of the various measurements and calculations. This may occur when certain conditions are deemed to be so undesirable such that Resource Points are deducted from the account, such as by the user over-riding an increase in the thermostat set-point for an air conditioning system on a peak demand day such as a hot afternoon in August, during a period when the electricity provider has called for demand reduction (“Demand Response”) via the dispatch of a Resource Parametric Signal (directive) calling for Demand Response, under a program in which the end-user has previously enrolled and has agreed to participate.

In further accordance with the present invention, a set of Local Rules that relate to operation of Devices at a given Location are established by the Program Participant at that Location, which are implemented in order to satisfy one or more Resource Points Goals of the Participant. For example, the Local Rules may prioritize a minimization of time to obtain a specified number of resource points. This would occur where a participant at the location specifies that he or she would like to earn 10 resource points in the next week (this is an example of a Resource Points Goal). This prioritization condition would be provided in the Local Rules, and the resource system operation would be adapted to enable the participant to achieve this goal (such as by instructing the participant that shutting off certain appliances at certain times would increase the amount of resource points such that the goal is reached) or by automatically implementing such an action as a result of prior permission by the participant. Likewise, the Local Rules may prioritize a given condition such as a maximum comfort level based on Resource Utilization at the Location. This would occur where a Participant at the Location specifies that he or she would like to maintain a comfortable inside temperature, such as a static temperature of 72 degrees or maintaining a limit on temperature change over time (an example of a Local Rule governing a Resource Utilization Device). This prioritization condition would be provided in the Device resource requirements profile, and the Device resource management profile would be adapted to enable the participant to achieve this goal (such as by instructing the participant to maintain the air conditioning on during the day or by doing so automatically with permission or by cycling the air conditioner on and off). As a further example, the Local Rules may prioritize a minimization of cost of resource consumption. This would occur when a participant wants to pay the least amount of money for the resource as reasonably possible, regardless of comfort requirements or resource point requirements as set forth above.

Resource Utilization may be monitored at the Location by monitoring the total amount of consumption or generation of the resource with a single Resource Sensor Device (e.g. a meter) located at the demarcation point between the resource delivery system and the end-use Location. In the example of the Resource being electric energy, electricity usage may be measured at the demarcation point of the Location, for example with a premise's electric meter, and the total electricity utilization would be used to determine the Resource Points to be provided as a function thereof. In the alternative, Resource Utilization may be measured at one or more individual Resource Consuming Devices at the Location, and this information would then be used to determine the Resource Points to be provided. This is a more granular and device-specific approach that would require use of specially adapted energy usage measurement techniques as discussed further herein.

Under this invention, Resource Points may be classified as Primary Resource Points, Derivative Resource Points, Resource Purchase Points or Resource Efficiency Points, and other types of points that may be defined by the Program Administrator in the Program Rules, in order to encourage (or discourage) various Resource Utilization activities, as set forth in the definition section of this specification.

The Program Administrator may also create other types of points that reflect changes in higher order parameters of the operation of the network as a result of activities by Participants (e.g. power quality).

Resource Points that are provided under this invention may be accumulated in an account stored at the end-user Location, or the account may be stored at a service facility remote from the Location, wherein the service facility additionally stores a number of accounts associated with different locations (such as associated with the Program Operator); or the account data may be stored in multiple locations and synchronized between locations. In the first case of local storage, Resource Points might be accumulated and stored in memory associated with a Device such as the Local Resource Monitoring Device. In the case of remote storage, the Resource Points would be tracked by a third party service provider (e.g. the Program Operator), that may or may not be a Resource Provider, wherein the Resource Point information is sent from the Location to the third party via a communication network or the like. The Resource Points may be viewed (e.g. by the Participant) for example at a local terminal such as a computer or other peripheral as described further herein, or they may be viewed remotely such as over the Internet.

Redemption of Resource Points

The Resource Points may be redeemed in various ways, such as (a) in exchange for an item (award or prize) that may be selected or pre-selected by the Participant, (b) in exchange for a reduction in the cost of Resource consumption, (c) for a quantity of a particular Resource as negotiated in a Resource Market, (d) for other types of Points as negotiated in a Points Market, or (e) for cash. That is, a Participant may obtain a reduced electric bill by redeeming Resource Points earned under this invention. Additionally, a third party may negotiate to trade, buy or aggregate Resource Points.

### High-Level Description of the Preferred Embodiment

FIG. 1 illustrates a high level logical block diagram of the system 102 of the preferred embodiment of the present invention. A Resource Provider 104 is shown interconnected to a Resource Delivery Network 106, which in turn is interconnected to one or more End-User Resource Locations 108 (e.g. Location 108-1, Location 108-2, etc.). Resources, which are a form or source of a resource such as electricity, water, oil, air, natural gas, etc., are generated or otherwise provided by the Resource Provider 104 to one or more End-User Resource Locations 108 via the Resource Delivery Network 106. For example, in the case where the Resource is electricity, then the Resource Provider 104 would be the regional supplier of electricity (such as such as the Long Island Power Authority on Long Island, N.Y.), the Resource Delivery Network 106 would be the physical power grid/network that carries, transforms and delivers electricity throughout Long Island, and the End-User Resource Locations 108 would be the numerous homes and businesses supplied with electricity from the power grid. The supplier, the homeowner, business operator and Devices (and their respective software objects and agents) at that Location 108 would thus be Participants in the Program.

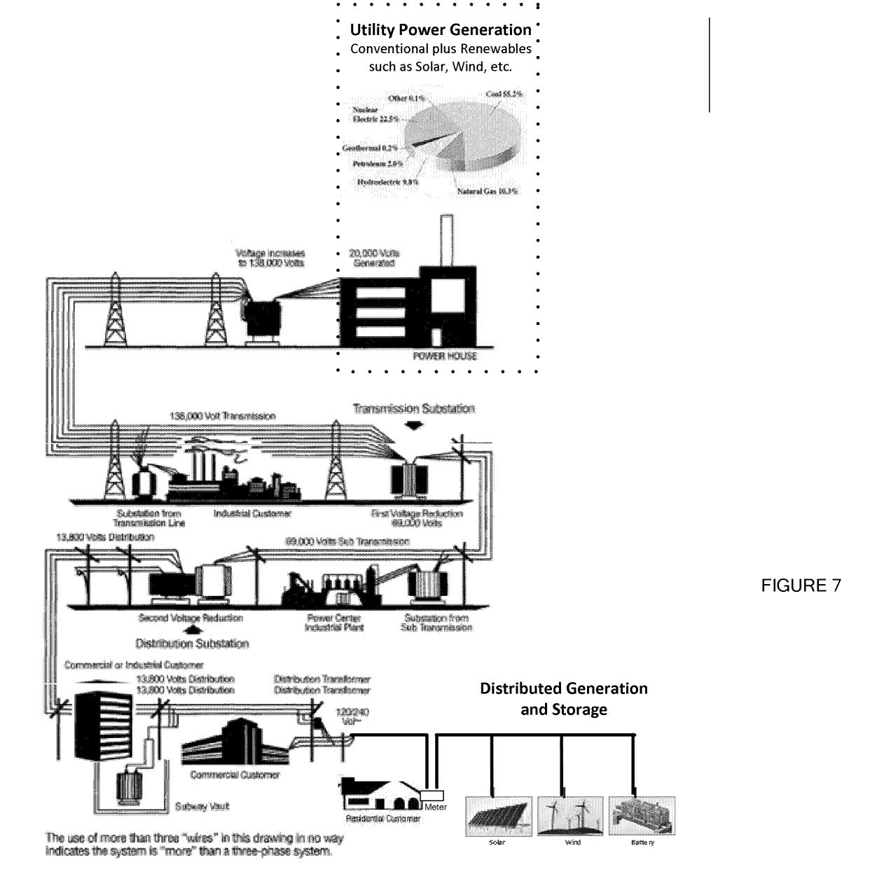

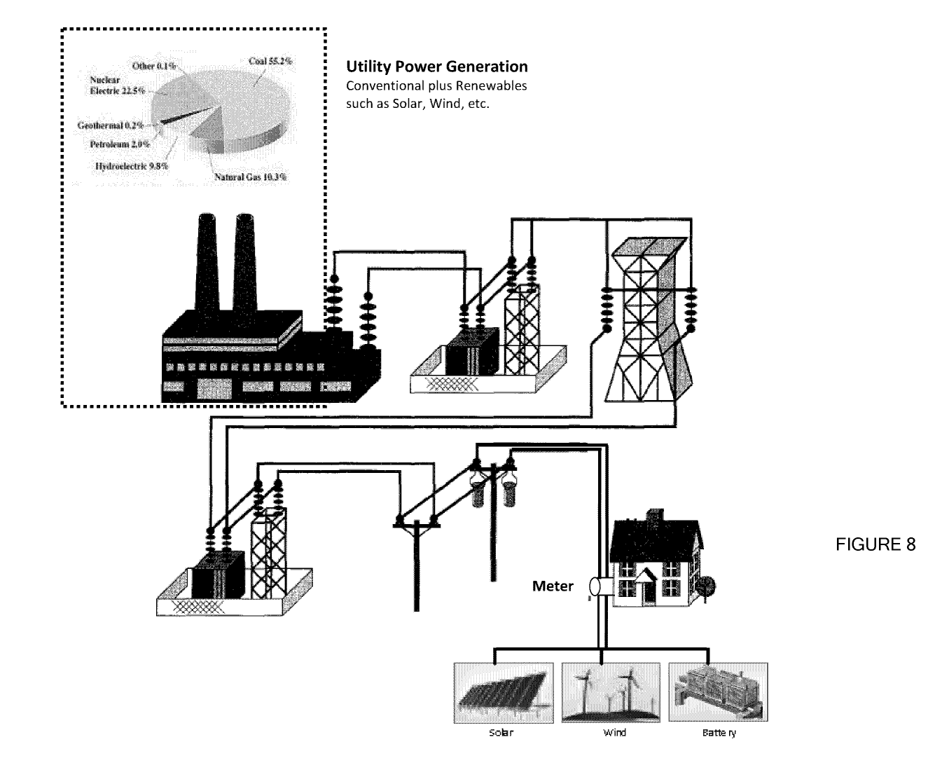

FIG. 6 is an illustration of a typical prior art electrical power distribution system 602. Illustrated is a Resource Provider 104, which is the source of the electricity for the region, and a series of switching stations 604, distribution stations 606, and transformers 608, all of which are known in the art of electrical power distribution. FIG. 7 also illustrates a prior art electrical distribution system that may be used with this invention, wherein the electrical resource is generated and then distributed via various sets of transmission lines, substations, and transformers. This is also illustrated pictorially in FIG. 8. It is noted that although the description of the invention herein is focused on Resource Utilization Devices at an End-User Location, it is understood that the various transformers, substations etc. as shown in these Figures are also considered to be Devices under this invention.

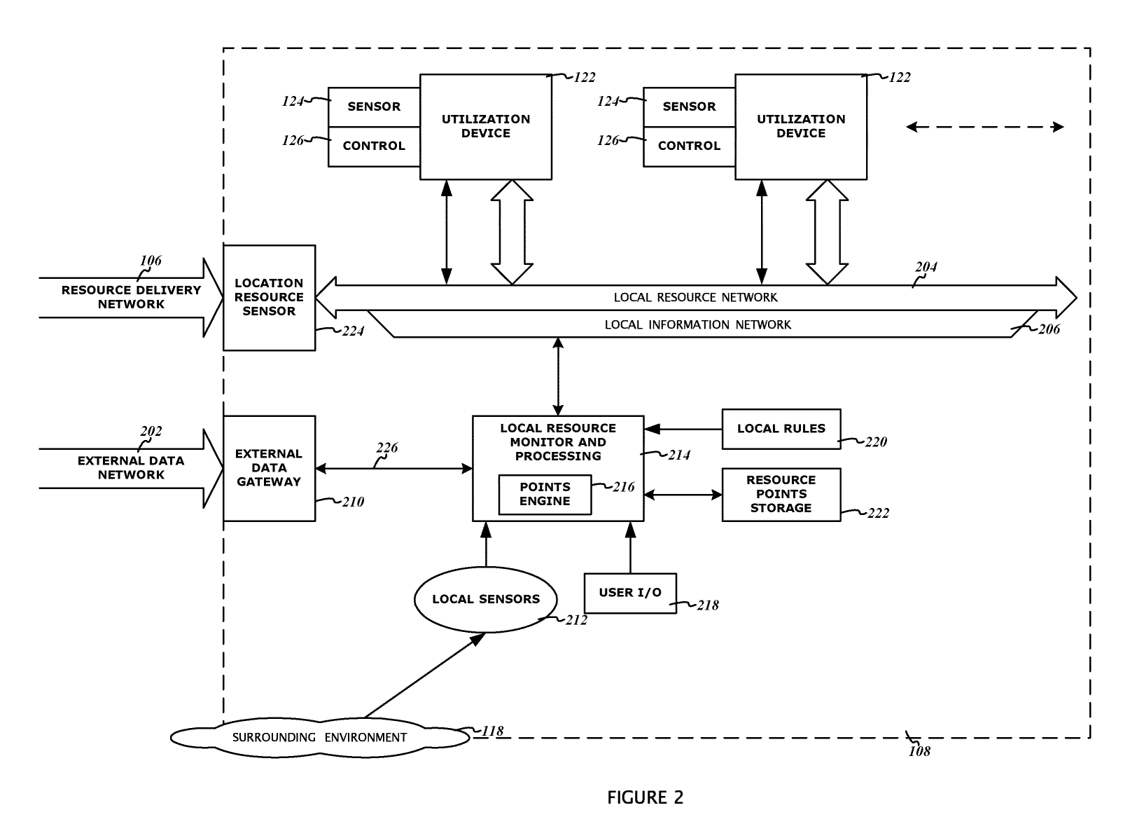

Also shown in FIG. 1 are a Program Administrator 110 and Program Operator 112, each of which interoperates with the system 102 as further described. Each End-User Resource Location 108 will have a Local Resource and Information Network 120 interconnected at a demarcation point 128 to the Resource Delivery Network 106 for delivering the Resource to and from a plurality of Resource Devices (e.g. Utilization devices 122) at the Location 108. In addition, information such as control data and signals may be communicated amongst the various Resource Devices as further described (using for example Sensor Devices 124 and Control Devices 126). The Local Resource and Information Network 120 may be a single network or it may be embodied in multiple networks such as a discrete Local Resource Network 204 (e.g. the electric power circuits) and a Local Information Network 206 (e.g. a wired or wireless LAN such as Ethernet or the like) as shown in FIG. 2.

Within any given market or market area (sub-market), the Program Administrator 110 will set up a Resource Points Program and (among other things) determine the Program Rules 114 governing the type and quantity of Resource Points awarded to Participants for various activities. The Program Operator 112 will administer day-to-day operations of the Resource Points Program in conjunction with the Program Rules 114 established by the Program Administrator 110 and as further described herein.

FIG. 2 illustrates a top-level block diagram for an End-User Resource Location 108 such as a house. As shown, the Resource Delivery Network 106 interconnects with the Local Resource Network 204 at a demarcation point 128, which would typically be an entry point at the building. In this embodiment, a Location Resource Sensor 224 is also shown at the demarcation point, which for example may be an electricity meter when the Resource being delivered is electricity. As well known in the art, an electricity meter will function to monitor the net amount of electricity being delivered to the building from the electric grid. The Local Resource and Information Network 120 of FIG. 1 is shown in this example as two separate physical networks (a Local Resource Network 204 and a Local Device Information Network 206), although both functions may be combined into one network if desired. For example, it is known in the art to be able to provide control data Information signals over power lines to enable distribution of Information without a separate network. Information signals may of course be distributed via a wired Ethernet network, via separate dedicated control wiring, via wireless signals, etc. For purposes of this discussion the control signals may be distributed over a separate physical network or via the local power network if desired. Shown in FIG. 2 is an external data network 202 such as a global data network (e.g. the Internet), which transfers data to and from the Location 108 and other Participants in the system as known in the art.

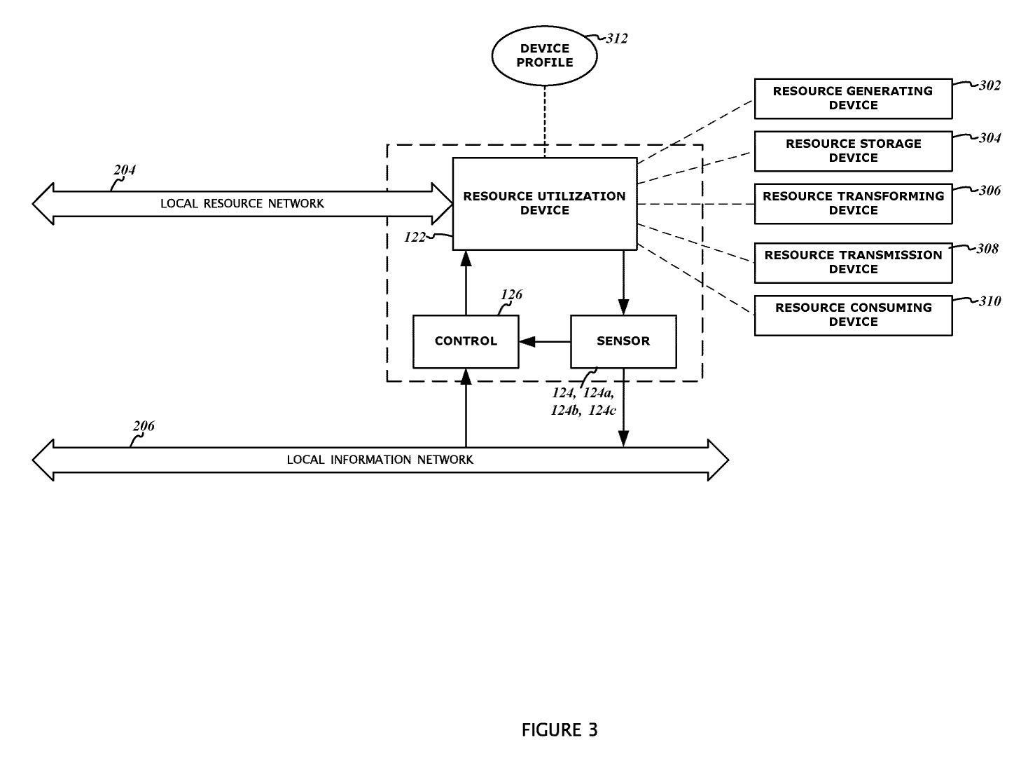

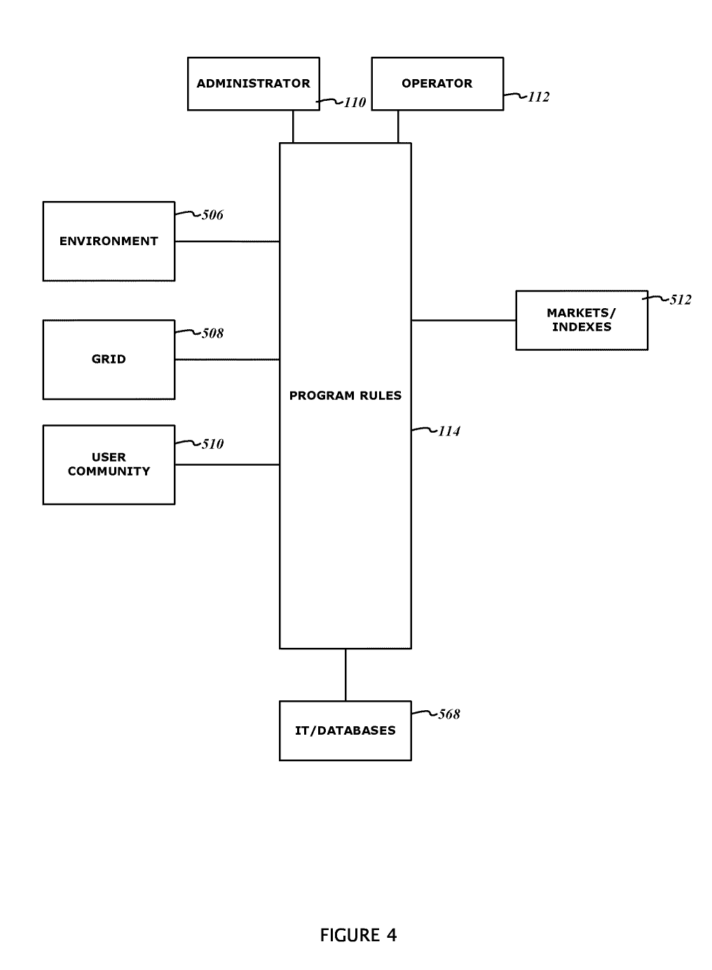

A number of Resource Utilization Devices 122 are shown in FIG. 2 interconnected to the Local Resource Network 204. These Resource Utilization Devices 122 are any equipment that generates, stores, transforms, transmits or consumes a Resource. That is, the Resource Utilization Device may be a Resource Generating Device 302, a Resource Storage Device 304, a Resource Transformation Device 306, a Resource Transmission Device 308 or a Resource Consuming Device 310, as shown in FIG. 3. Any such Device may be physically a combination of any or all of these Devices, but for purposes of this discussion, each Device will be one of these logical types of Devices. For example, a Resource Generating Device 302 may be a gas-fired generator that generates electricity, and a Resource Consuming Device 310 may be an air conditioner. As with all Devices (there are other types that are discussed later), these Resource Utilization Devices 122 may be provided with a mathematical model that may be represented in software as an object (representing the device's operating characteristics or parameters) or agent (representing a desired operating state for a device) together comprising a Device Profile 312. The Device Profile 312 would include a set of parameters associated with that Device that relate to its Resource Utilization, including but not limited to parameters determined by the manufacturer or seller of the Device according to a recognized standard, parameters determined by the Program Administrator 110 or Program Operator 112, and/or parameters determined by the End-Use Participant (such as a device priority or a points goal). All of these parameters may be incorporated in a Device Profile 312. For example, in the case of an air conditioner, the Device Profile 312 may specify the EER or Energy Efficiency Rating specified by the manufacturer of the air conditioner. The Device Profile 312 may be incorporated in a software object that represents the Device, and/or in a software agent that represents the Device in its interactions with other Devices.

Also shown in FIG. 2 is a Local Resource Monitoring Device (LRM Device) 214, which serves several functions to be further described herein (including a Points Engine 216 to be further described below). This LRM Device 214 will be interconnected to the various Resource Utilization Devices 122 via the Local Device Information Network 206 in order to obtain data regarding Resource Utilization by those Devices (referred to as Resource Utilization Parameters). For example, a Resource Consuming Device 310 such as an air conditioner may consume X amount of electricity, and that information is provided to the LRM Device 214 for analysis and processing. Similarly, the LRM Device 214 might effect control of the air conditioner by sending a control signal to it (or an associated Control Device 126) via the Local Device Control Network 206 as shown. For example, in response to a Resource Parametric Signal 226 indicating price or demand in excess of a defined threshold, the LRM Device 214 might issue a command to reduce the power consumed by the air conditioner by turning down its controls. Such data is provided to the LRM Device 214 from the Resource Consuming Device 310 via a Resource Sensor Device 124 associated with that Resource Consuming Device 310, and similarly control data is provided from the LRM Device 214 to the Resource Consuming Device 310 via a Resource Control Device 126 associated with that Resource Consuming Device, as will be further described below.

The Local Resource Monitoring Device 214 may also be interconnected to one or more local sensors 212 in order to collect data regarding the local surrounding environment 118 of that Location 108. For example, a local sensor 212 may be a thermometer located on an outside wall of the building at the Location 108, which will enable the LRM Device 214 to obtain the outside temperature conditions at that Location 108. Similarly, the LRM Device 214 is connected to an external data gateway 210, which in turn is connected to an external data network 202 such as the Internet. This will enable the LRM Device 214 to obtain various types of external information, such as Resource market and price information. This will also be described further herein.

FIG. 3 illustrates a more detailed block diagram of the Resource Utilization Device 122 of FIG. 2. A Resource Utilization Device 122 may interoperate with a Resource Control Device 126 and/or a Resource Sensor Device 124. The Resource Control Device 126 operates to effect control of how the associated Resource Utilization Device 122 utilizes the Resource. Thus, in a simple case, the Resource Control Device 126 for a Resource Utilization Device 122 that is an air conditioner may operate to control the temperature setting of the air conditioner such that it can reduce the amount of electricity consumed by the air conditioner (Resource Utilization Device) by raising the temperature setting via raising the setpoint on a thermostat, turning off a load control on the compressor, or other control mechanisms on individual zones or the overall system (collectively “Resource Control devices”), and conversely it can allow an increase in the amount of electricity consumed by the air conditioner by lowering the temperature setting via lowering the setpoint on a thermostat, switching a compressor load control to “on”, or using similar controls within the system. The Resource Control Device 126 may physically be embedded within the Resource Utilization Device 122 or it may be physically separate from the Resource Utilization Device 122; for purposes of further discussion it will be considered to be logically separate from but interoperable with the associated Resource Utilization Device 122.

The Resource Utilization Device 122 may also interoperate with a Resource Sensor Device 124 as shown in FIG. 3. The Resource Sensor Device 124 operates to measure, monitor or calculate the utilization of the Resource (the Resource Utilization Parameters) by the associated Resource Utilization Device 122. Thus, in a simple case, the Resource Sensor Device 124 for a Resource Utilization Device 122 that is an air conditioner may measure the amount of electricity consumed by that air conditioner. The Sensor Device 124 would then provide a measurement data signal to the Local Resource Monitoring Device 214 via the Local Device Information Network for subsequent analysis. This is referred to as a Communicating Sensor 124a since it can communicate the measurement data to other Devices, in particular to the LRM Device 214. The Resource Sensor Device 124 may physically be embedded within the Resource Utilization Device 122 or it may be physically separate from the Resource Utilization Device; for purposes of further discussion it will be considered to be logically separate from but interoperable with the associated Resource Utilization Device 122.

In addition to or instead of communicating directly with the LRM Device 214, the Resource Sensor Device 124 may also be a Smart Sensor Device 124b in that it can measure one or more Resource Utilization Parameters and compare that against a Resource Utilization Parameter or other calculated parameter (such as a temperature rate of change), and as a result of that measurement, calculation and comparison, will communicate a signal directly to a Resource Control Device 126 to automatically implement a change in Resource Utilization. That is, the Smart Sensor 124b may use local intelligence to directly control the Resource Control Device 126 associated with the same Resource Utilization Device 122, as shown in FIG. 3, without requiring intervention by the LRM Device 214. In the air conditioner example, the Smart Sensor Device 124b may be programmed to monitor the instantaneous amount of electricity used (kW demand), or the unit cost (TOU price), total usage over a period (kWh consumption), or total spending for a given period against actual and projected budget, and, if that amount exceeds a certain predetermined threshold, then raise the temperature setting of the air conditioner to reduce electricity consumption. Additional policies (e.g. thresholds) set by the user, such as maintaining comfort, and the occupancy schedule and priority of a given area or device, would all be factored in to the determination of the amount of this change. The award of Resource Points to be awarded for that (behavior) change will express the desireability of the change at that moment from the perspective of the combined participants in the overall resource network. Thus, the use of a Smart Sensor 124b provides a local feedback loop that would not require intervention by the LRM Device 214. A Smart Communicating Sensor 124c is able to communicate the utilization data with the LRM Device 214 in addition to effecting local control of the Resource Utilization Device 122. This is particularly useful in providing Resource Points to the associated Participant, as will be described further herein.

In addition to measuring resource consumption on a per-device basis with individual Sensor Devices 124 as just described, a Location Resource Sensor 224 as shown in FIG. 2 may be used. The Location Resource Sensor 224 is adapted to measure Resource Utilization (e.g. consumption) for an entire Location 108, which may be required when individual Sensor Devices 124 are not available or practical. For example, an electric meter that is located at the demarcation point 128 of a building can easily be used to measure net electricity consumption for that building. This aggregate Resource Utilization information is then provided to the Local Resource Monitoring Device 214 as for subsequent calculation etc. as further described below.

Points Engine

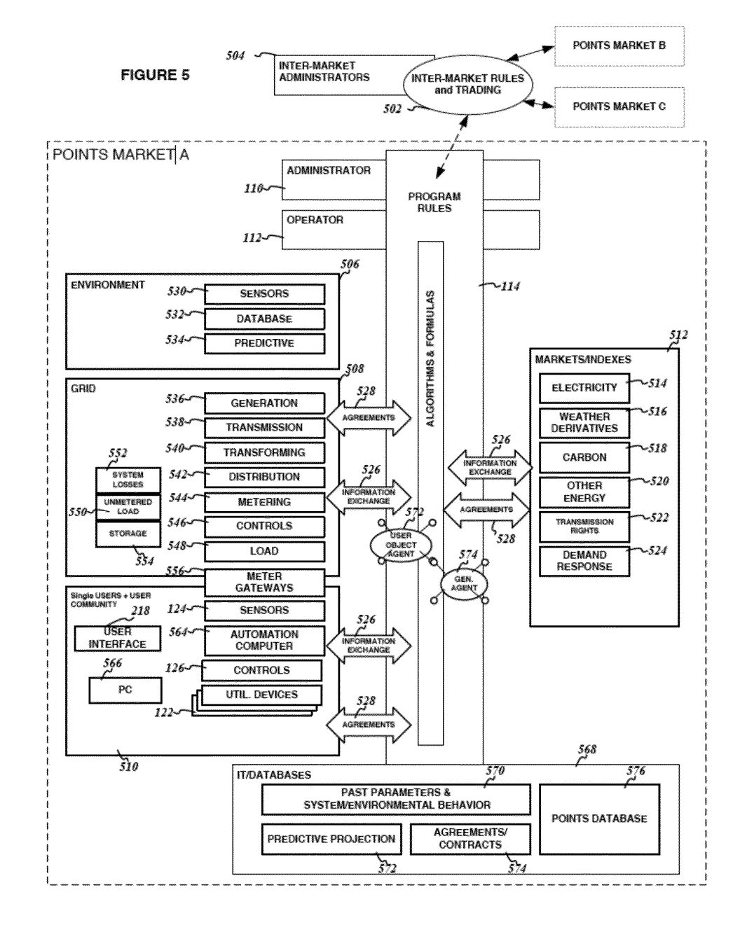

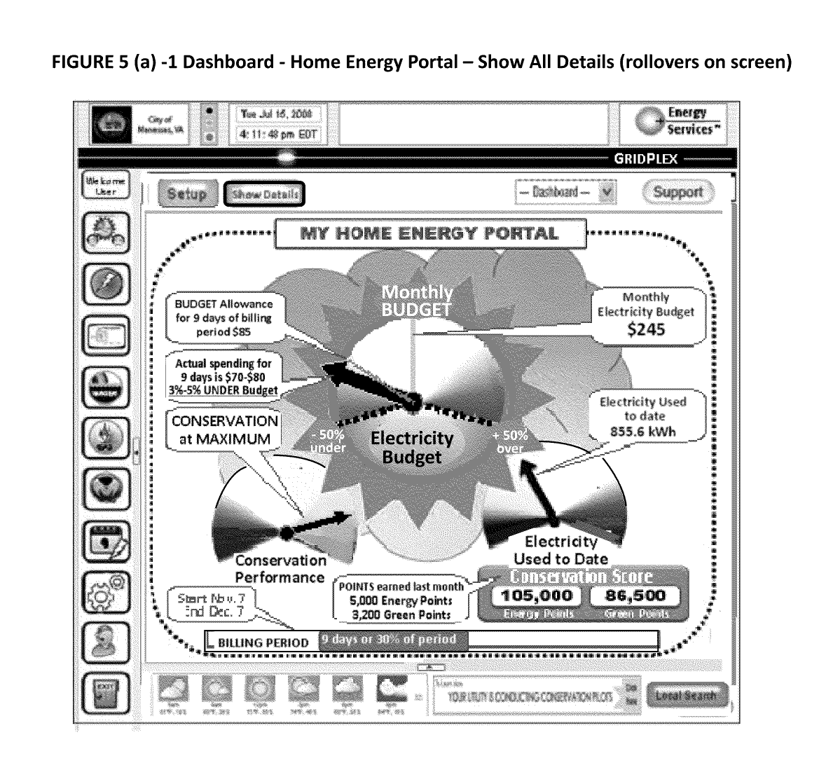

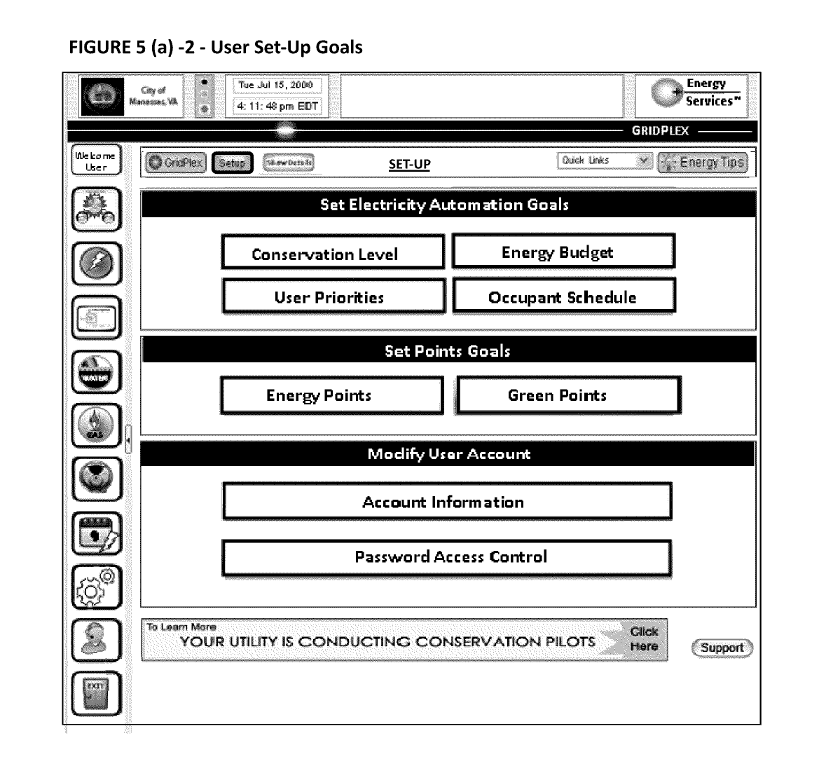

The LRM Device 214 at a given Location 108 also has a Points Engine 216 embedded and/or associated with it. The Points Engine 216 is a computerized system designed to obtain data inputs from various sources such as Local Sensors 212 and Sensor Devices 124, Utilization Devices 122, and other inputs such as market and environmental conditions, and predictions based on the analysis of historical and other data, etc., and to calculate the number and types of Resource Points to be awarded to a Participant at that Location 108 based on various Program Rules 114 and Local Rules 220 and agreements that have been entered into by the Participant. The operation of the Points Engine 216 will now be described with respect to the logic flow diagram in FIG. 5.

Central to the Resource Points analysis executed by the Points Engine 216 are the Program Rules 114 that are established by the Program Administrator 110. These Program Rules are established on a per-market basis, with different markets thus having different sets of Program Rules. FIG. 5 illustrates a detailed embodiment of Points Market A, and similar embodiments exist in Points Market B and Points Market C. There also my be sets of Inter-Market Rules 502 established for inter-market exchanges, which would be agreed to by the participating Program Administrators 110 and overseen by an Inter-Market Administrator(s) 504.

The Program Operator 112 is the entity that runs the associated market and the operation of the Rules 114 by sending various signals, indexes (formulas), negotiations and responses.

The left side of FIG. 5 depicts the various input sources to the Points Engine 216, which are the environment 506, the grid 508, and the user 510. The right side of FIG. 5 depicts the various markets and indexes 512 associated with this analysis, including for example an electricity market 514, weather derivatives 516, carbon markets 518, other energy markets 520, transmission rights 522, and a demand response index 524.

Information Exchanges 526 occur between the various inputs such as the grid 508 and the users 510. In addition, users may enter into agreements 528 with the Program Operator 112 with respect to a User response to a signal they may receive from the Program Operator (the Demand Response Signal).

In the environment block are sensors 530 and a database 532. The sensors 530 provide current measured data from the environment, and the database 532 is a repository of historical data from previous samples. There may also be a predictive model 534 that provides predictive analytics regarding environmental patterns, changes, etc.

The grid block 508 illustrates the various factors associated with the grid (Delivery Network), which may be defined as mass providers of electricity and aggregators (entities that sell or manage electricity at more than one Location). Variable parameters associated with the grid and its subsections include but are not limited to location, time, criticality, vulnerability (i.e. old wiring), and volatility (i.e. rise and fall of demand).

The major parameters associated with the grid include resource generation 536, transmission 538, transformation 540, distribution 542, metering 544, controls 546 (e.g. switching capacitors in and out of the grid), and the load 548 (which includes everything on the user side of a meter, i.e. at an End-User Location). Other factors to consider with respect to the grid include unmetered loads 550 (such as cities with streetlights and the like), system losses 552 due to operation of the grid, and resource storage 554 associated with the grid or at other participant locations.

The user community block 510 refers to any number of users from 1 to n. As shown, the interface between the user community and the grid is referred to as a meter gateway 556. Associated with each user are also the sensors 124 and control 126 at the location, associated utilization devices 122, and an automation computer 564. There is also a PC (computer) 566 and an associated user interface 218 that allows the user to interact with the system using a conventional web browser or similar information and control interface, or even with a remote control and a local interface unit to a conventional TV set (using an unoccupied channel such as “00”). Also shown are the exchange of agreements 528 and an information exchange 526 which interact with the Program Rules 114 as shown.

Shown in the bottom logic block is the database portion 568 of the Points Engine 216. Stored in the database 568 are various past parameters, system behavior and environmental behavior 570. This provides a historical record of system behavior with respect to various weather conditions at given times (e.g. on Aug. 10, 20xx the temperature was 72 degrees and the system operated as follows . . . ). Also stored are predictive projections 572 based on the historical data as applied to defined algorithms designed to predict future results, The database also stores all of the agreements and contracts 574 between the various participants. The database may also store various priorities as may be set by the users, the grid and the environment.

Also stored in the database shown in FIG. 5 is the Points database 576, which is a repository of the Resource Points that have been awarded to or otherwise accumulated by an end user under this invention. As previously mentioned, the account of Resource Points may be stored locally in storage 222, at each user Location 108, or a central repository as shown in FIG. 5 may be implemented. In addition, the account information may be synchronized between the local storage and the central storage so each location has valid information regarding a user's Resource Point account.

Each Device in the present invention may be represented abstractly by an object model, also referred to as a Device Profile 312. The object model is a representation in software of the various parameters including the Device's operating characteristics, goals, priorities, efficiency (rated as well as measured), and impact on power quality. The goals to be achieved for the object model (representing a device or participant) are attempted to be implemented by a software agent that operates on behalf of the object model. As shown in FIG. 5, an agent acting on behalf of an object may be represented by a hub and spoke model, such as the user object agent 572 and the generating object agent 574 as shown. These agents are programmed to negotiate with each other and execute agreements when the negotiations are successful. Each spoke of the agent may represent a term or parameter of that agent, such that matching terms or parameters may link or overlap accordingly. For example, a user object agent may offer to provide X resource points in exchange for 1 KW of power, and the generating object agent may agree to that term (thus their spokes link with each other). Thus, these agents may be considered to interoperate over the applicable network with each other, wherein matching terms and parameter lead to linking of associated spokes such that the interacting agents end up making agreements on behalf of the Devices or participants for which they are agents.

Points Certificates

In addition to earning Resource Points based on certain behaviors in the system, a User in this invention may obtain Resource Points as part of a product purchase. In this case the product may be accompanied by a “points certificate”, which would represent a given type and quantity of resource points. For example, a user purchasing an energy efficient air conditioner may receive a certificate worth 500 points, which may then be added to that user's points account in the same manner as if the user had earned the points for behaving in a certain manner.

Electricity Resource Markets

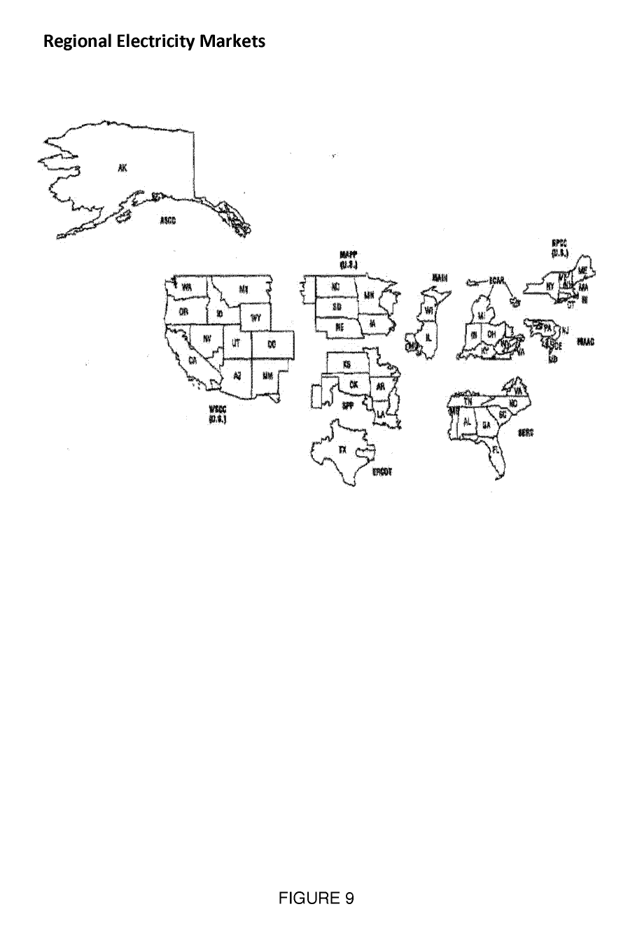

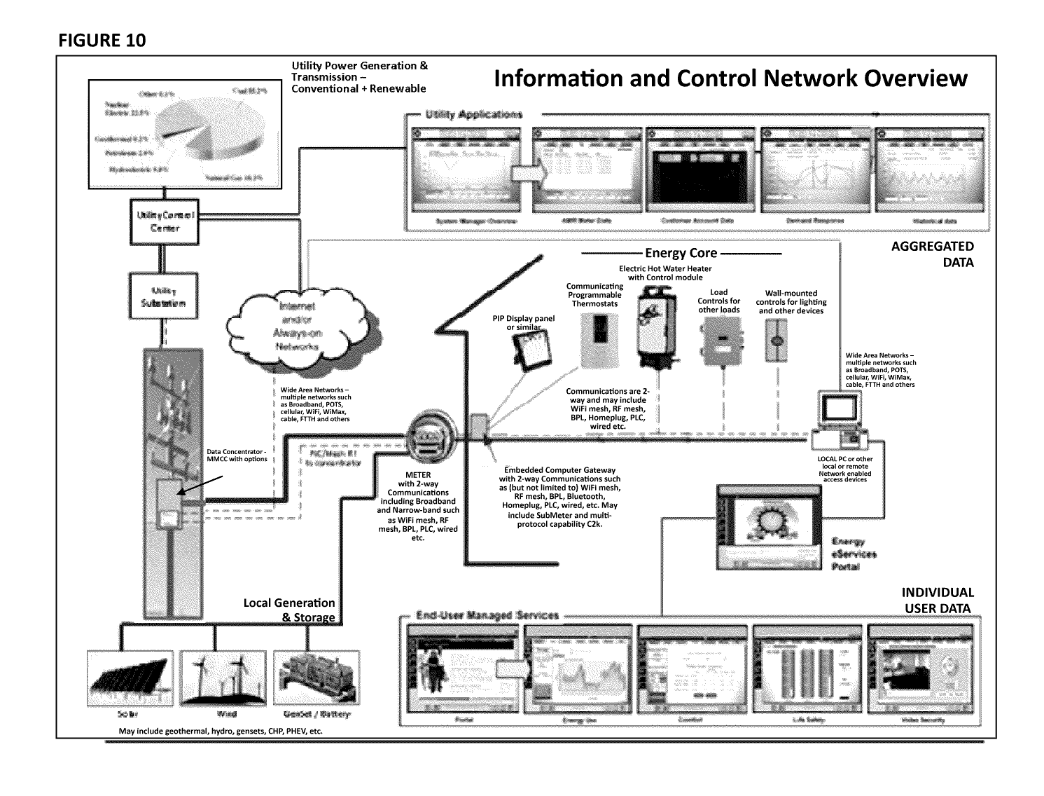

As previously described, Resource Markets may be used as a basis for establishing various Points Programs throughout a large region. For example, with respect to electricity, the United States can be divided into several regional markets as shown in FIG. 9 (“Regional Electricity Markets”). Since the individual States within each region may apply different regulations to utilities operating within their borders, the market regions may be further divided into sub-markets by state. It is contemplated that each of these regional markets or sub-markets may independently operate a Resource Points Program in accordance with the present invention. That is, each market region as shown in FIG. 9 would have its own Program Administrator, Program Operator, Program Rules etc., as shown in FIG. 1. It is also contemplated that each region may elect to interoperate with other regions such that Resource Points from one program may be interoperable (tradable, redeemable, etc.) with Resource Points from another region. Such interoperability would be negotiated for example by the respective Program Administrators, with agreed-to parameters set forth in each set of Program Rules, and executed by each respective Program Operator. Thus, although each region may operate independently, the regions may benefit if desired by offering their customers such interoperability.

### Detailed Example of the Preferred Embodiment

The following is a detailed example of the preferred embodiment implementation of the present invention, wherein the Resource is electricity. The Resource Provider 104 in this case is an electric utility company, which will provide the electricity Resource to the End-User Locations 108 via the Resource Delivery Network 106. The Resource Delivery Network (the distribution grid) will be similar to what is shown in any of FIGS. 6-8. At a given End-User-Location 108, such as a house in a residential neighborhood, an electric meter will be located at the demarcation point 128 between the premises of the house and the electric grid (shown in FIG. 2 as a Location Resource Sensor 224). Although this electric meter will provide overall utilization data based on the net electricity usage of the entire house, there are also several Resource Utilization Devices 122 that have Resource Sensor Devices 124 associated such that the electricity usage may be monitored on a per-Device basis as previously described.

The end-use customer (for example, a homeowner) at the End-User Location 108 will become a Program Participant in the Resource Points Program be entering into a Resource Utilization Agreement with the Program Administrator 110. As previously described, the Resource Utilization Agreement is an agreement between Participants in the Resource Points Program that governs the activities of a Participant's operation of a Resource Utilization Device 122 under certain mutually agreed conditions and/or in response to a Resource Parametric Signal 226 or Resource Parameter Threshold. This will govern the type and quantity of points awarded based on the operation of the Resource Utilization Device(s) 122 under the agreed conditions. In this example, the homeowner agrees to a set of rules 114 that will award him Resource Points if he allows the Resource Utilization Devices 122 (his air conditioners) to be managed by the system.

At this End-User Location 108, an air conditioner in the master bedroom is a Resource Consuming Device 310 covered by the Agreement. This particular Resource Consuming Device 310 has an associated Resource Control Device 126 that is adapted to receive control data from an associated LRM Device 214 (see FIG. 2) in order to control operation of the air conditioner, and an associated Communicating Sensor Device 124a that measures the amount of electricity being used at any given time (the Resource Utilization Parameters) and reports that information back to the LRM Device 214. These Devices communicate with the LRM via a wireless LAN, such as an 802.11(n) network as well known in the art.

The master bedroom air conditioner has a Device Profile 312 associated with it and stored in memory at the LRM Device 214. In this case, the Device Profile 312, which is a set of parameters associated with the air conditioner that relate to its Resource Utilization, contains the Energy Efficiency Rating (EER) of the air conditioner as determined by the applicable U.S. government or other authorized testing agency. The EER of this master bedroom air conditioner is relatively high, which will result in this Device being awarded relatively more Resource Points than would a Device having a lower EER.

In a first basic scenario, it is a relatively hot and humid day in mid-August in the Northeast United States. As the demand for electricity in that region increases, a Resource Parametric Signal 226 is sent from the Program Operator 112 to this End-User Location 108 that indicates that the demand is rising from X to Y. In this example, the Internet is used as an External Data Network 202, so the Resource Parametric Signal 226 is received via the External Data Gateway 210 at the Location 108 and provided via the internal LAN to the LRM Device 214 (see FIG. 2). The processing software of the LRM Device 214 determines from the received Resource Parametric Signal 226 that the demand for electricity (and thus the price) is rising. The processing software analyzes this real-time demand information, as well as the measured electricity usage from the master bedroom air conditioner. The processing software also determines from memory the terms of the Resource Utilization Agreements, which in this case state that the customer has agreed to allow the air conditioner to be raised from 72° to 78° when the demand for electricity reaches Y level. Thus, the processing software of the LRM Device 214 has determined that

the Demand has risen to Y level (in the general case, a parameter is tracked and a threshold is set against that parameter)
the customer has agreed to raise the thermostat of the master bedroom air conditioner from 72° to 78° when the Demand increases to Y level (the event is triggered when the parameter reaches that threshold and a predetermined action is taken).

As a result, the LRM Device 214 issues a control command to the Control Device 126 associated with the master bedroom air conditioner to change the setting of the air conditioner to 78°. As a result, the air conditioner will presumably consume less electricity from that point on. The electricity usage is continuously measured (or sampled) by the associated Sensor Device 124a, and that usage data is communicated back to the LRM Device 214 in a feedback loop. A Verification process will then be carried out, where the LRM Device 214 will “bracket” the data by analyzing:

the electricity utilization after receipt of the parametric signal and just prior to the change in the air conditioner setting, and
the electricity utilization immediately subsequent to the execution of the conservation event in response to the parametric signal and consequent change in the air conditioner setting

Assuming that the electricity utilization (in this case, consumption) has been modified (e.g. reduced) as expected or agreed, then the Verification process will report this information to the Points Engine 216 (see FIG. 5) so that desired behavior may be verified and the appropriate Resource Points (Conservation Points) awarded. The number of Conservation Points will be based on the terms and conditions of the Resource Utilization Agreement. In this example, the Points Engine 216 will award 100 Conservation Points to the Participant, which will be stored in local memory 222 (see FIG. 2). At a subsequent time, the Resource Points information may be synchronized with a central database associated with the Program Operator 112 for record-keeping purposes.

The above scenario implemented an automatic response methodology, where the air conditioner setting was changed automatically by the system based on the pre-existing Resource Utilization Agreement. In another embodiment a user authorization step is required in the Agreement, and will be implemented as follows. Rather than automatically instructing the Resource Control Device 126 to change the temperature setting of the master bedroom air conditioner to 78°, a data message is sent to an associated terminal such as a personal computer or the like having an interface 218 adapted in accordance with this invention (see section User Interface). The user interface, which may for example be a web browser running an interface page from a local web server operating in association with the LRM Device 214, will alert the homeowner (such as with a chime and visual cue) that an operation change is being requested. The homeowner will be requested to authorize the change in temperature setting from 72° to 78° at the master bedroom air conditioner. Assuming the homeowner inputs his acceptance of this requested change, then the air conditioner will be instructed as previously described and the points will be awarded and logged in memory. If the homeowner does not accept this change (for example, he feels it is too hot outside and wants to keep cool), then the air conditioner setting will not be changed and the Points Engine 216 will not award any points, provided that the homeowner has not previously agreed to make such a change. However, if the customer (as a Program Participant) has made a prior Agreement to execute a change when called upon on the receipt of a Parametric Resource Signal, and fails to do so, he may receive negative points (as a penalty) for failing to make the change, or for over-riding the response to the Parametric Resource Signal.

The Verification process is used to ensure that the requested change has actually produced effective results before awarding the Resource Points to the homeowner. In addition, the Verification process will ensure that that someone has not tried to fool the system by allowing the change to be made by the system but attempting to override the settings manually. If this happens, the electricity consumption will not decrease, and the Verification process will indicate that conservation has not been accomplished and points will not be awarded.

User Interface

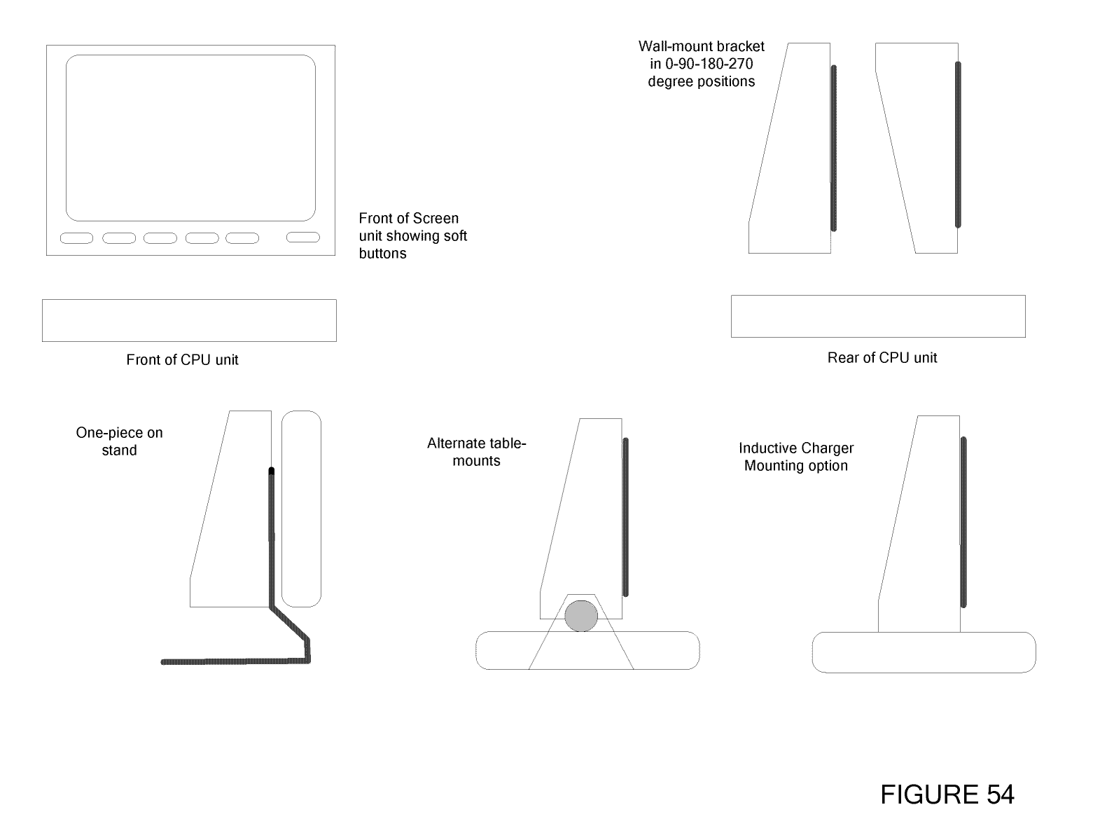

A user terminal 218 such as a computer or other device equipped with an information display (which may be as simple as an indicator light or audio tone, or a more complex display on a portable phone, handheld display, graphical display panel, TV set or computer monitor) may be used in conjunction with the location area information and control networks (or LAN) to enable a user to interact with the system as further described herein (see FIG. 2). The user terminal may also be directly connected to the LRM Device 214 if a location area information and control network (LAN) is not present at the Location. If a computer is used as the user terminal, it may be adapted via a dedicated client software package to interact with the LRM Device, or it may optionally use a browser interface or the like that would communicate with a web server running on or in association with the LRM Device. Use of a web server would enable any standard computer to interact with the system without requiring special adaptation; it would also enable a user to interact with the system with any type of computing platform that can run a web browser such as a laptop, Smartphone (such as an IPHONE), etc. Also, the user would be able to interact with the system in this fashion from any location having access to the Internet. In a preferred embodiment, a personal information peripheral (PIP) is a network-based information appliance that is used to interact with the system. The PIP is a dedicated device having display, sensors and communication devices, as shown in FIGS. 53-54.

In the event that a dedicated device (rather than a computer platform) is used for the user terminal, then there will be an associated display and input device that enable a user to control and receive feedback from the system. For example, the display may include an alphanumeric display suitable for providing short messages, or it may be a screen suitable for displaying graphics and text, or it may include one or more indicator lights such as LEDs, or it may even be an audio device that generates a tone to signal a specific condition, etc. The input device may include a keypad, group of switches, buttons, touch screen, handheld remote control, etc.

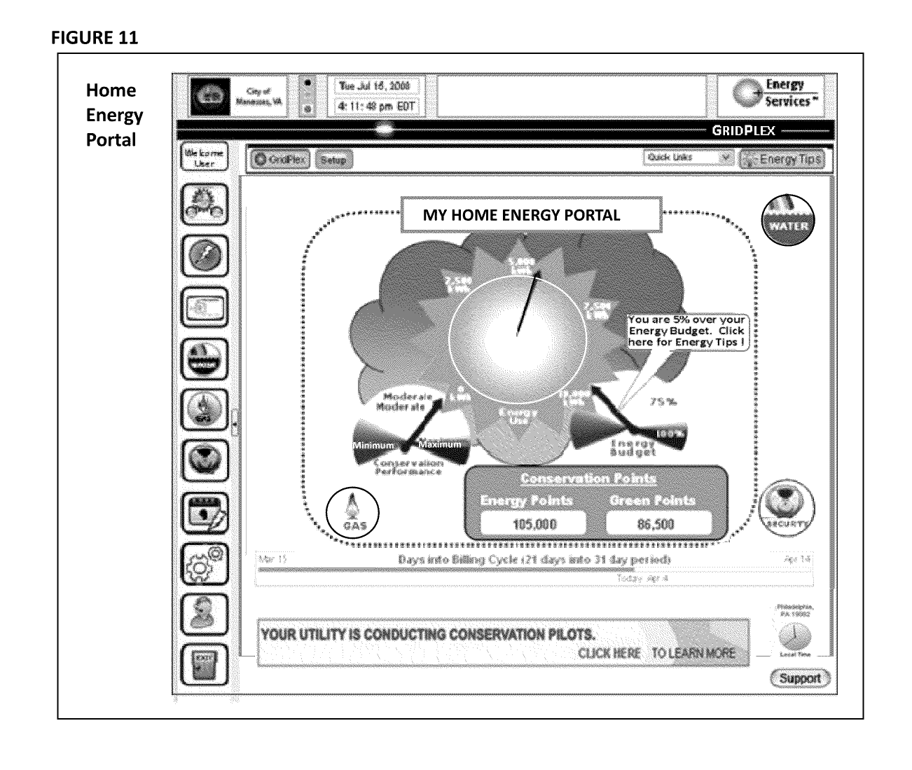

Assuming that a computer running a web browser is implemented in this example, then the user is able to interact with the system as follows. FIG. 11 illustrates an introductory web portal page 1102 (“My Home Energy Portal”) which is a dashboard that would be displayed upon a user logging into the system. This page will provide the user with basic performance information such has total energy use 1104 (e.g. “Your energy usage is 1770.29 kwHr”), relative conservation performance 1108 (e.g. “Your conservation participation level is Moderate”), and energy budget status 1106 (e.g. “you are −10% to −1% of your budget to date”). The page also informs the user how far they are into the billing cycle established by the resource provider. There are also links to an Energy Tips section 1110, that will provide a real-time calculator of projected cost savings for various thermostat setting scenarios, as well as a Bill Analysis section that illustrates the user's bill/payment status.

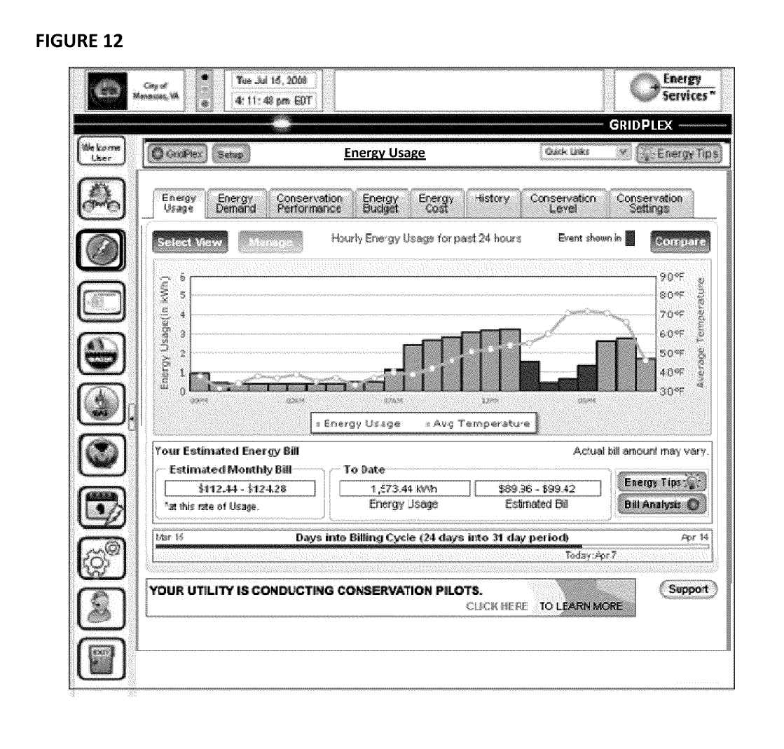

A web page entitled Energy Usage 1202 may be linked to from the Dashboard, which provides several options. First, the energy usage for the past 24 hours may be viewed in graph form 1204 as shown in FIG. 12. This will illustrate graphically the energy usage over time, as well as the average temperature. Energy conservation events, such as the change in the air conditioner settings described above, are also highlighted 1n bars 1206. As can be seen in FIG. 12, the bars from 2 Pm to 6 Pm illustrate that conservation events occurred at these times, and as can be seen although the temperature was rising in that time period the energy usage in kWh actually decreased (due to the conservation event at that time). This provides visual confirmation to the user that the conservation event actually occurred and resulted in less energy usage during that time period. The user is provided with a Select View option 1208 in which he can change the view from daily to weekly or monthly, or change from graphical to detailed view, etc. A Compare option 1210 is also provided that enables the user to compare energy usage, demand, cost, conservation and saving of the present period with a plurality of previous periods, and with predictions based on changes in user-determined setting and other conditions.

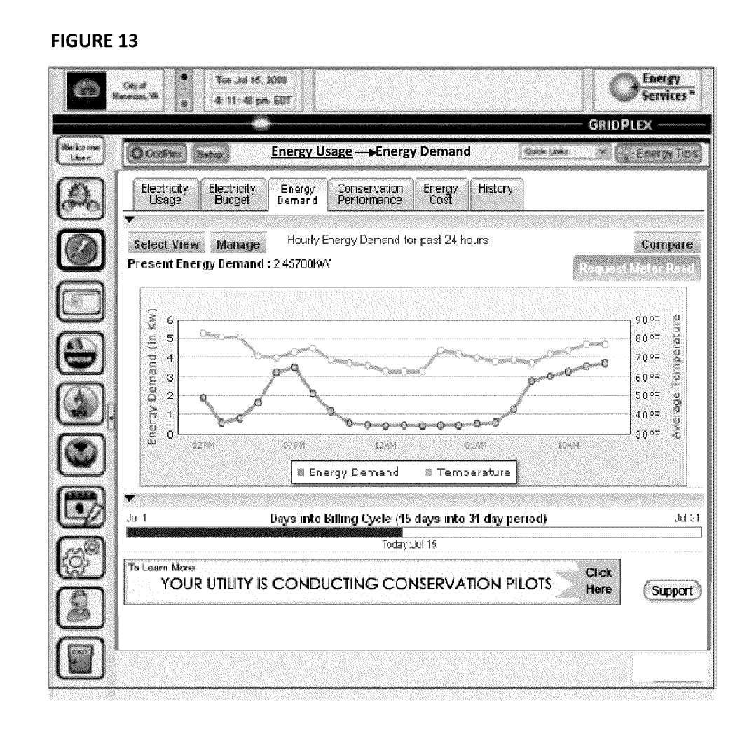

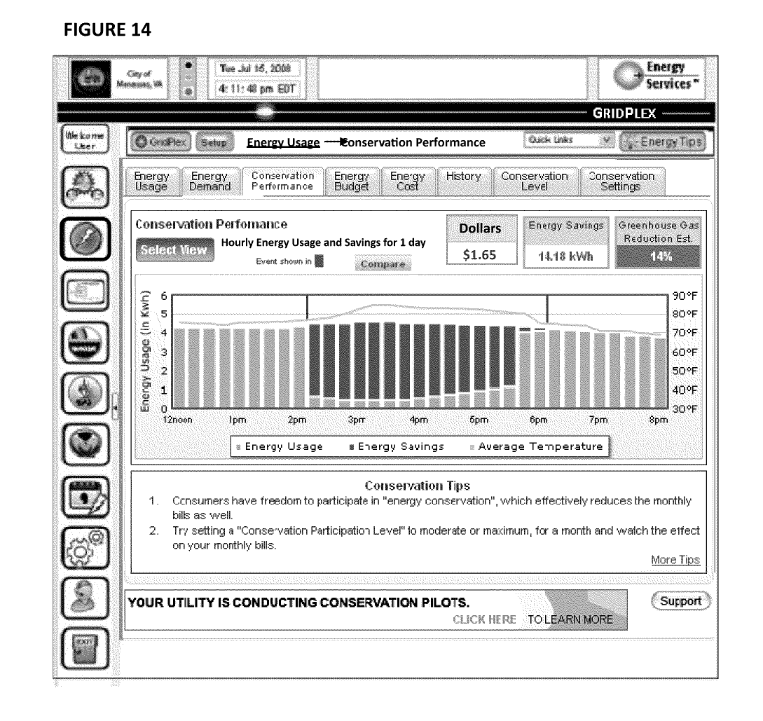

Selecting the Energy Demand option 1212 provides a graph 1302 as shown in FIG. 13. This is a plot of the energy demand in Kw with respect to the average temperature over a given time period, such as one day (or other periods if desired). In FIG. 14, a plot 1402 is provided that graphically illustrates energy usage over a time period as well as projected energy savings, all with respect to temperature. Tables of numerical values may also be selected for display, with a variety of time intervals and different time periods. Total energy savings for that period is calculated and displayed, as well as an estimate in greenhouse gas reduction due to the conservation that took place. An Energy Budget page may be displayed that provides a detailed display of the energy budget data summarized on the Dashboard of FIG. 11.

The user is also presented with an option to set the conservation level settings of the system. For example, in this case the user may set any of the following levels: Maximum, Moderate, Minimum, and None. Setting the desired conservation level will cause the system to operate accordingly. For example, if the Maximum option is set, then the system will operate to provide the most conservation measures, which will likely be at some expense of comfort (such as by causing the room to operate at a high temperature setting, thus providing less comfort but more energy conservation—and more resource conservation points are awarded). Similarly, if the Minimum option is set, then the system will operate to provide the least conservation measures, which will likely provide a higher degree of comfort (such as by causing the air conditioner to operate at a lower temperature setting, thus providing more comfort but less energy conservation—and fewer or no resource points awarded). Users will be able to select their priorities (goals) for each area and the system will operate to move towards the goals within the constraints of possibly conflicting priorities; the award of points will act to mediate such conflicts and influence the user's (or their agent's or device's) behavior in the direction benefiting all of the participants in the network. However such action includes possible “negotiation” or “bidding” between the end-user and the resource provider (and/or their “agents”) concerning the number of points offered or required to implement such behavior. These negotiations may also include “agents” operating on behalf of specific Resource Utilization Devices within the system (the devices themselves may be represented as software “objects” in this scenario).

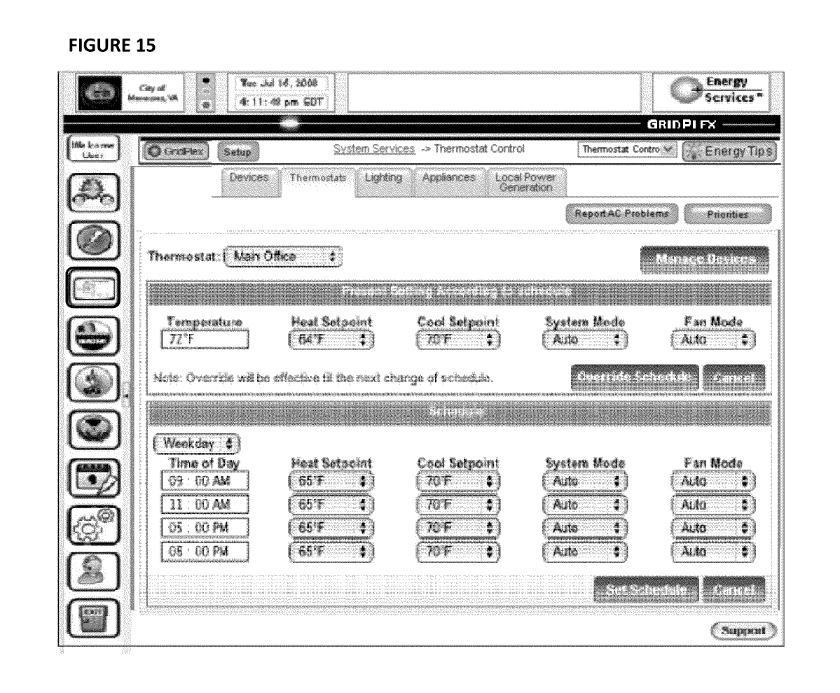

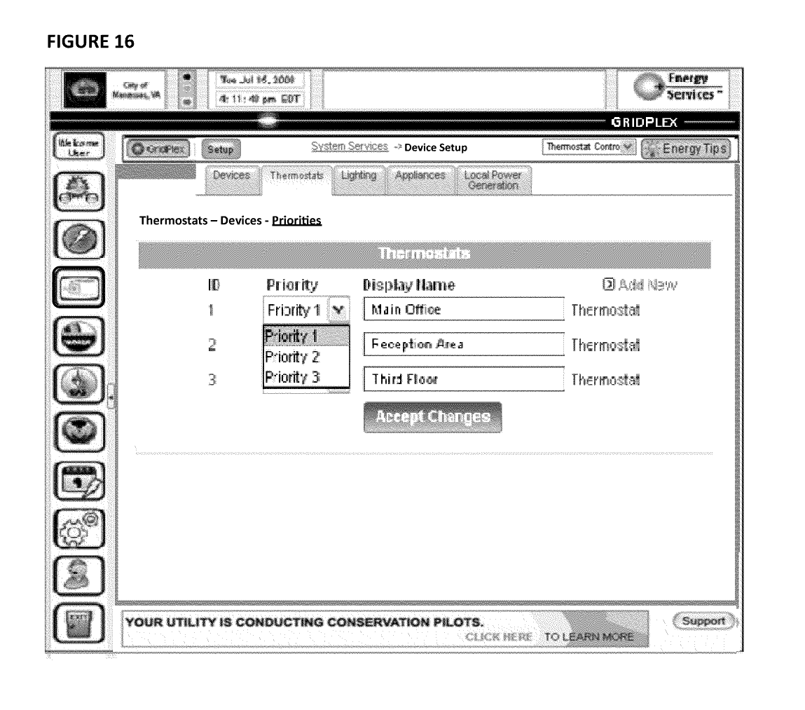

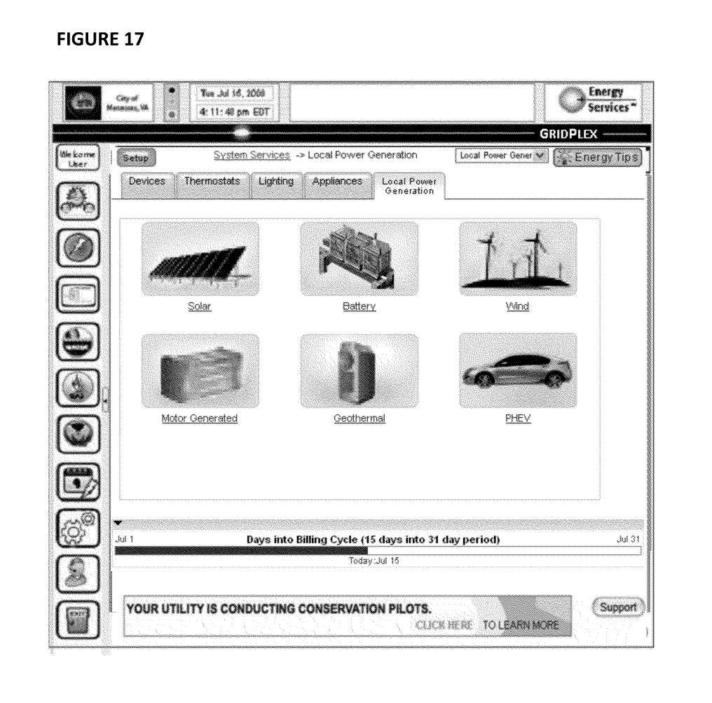

The system includes a set of “Master Set-Up Screens”, where policies may be easily accessed and established across particular systems or subsystems. An individual System Services page may be accessed, which provides several further options for specific devices such as Thermostats, Lighting, Appliances, and Local Power Generation. The Thermostats page 1502 is shown in FIG. 15. Here, the user may select a thermostat Device and enter a desired schedule for settings. In FIG. 15, the Main Office thermostat schedule is shown, and the setpoints may be changed as desired for any time of day. The user may also override the present setpoint if desired. As previously explained, this may result in the Points Engine 216 subtracting resource points from the user's account since it may result in less conservation than previously agreed to (alternatively it may result in the Points Engine adding more resource points to the user's account since it may result in greater conservation than previously agreed to). The user is also given a Manage Devices option 1602 as shown in FIG. 16, in which he can set a priority of devices such as thermostats. For example, as shown, the Main Office and Reception Area thermostats have been assigned to Priority 1, while the Third Floor thermostat has been assigned to Priority 2 (other devices may be added to the listing if desired). A lower priority device (which may be expressed by a larger or a smaller numerical setting, according to the operating convention set in the rules, so that, for example, a “Priority 1 device” may in fact express a “higher priority setting” than a “priority 2 device”) will undertake conservation measures before a higher priority device, based on expected occupancy of the area associated with that device. So, during the daytime, a thermostat in the living area of a house may be assigned a higher priority than a bedroom thermostat, while the converse would be true for the night hours. Similar scheduling control may be provided for the Lighting and Appliance devices of the system as desired. The Local Power Generation page 1702 is shown in FIG. 17. This provides links to setting pages for the available local power generation devices (Resource Generating Devices) 302, such as Solar, Battery, Wind, Motor Generated, Geothermal, Plug-In Hybrid Electric Vehicles (PHEVs) and other Resource Utilization Devices, that may consume, store, transform or generate electricity locally.

Program Administrator/Operator Interface

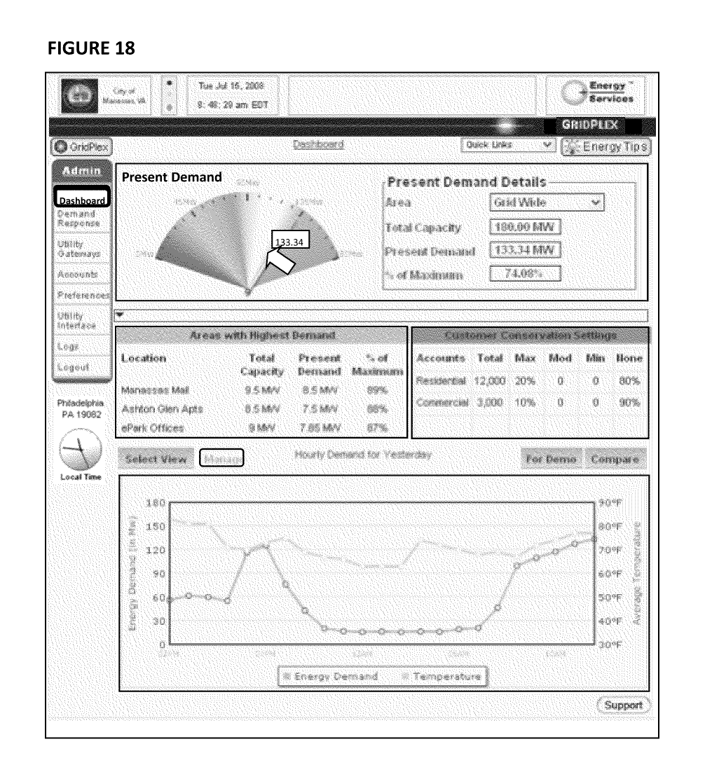

The Program Administrator 1110 and/or Program Operator 1112 may implement an Admin Interface to interoperate with the system as will now be described. In the same manner as with the User Interface, the Admin Interface typically will run on a web browser that enables access to a web server running in association with the Program Operator infrastructure. FIG. 18 shows a Dashboard page 1802 for the Admin Interface. The Dashboard 1802 summarizes various data such as Present Demand 1804, which may be viewed for the entire grid or for any selected component of the grid such as any substation or transformer. Data such as Total Capacity of the grid or component, Present Demand, and resulting % of maximum are also shown. The Dashboard also flags and display areas of possible concern, such as those with most consumption, or areas where maintenance is needed.

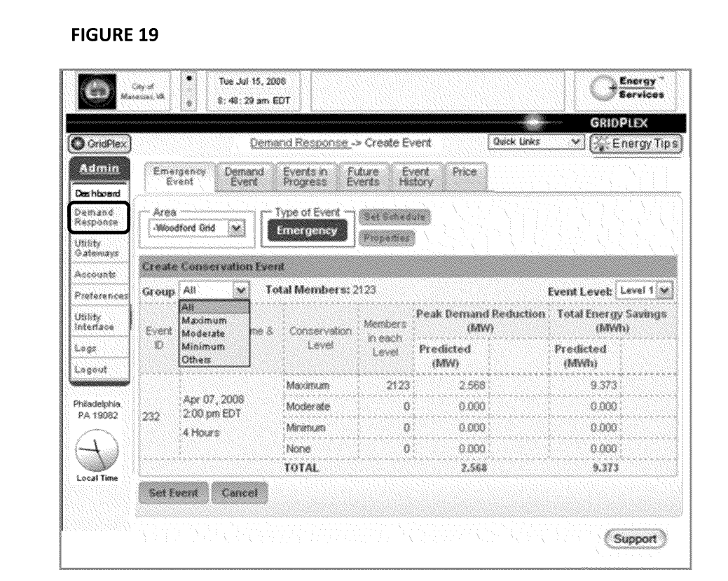

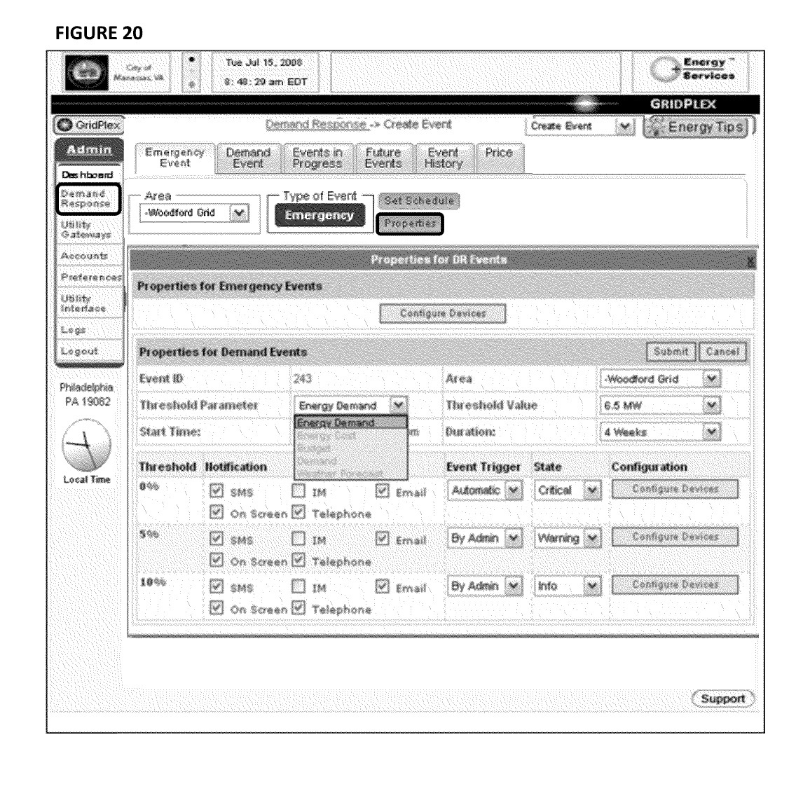

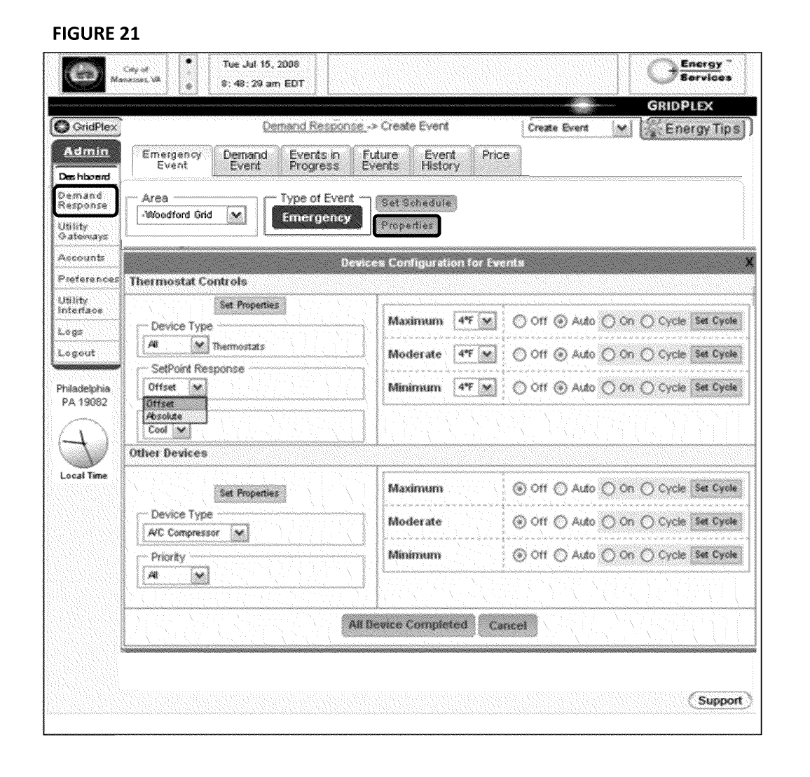

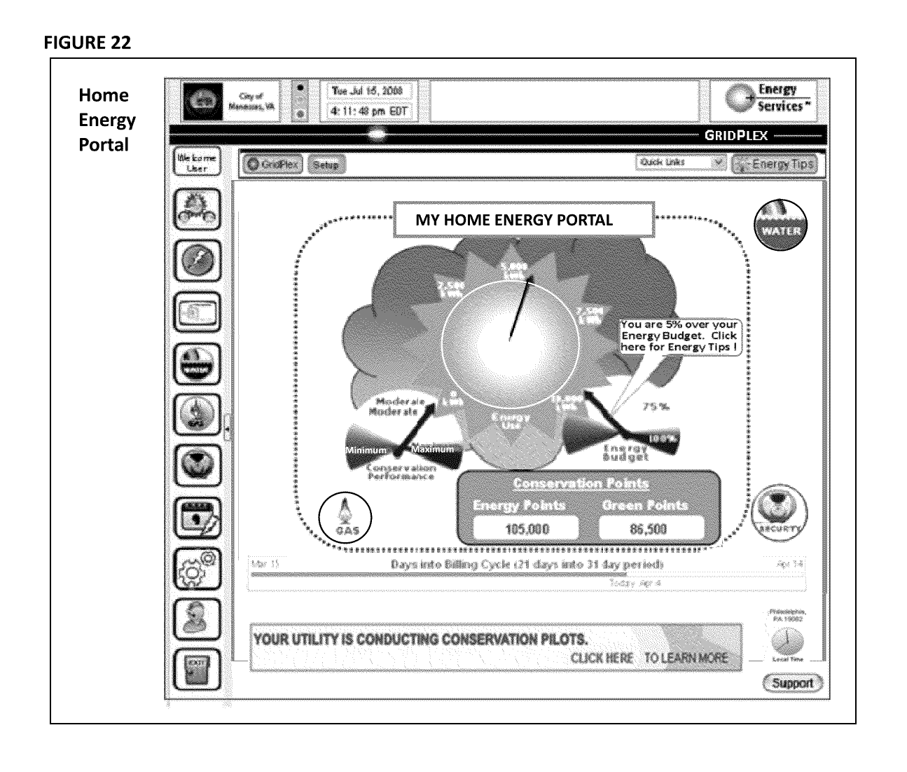

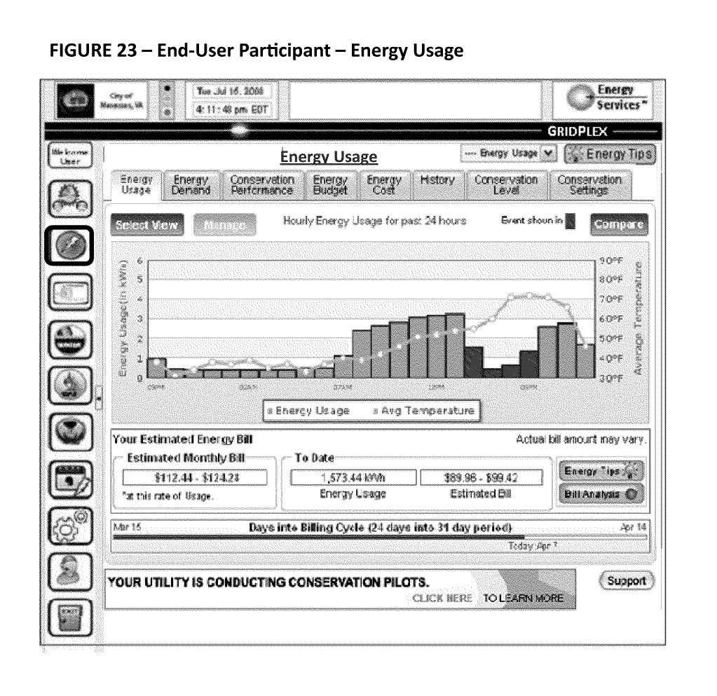

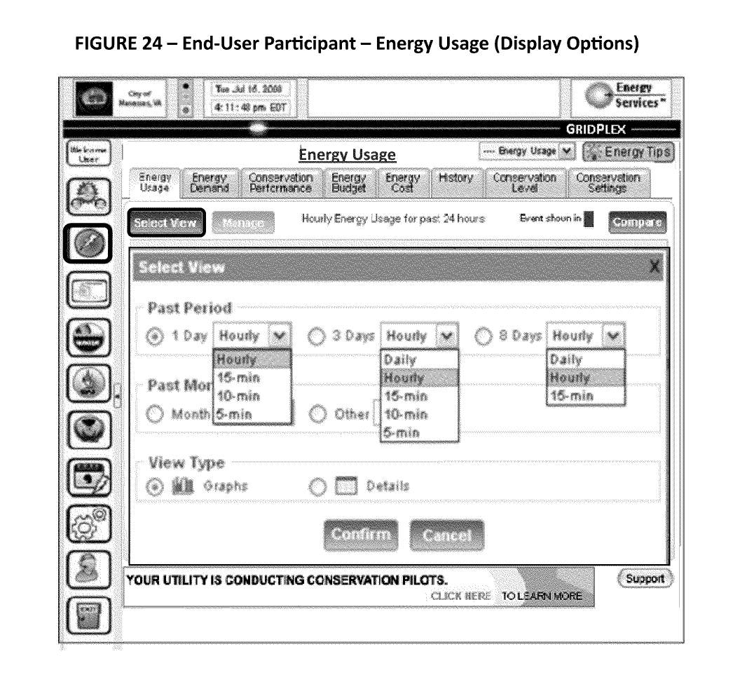

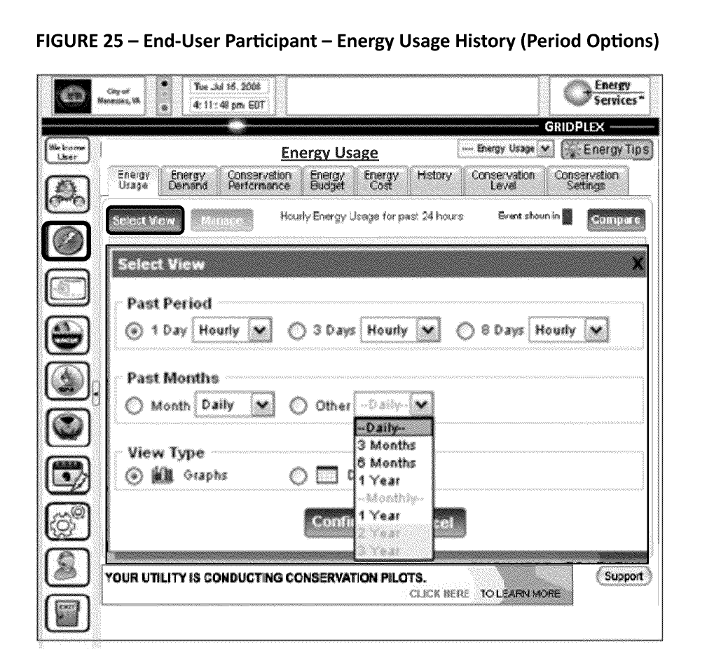

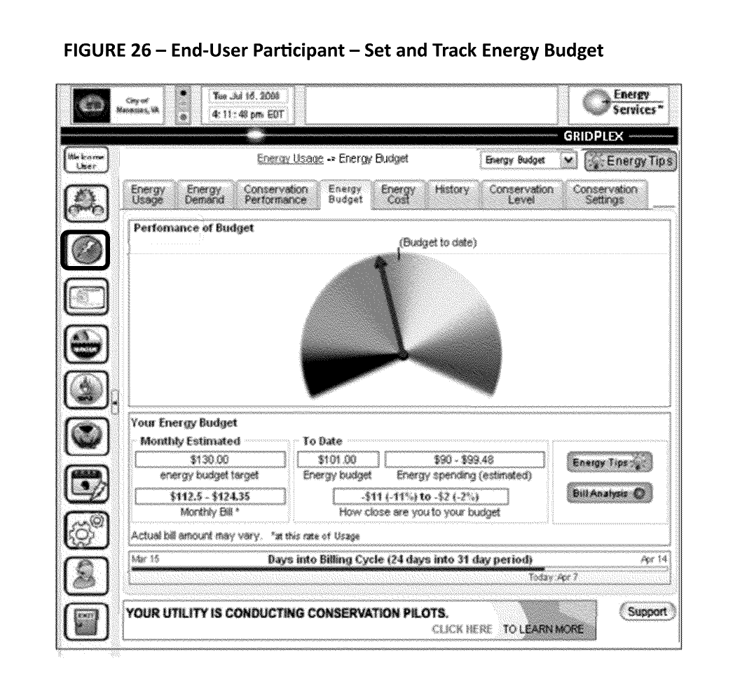

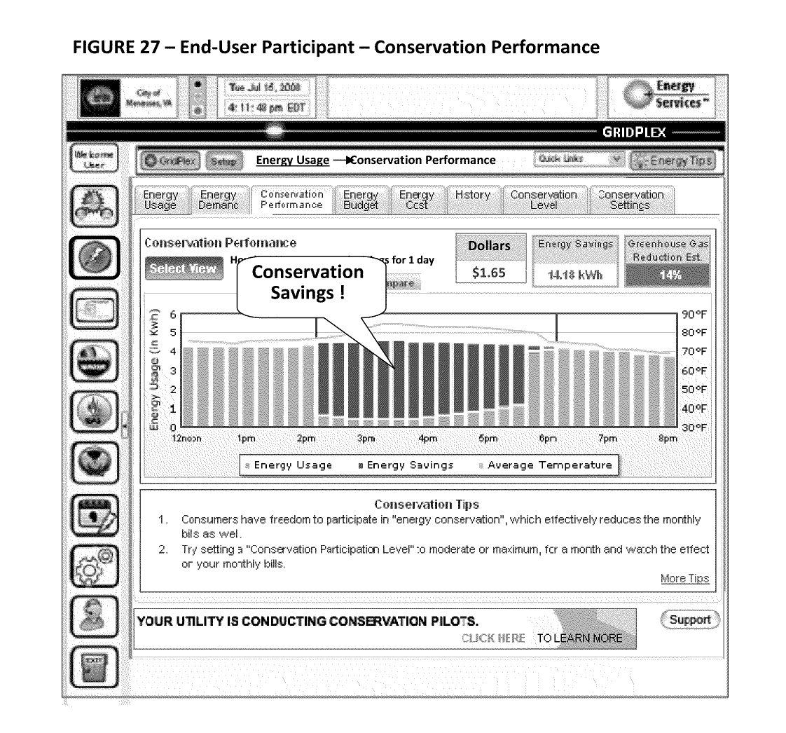

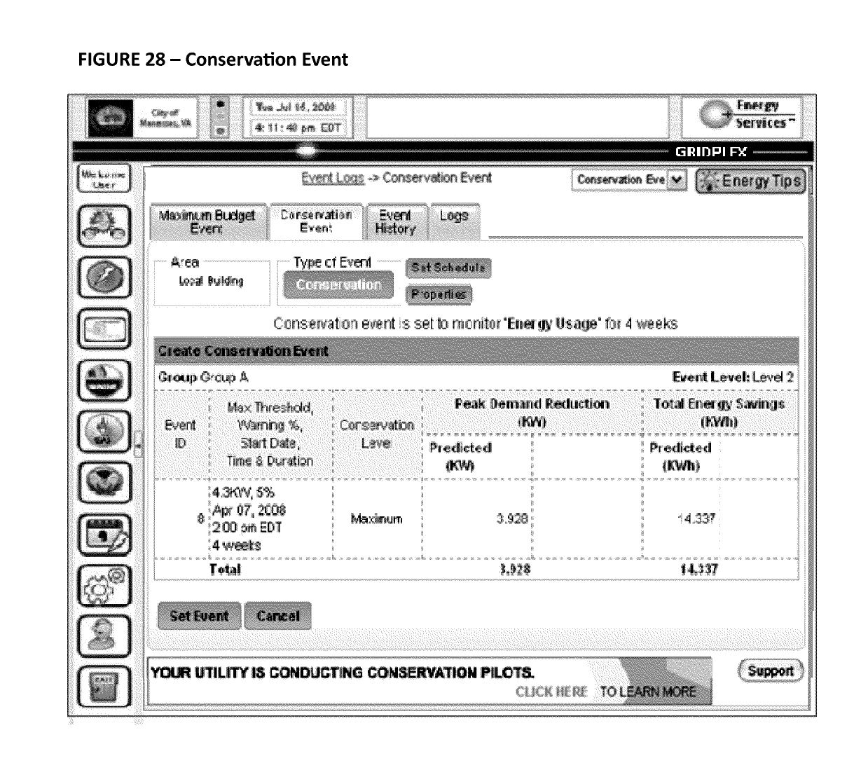

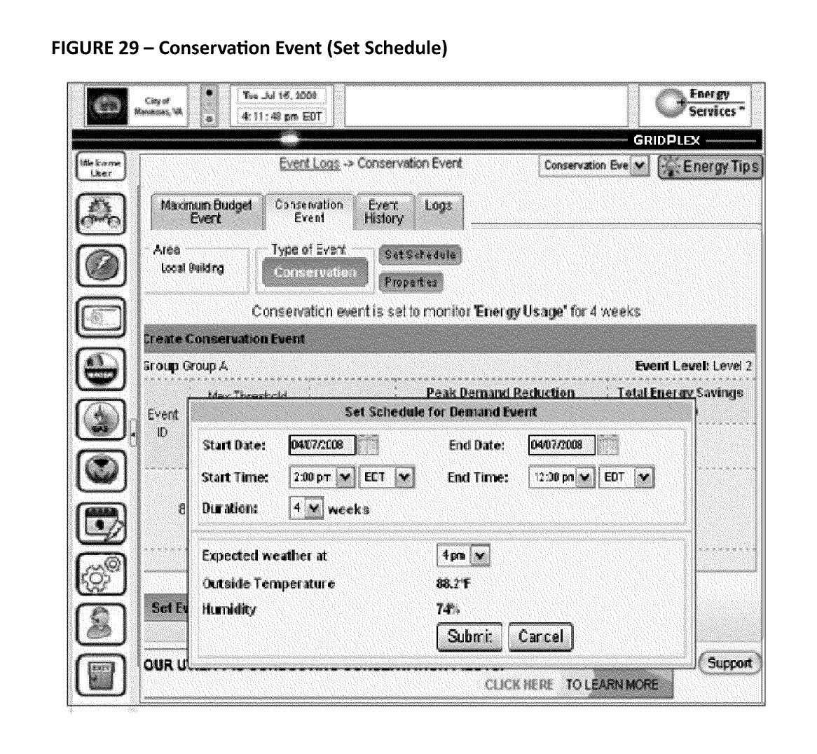

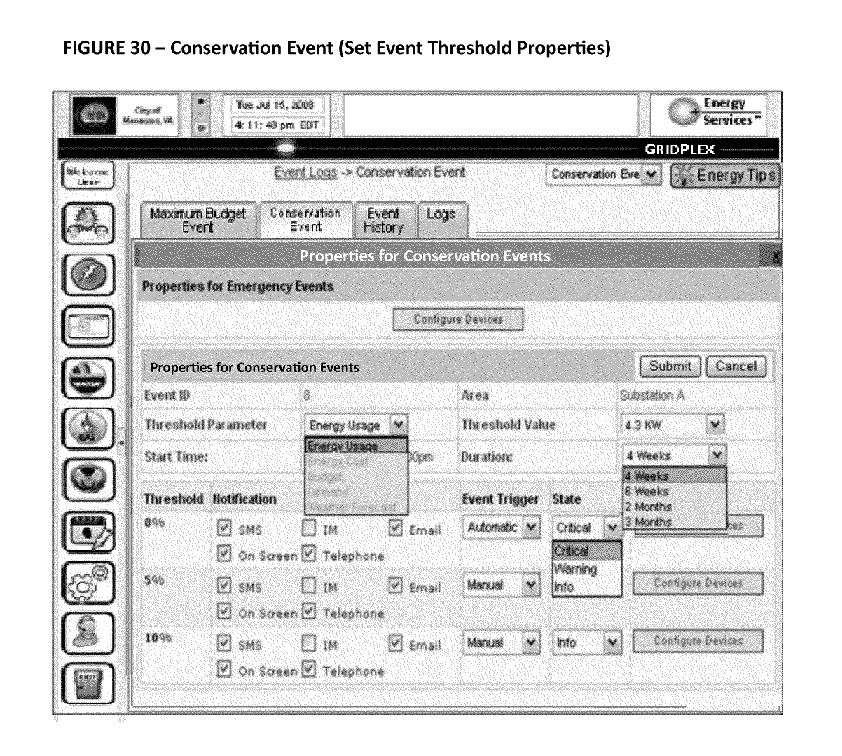

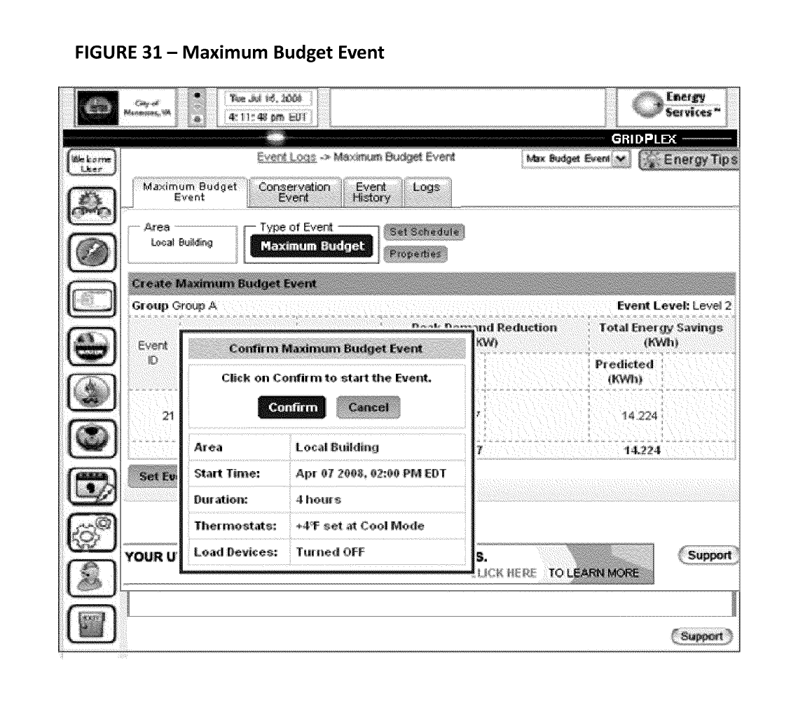

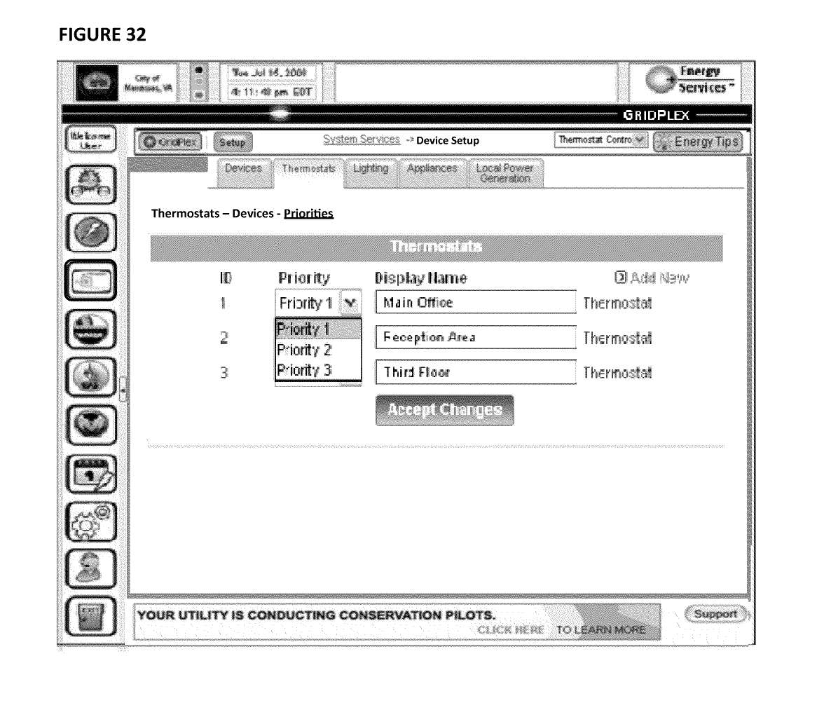

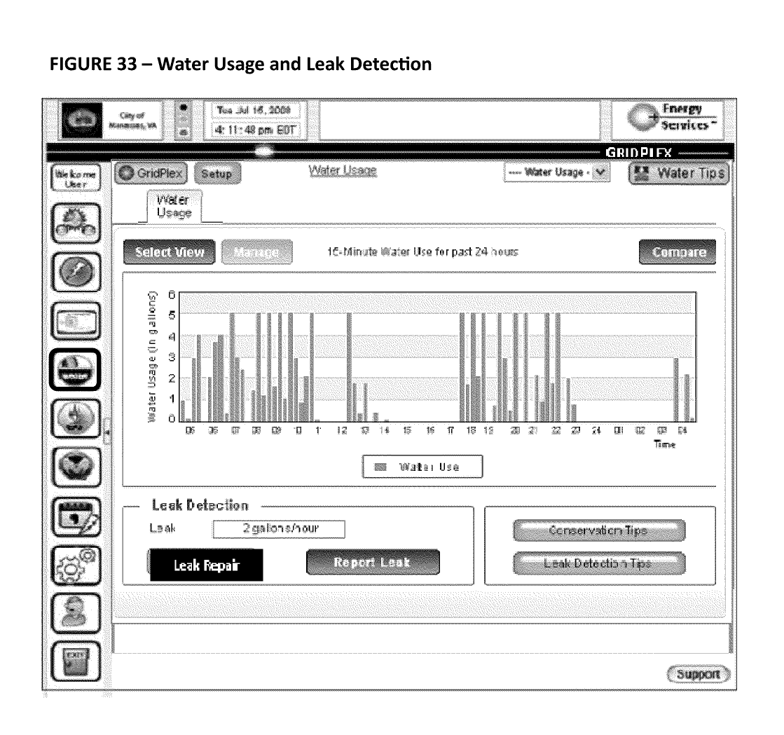

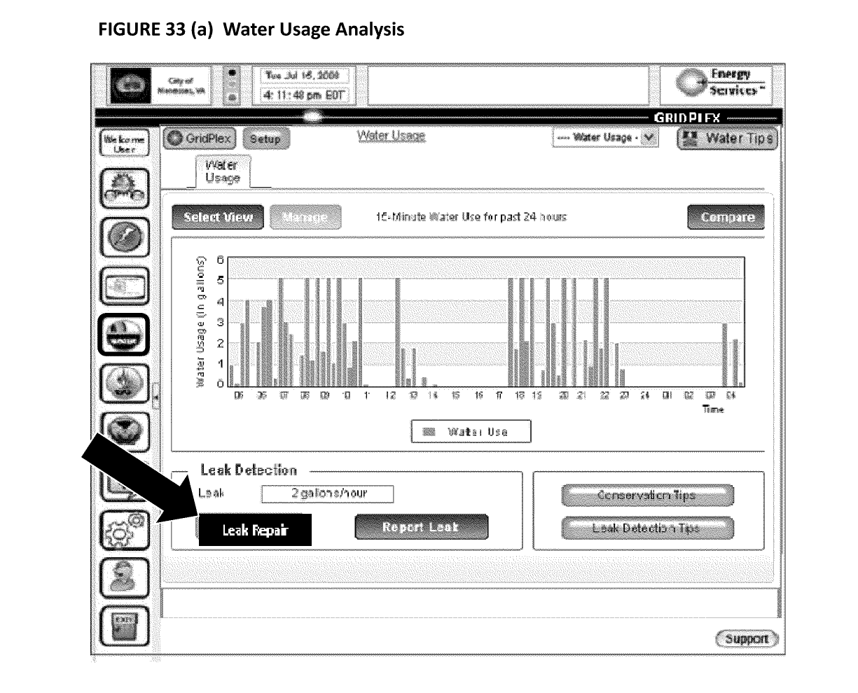

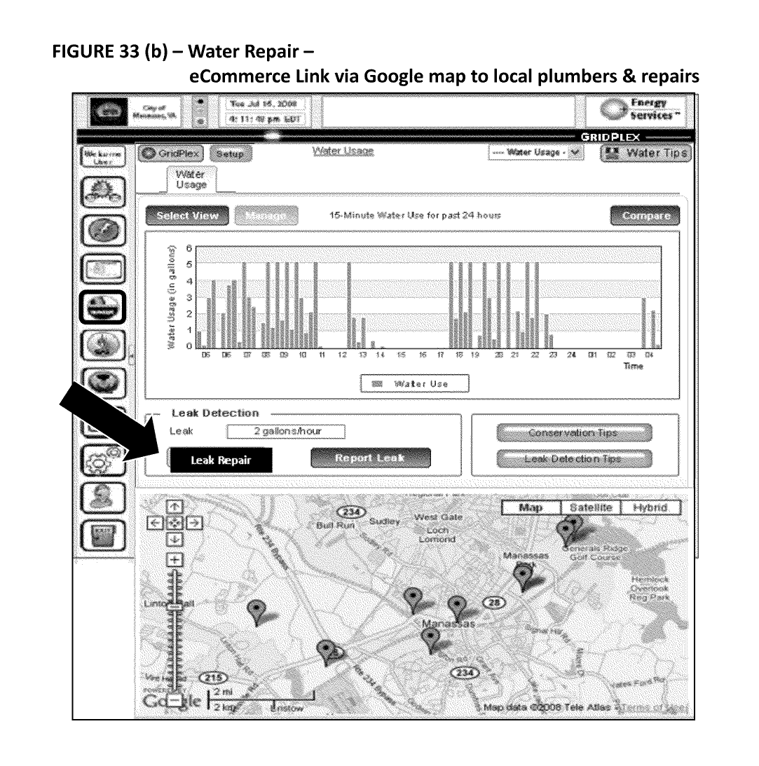

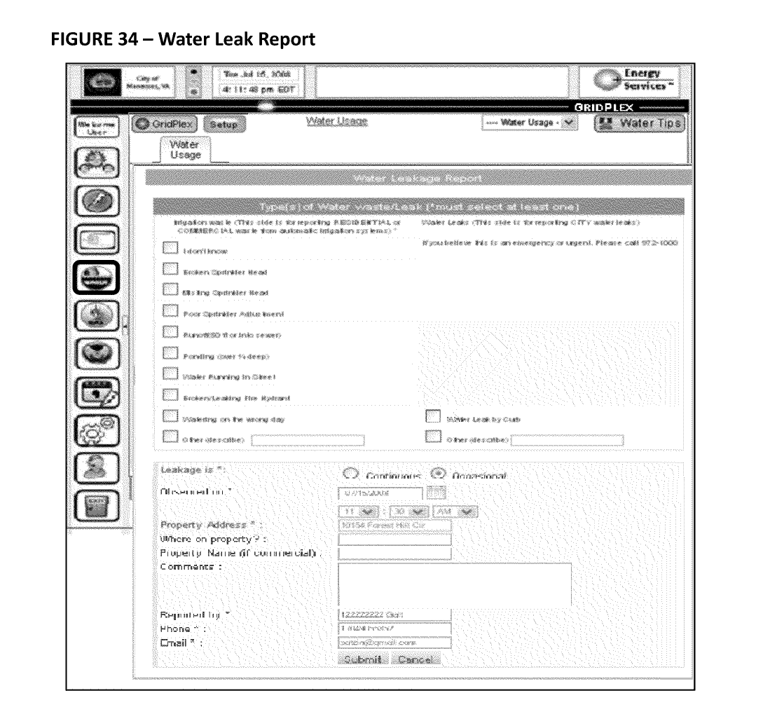

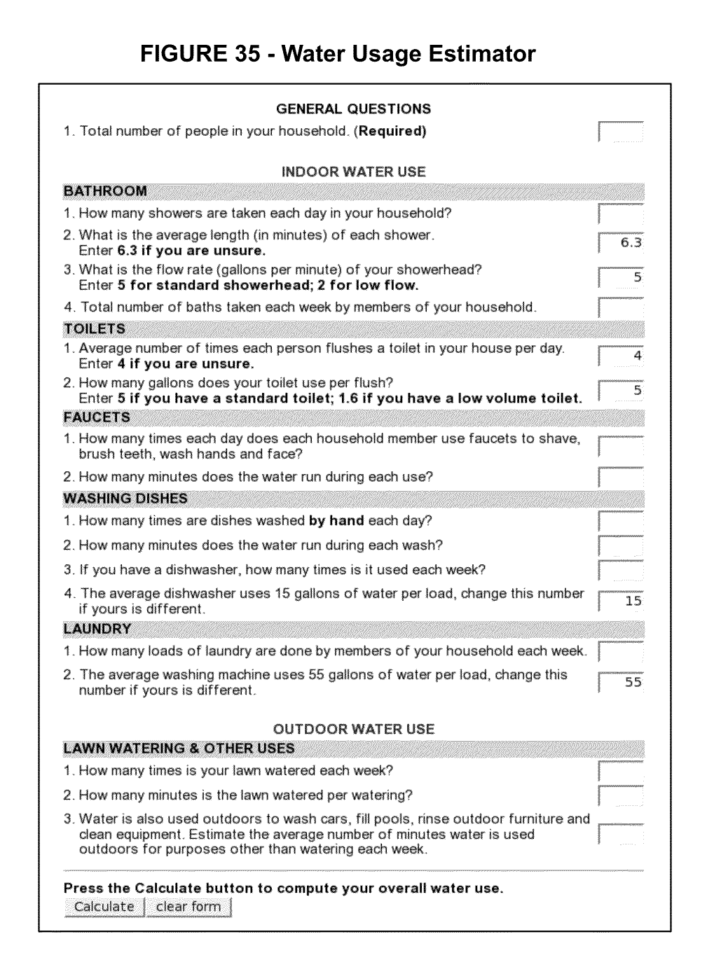

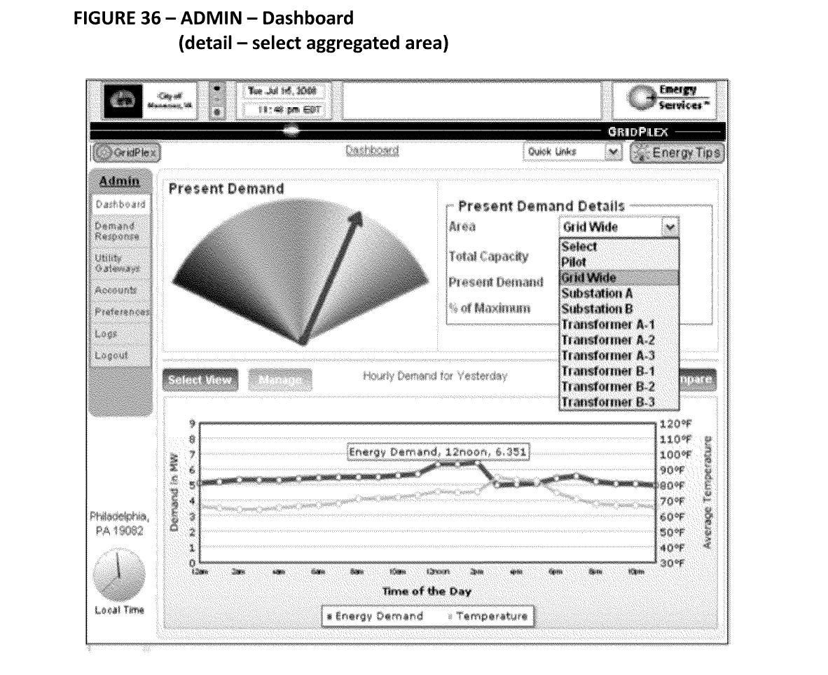

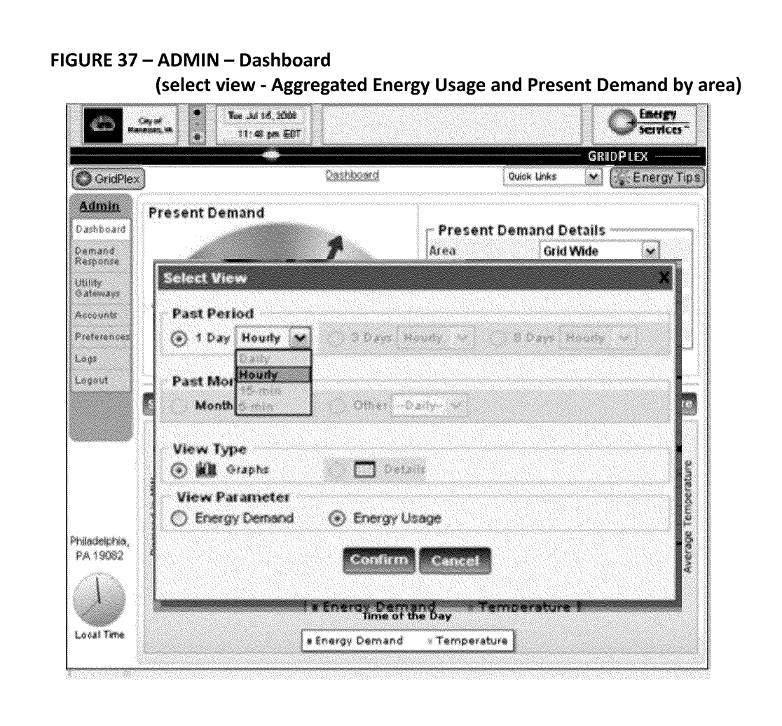

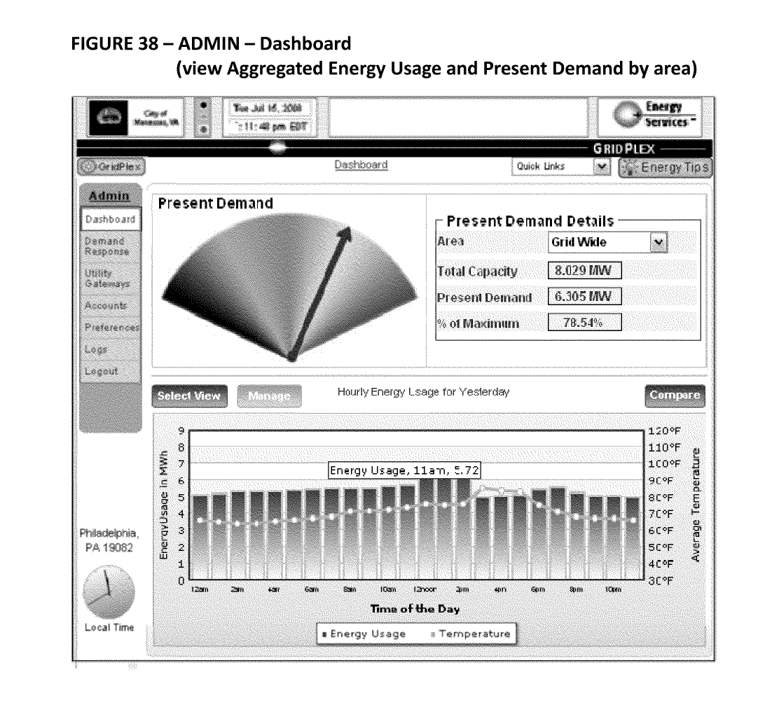

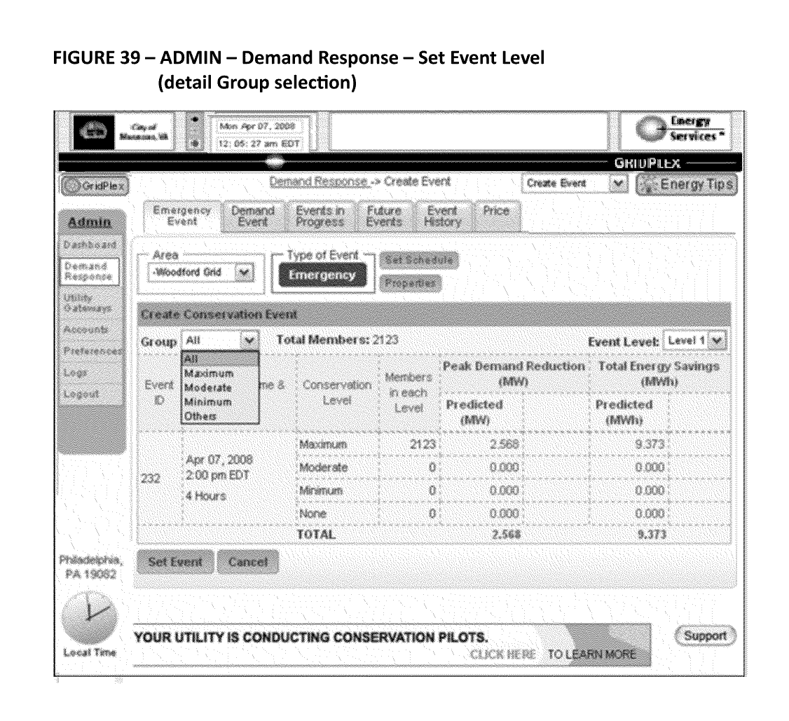

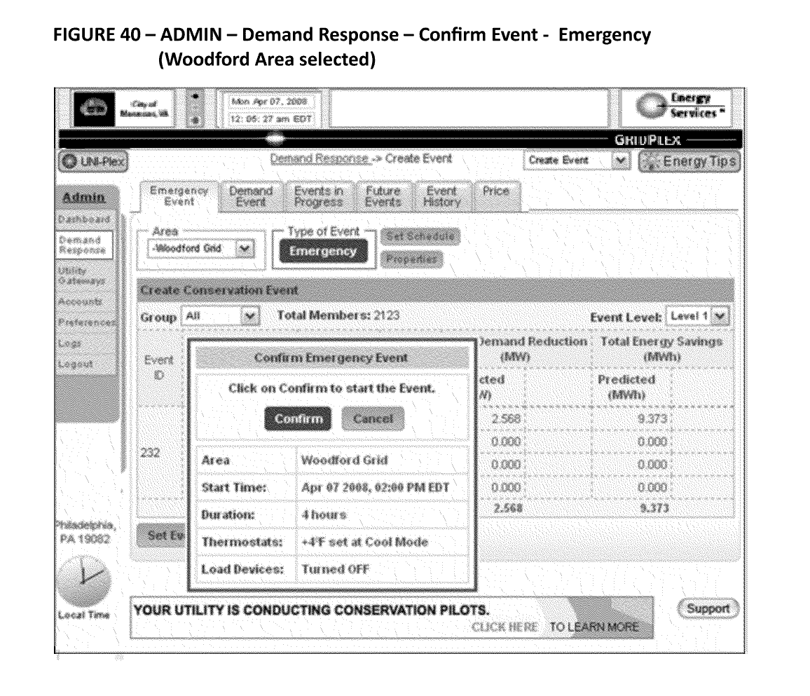

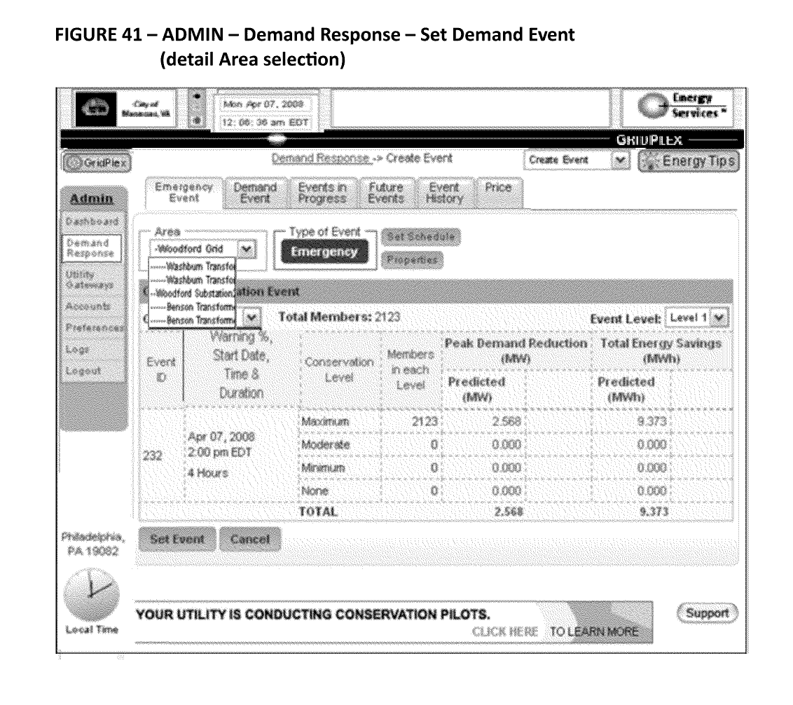

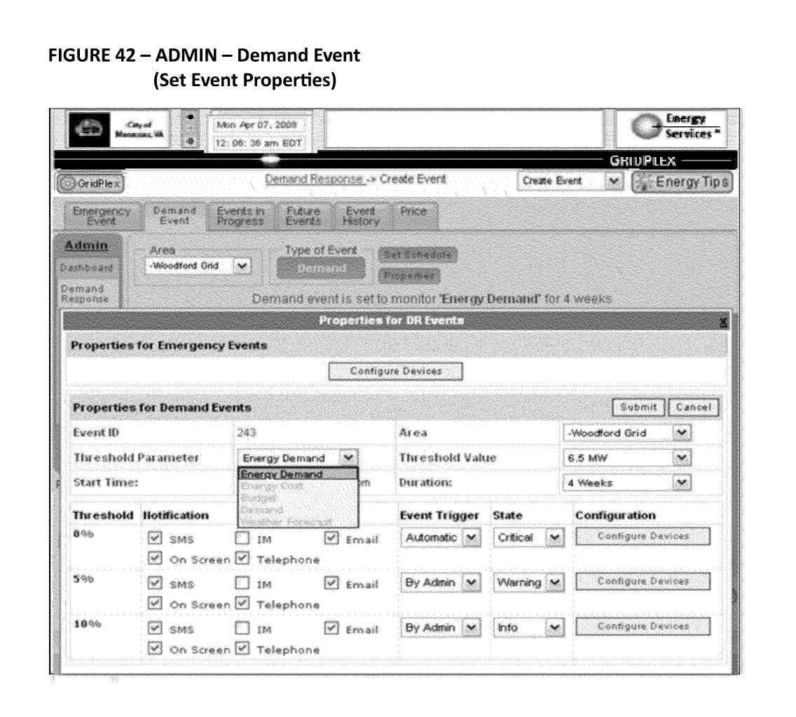

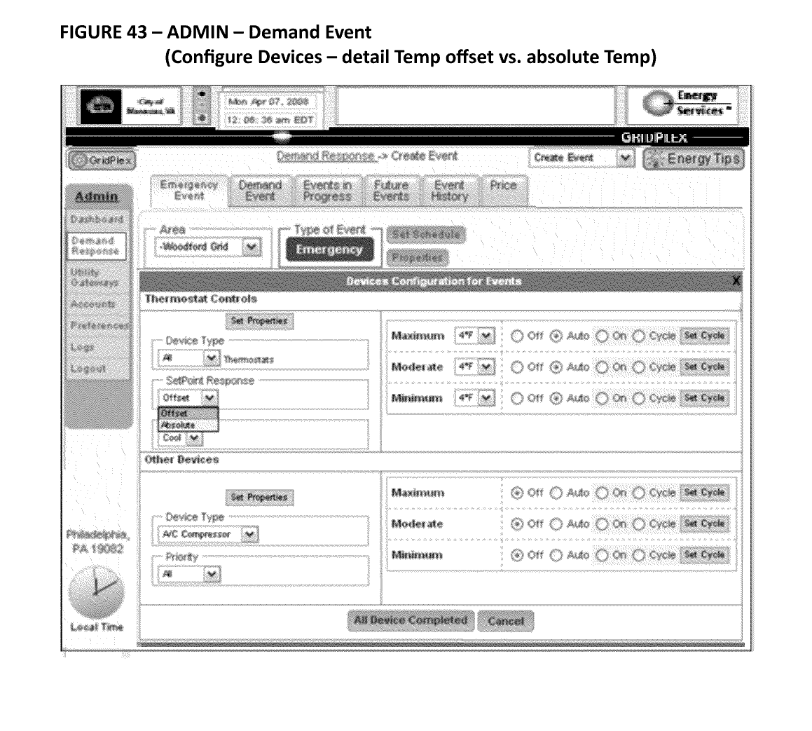

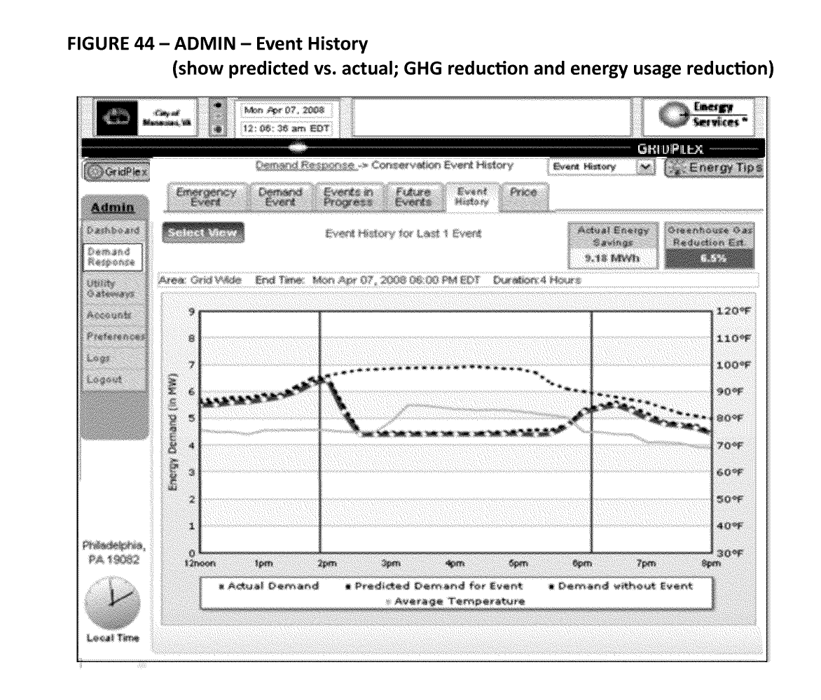

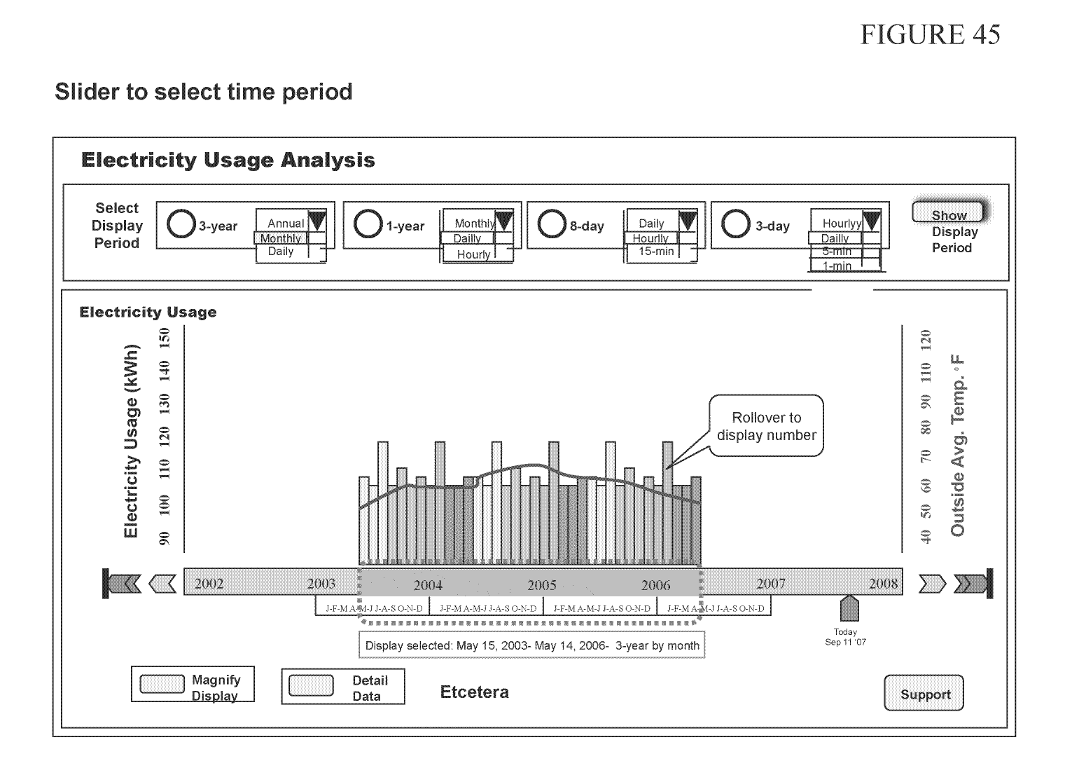

A Demand Response web page 1902 is shown in FIG. 19. This enables the Program Operator to create a Conservation Event (also known in the electric utility industry as a Demand Response Event if it concerned with a request by the electric utility for end-users to reduce their demand for electricity) when and where desired. The Program Operator may select an Area where the Conservation Event will occur (which may be based on the Demand data), a group of Participants for whom the Conservation Event will apply, and can also set an applicable Event Level. For example, this page will inform the Program Operator how many Participants are set to Maximum Conservation Level, Moderate Conservation Level, and Minimum Conservation Level (as previously described with respect to the User Interface). Thus, if the Conservation Event is configured for the group of Maximum Conservation level Participants, then it will only apply to those users. The Program Operator may then enter the start date, time and duration of the Conservation Event. The Program Operator may also set the properties for the event as shown in FIG. 20, including the Threshold parameter, Area, Threshold Value, and duration. The Device Configuration parameters are shown in FIG. 21, that enable the Program Operator to set the desired thermostat controls, set point responses, and modes of operation. Also, the temperature offsets for thermostats (for example in an emergency or similar situation where the utility may be permitted to actually take control of the customers' equipment) are set in this window as shown.

Once the Conservation Event has been defined by the Program Operator, then it is saved and a set of Resource Parametric Signals are generated that are transmitted over the network to each Participant affected by the Conservation Event. The demand responses will then be executed at each Location as previously described.

Depending on the Demand Response policies in force in a particular area, the Utility/Resource Provider or Program Operator may have the ability to directly control devices in end-user Participant locations (particularly in an Emergency Event); however, in many cases of non-Emergency Demand Response (sometime called “Economic Events”, the control of end-user devices will be managed by the “Response” that the user has selected when there is a “Demand” (or threshold event) from the Resource Provider of Program Operator. These degrees and hierarchical levels of response and control may be determined in software according to the requirements of a given Resource Provider and Market.

Security Architecture

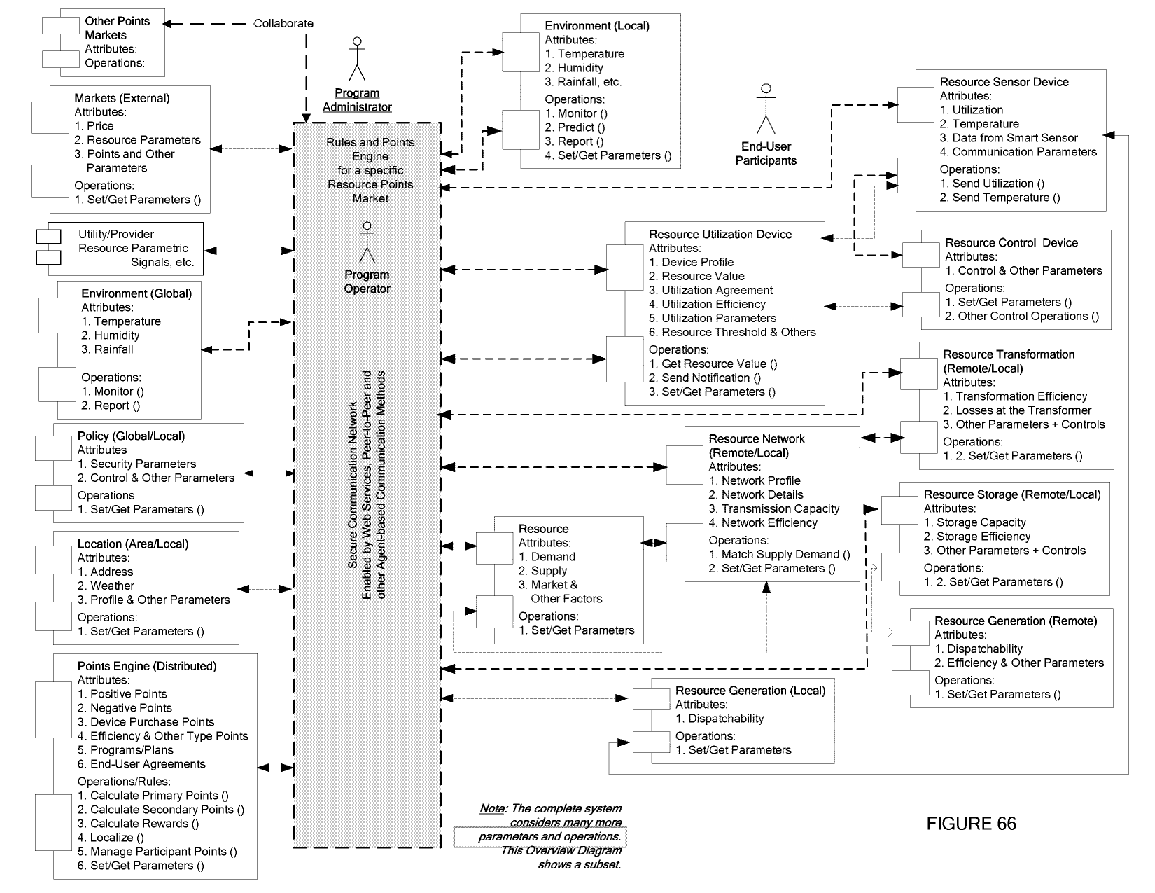

The Security Architecture to be implemented in the subject invention includes, but is not limited to, the following security features. These and other security features will be integrated into the communications and access functions for the software applications, as in one implementation described in FIG. 66 and in the demonstrative user-interface screens also depicted herein, as follows:

Basic authentication using Login/password (facility to hook in Federated Identity features to facilitate login from partners)—there may be hierarchy of access permissions for different individuals
Facility for Strong Authentication (two-factor, token-based—both hard or soft and biometric)
Facility for Authentication Protection (out-of-band passwords over SMS/mobile/phone)
Set authorization level based on USER TYPE—customer, administrator, operator, partner, and guest
Set authorization level based on ACCESS DEVICE (trusted, semi-trusted and public devices/remote networks or locations)
Use group functionality to simplify authorization and other policies for user groups
Use SSL/TLS/AES to encrypt session and data (in transport or on storage media), with variable key strength (256/1024 bits) and choice encryption algorithm, depending on the requirement
M2M (machine-to-machine) traffic, including wireless/PLC, is encrypted using special keys, and segregated using unique network/home ids
Use device identification with the help of a unique machine id, that helps in formulating additional authorization policies.

Application to other Resources—while the preceding example of Best Mode presented above applies to Electricity Resources, one familiar with the operation of the devices, systems and interactions described herein will readily see analogous application to other consumable resources, such as water, natural gas, oil, secure access and the like, using similar techniques to create a Resource Points Program specific to that resource.

Transitional Intelligent Metering (“xIP Meter”) Platform

FIGS. 46-50 refer to a utility meter platform with modular components (“xIP Meter Platform Modules”), providing enhanced metering functionality and multiple communication capabilities, and designed to accept multiple configurations of conductor blades and support inserts, compatible with a variety of legacy meter sockets. The platform design includes one or more stacked modules that plug-in electrically between the legacy meter socket and the reinstalled legacy meter. Each module contains openings designed to plug into the legacy socket on one side, and on the other side a similar set of openings to enable one of the following to be plugged into it: (a) another module in the series (which itself will have socket mounting capability on both side so that the xIP modules may be “stacked”), or (b) the legacy meter, or (c) a face panel (described below) may be plugged.

The module are designed in such a way that power is carried from one module to the next, along with a data/information bus.

The modules are configured so that a module may contain one or more of the following functions, installed in the form of standardized plug-in cards or a similar standardized construction, including:
(1) metrology (meter functionality, according to ANSI standards defined for such functions (also defined as a resource utilization sensor in the context of the present invention);
(2) power quality functions, including monitoring of voltage, frequency, power factor, outage (lack of power), and other functions related to the supply of the resource (in this case electricity);
(3) control and automation, including scheduling, timers, connect/disconnect, load control (partial disconnect or load limiting)
(4) communications of various sorts, including wired and wireless (RFI Powerline, etc.) to communicate to one or more of the following: (a) to a data concentrator located remotely and connected to a wide area network, either on the supply side of the meter or on the demand (user) side of the meter, (b) directly from the meter to a wide area network connection, (c) to devices located inside the user's facility (demand side), either through direct point-to-point communications or through a mesh using transceivers and routing configuration software, (d) to other resource utilization devices as defined in the present invention, (e) sensors and transceivers located remotely from the meter.
(5) Sensors for conditions inside the meter, such as temperature, humidity, tamper detection, etc.
(6) Other cards to provide additional services, such a broadband services delivered into the facility.

The conductors of the first module are electrically connected to the conductors of the second module, and so on throughout the “stack”, to transport power and data.

The legacy meter may also have a communications module installed in it as a retrofit so that readings between the legacy meter and the xIP meter modules may be periodically compared;

Process for Migration from Legacy Meter to Enhanced Intelligent xIP Meter

1. Transitional migration from a legacy utility meter to the enhanced intelligent xIP meter platform include the steps of:
(a) removing the legacy meter from the existing legacy meter socket;
(b) after step (a), installing an xIP Meter Platform module that includes the enhanced utility meter platform in the legacy meter socket by the xIP Meter module into the legacy meter socket; wherein the xIP Meter module has a front side with a second meter socket that includes a second group of openings that have substantially the same spacing and orientation as in the legacy meter socket; and where the conductors in these openings are electrically connected to conductors in the xIP Meter module;
(c) after step (b), installing the legacy meter in the second meter socket on the front of the xIP Meter module by inserting the legacy meter into the openings in the front of the xIP Meter module (alternative, another xIP Meter module #2 containing other circuits for additional functions may be plugged into the front socket, and then the legacy meter plugged into the front of xIP Meter module #2, and so on);
(d) for a period of time after step (c), metering a load associated with the legacy socket using the legacy meter and separately metering the load with the enhanced utility meter platform, where the reading of the legacy meter may be compared to that of the xIP Meter module containing the metrology function, either via an electronic data link by a manual read and comparison; and
(e) after the period of time, removing the legacy meter from the front-most meter socket on the xIP Meter “stack” and inserting a cover in the second meter socket, which cover contains an electrical conductor that will complete the electrical circuit, and, in addition, ay contain a numerical readout, optical port and/or other such features as may be required by the applicable meter standard (such as ANSI) or other requirement, so that the transitional intelligent meter module(s) become a fully-functional, stand-alone intelligent meter, in among it other functions, that has regulatory approval to be used for revenue purposes.

Delivery of Meter Data for Use by Other Systems

1. The xIP Meter platform is adapted to provide metering data to an external system using a plurality of different protocols, and transported over a variety of different communications media (wired and wireless) accomplished by the installation of plug-in communications cards into the various xIP Meter modules (as described in the 2COMM/3COMM specifications in the present invention). comprising:
The communications card(s) in the xIP module receives metering data, formats the metering data for transmission using one of the protocols and communications media supported by the communications card (which may be located in that xIP module or in another xIP module), and transmits the formatted metering data to an external system in accordance with the protocol and media used for formatting. The data may also be encrypted during this process, and subject to authentication to access different types and levels of data from an external system.

Audio or Visual Alarm Generator in xIP Meter Modules
An xIP Meter module may also contain an alarm component with an audio generator (or a flashing LED or similar indicator) that generates an alarm upon detection of one or more triggering events, and/or in response to receipt of a signal from the metrology or a sensor monitoring component, and/or from an external source via a signal received by a communications card installed in an xIP module;

Meter Heartbeat Function

The xIP Meter platform will periodically and repetitively determine whether the meter platform is receiving power, is operating properly, and is accessible over the network. This may be accomplished when a communication component receives periodic echo request signals from a host coupled to the xIP utility meter platform over the network, and transmits echo response signals to the host over that or another network. An xIP module will contain a processor, coupled to the metering component and the communication component, that instructs the communication component to send an echo response signal to the host over the network in response to receipt of an echo request signal at the utility metering platform. If the meter is not receiving power from the utility system, it may rely on a battery or charged capacitor to operate and send a “distress signal”.

Event Bracketing

The xIP Meter is designed to respond to external signals that request a response by providing demand reduction or energy conservation. The interaction of the signal and response is termed a “response event”. When a request signal for such a response is received, provided that permission has been provided to the system for such response (by the utility and/or by the participant), immediately prior to implementation of the response event, the xIP will take a time-stamped “snapshot” of the various readings and condition of the operating parameters of the system. Then, immediately after the implementation of the event, another time-stamped “snapshot” is taken of the system parameters. This is known as “bracketing” the event. These event snapshots may be periodically repeated, to verify compliance with the requested action throughout a given time period. The time-stamped readings will be stored in memory in one of the xIP Meter modules and also transmitted over the network to the utility and/or to the user. This verification may be used for the computation of points to be issued in the Conservation Incentive Points program that is the subject of this application.

Environmental Sensors in the xIP Meter Module(s)

One or more modules within the xIP Meter platform may contain sensors, or communications transceivers that receive and/or transmit signals from local and/or remote sensors that are used for monitor environmental and/or other parameters (such as temperature, humidity, air quality, barometric pressure, particulates, gases, vibration, temperature of the interior of the xIP meter enclosure, etc.).

Automotive Interface in Meter

The xIP Meter platform may contain a module that separately tracks resource utilization associated with a plug-in hybrid vehicle, which may be applied to consumption during recharging, or generation through operation or discharging or power, used locally or dispatched into the electric grid.

Electricity Tags

Additionally, the power may be imprinted with a “source tag” by being distorted by the addition of a powerline signal that will travel with the power, in order to distinguish its source. Such a “source tag” may be used in the computation of resource points to be awarded under the present invention, or for other purposes, enabling the xIP Meter platform to distinguish one source of power from another.

The xIP Meter module may thus contain an automotive interface component that generates an identification signal and may even control when the plug-in hybrid vehicle is recharging or charging into the grid, and a memory component, responsive to the signal, that stores the resource utilization data associated with the operation of the plug-in hybrid vehicle separate from utilization data associated other devices monitored by the xIP metering component.

Fully Self-Contained xIP Meter to Replace the Legacy Meter

The xIP Meter may also be manufactured complete with a face plate containing the required read-out elements, so that it is a one-piece fully self-contained intelligent meter that completely replace the legacy meter. In this case, the legacy meter is removed from the legacy meter socket and the fully self-contained xIP Meter installed in its place.

Thus, FIGS. 46-50 relate to a modular electric meter and intelligent metering platform (“xIP Meter”™) that utilizes the GridPlex UNI-Plex™ embedded automation computing architecture. The xIP meter platform is able to supply interval data about a range of parameters, to accumulate and communicate that data in real-time (or near real-time) to the utility and to its end-use customers, and to enable automated control of the devices and networks both locally and remotely.

The UNI-PLEX xIP Intelligent Meter Platform consists of a series of modular meter, communications and automation control building blocks that can be used in conjunction with, or to replace, an existing utility revenue meter.

The initial version is designed for small to medium commercial, residential and submetering applications. However, the same concept can be applied to larger industrial and commercial meters in various packages for mounting and deployment across the grid.

A Utility has three groups that can operate more effectively with access to on-demand meter data about usage other conditions at end-points of the network:

the operations engineering group, that can use the data to operate the grid to better meet efficiency and reliability imperatives;
the supply and trading group, that can use the data to produce, buy and/or sell the commodity more effectively; and
the revenue group, that can use the data for rate-case filings, and ultimately, for billing purposes. The revenue group often refers to the meter as the utility's “cash register”.

Access to real-time (or near real-time) meter data is important to each of these three groups. However, concerns by public utility commissions and other regulators that variable pricing might adversely and unfairly affect consumers through exposure to the volatility of wholesale markets, regulatory approval of time-of-use billing for residential customers has been extremely slow, which, in turn, has slowed deployment of interval, communicating “intelligent” meters to replace existing conventional meters. As a result, total penetration of communicating interval meters today among electric utilities as a whole is little more than 20%.

The present design seeks to provide an immediately-deployable solution that meets the needs of the first two groups while avoiding the regulatory delays inherent with respect to the third, until such time as regulatory approval is secured to use the intelligent meter for billing purposes. At that point, a low-cost upgrade plug-in LCD front panel enables the GPX xIP unit to be quickly and easily converted into a revenue meter.

The GPX xIP device provides all of the data measurements available from other modern electronic meters, with the addition of several other functions that add value to the system. Data will be collected and stored, accurately time-stamped, and delivered to utility servers for access by each of the three groups as needed.

Impact Analysis

The UNI-PLEX xIP meter design is intended to:

enable immediate deployment of the platform to improve grid management and reliability by supplying needed data to utility operations and supply groups
enable cost to be written into rate-base while avoiding the necessity to replace and write-off existing legacy meters and preserving existing utility meter-reading and billing procedures (and staff) pending rate filings and approvals
provide verification data to confirm accuracy of new system vs. existing meters
provide an open-platform with a choice of AMR communications and future upgrade capabilities available from many manufacturers
provide future software and configuration upgrades over the network
provide platform for Utility Applications that interfaces with utility Grid Management and SCADA systems
enable demand-side services including meter data management, customer communications and demand response
provide an easy and inexpensive plug-in to convert xIP to a revenue meter after regulatory approval
provide platform for future value-added services to communities and end-use customers standardized and published hardware and software interface specifications (APIs)
including physical requirements, electrical, data and communications interfaces, protocol, etc. to accommodate components and applications from other manufacturers dedicated I/O for use with external sensors

Related Systems and Accessories (Some Examples)

The current xIP meter system incorporates modules from related systems that are described in separate Requirements Specification documents as follows:
C2k2 Automation Computer Core module—provides core automation functionality, including data logging, protocol translation, web-server and other C2k2 monitoring and control functions
   2COMM Communications modules—provides WAN and LAN communications incorporating RF, PLC and other communications and data transport media, and provides protocol support for various devices and sensors
   PIP Remote Display module—Provides portal extension for meter data and related information, and Includes remote pushbuttons to interface with system over RF/PLC link
   TSC Thermostat Control module—provides sensor and control interface for HVAC control
   LCT Load Control module—Load control for analog and digital control of loads

Multiple Packaging configurations (Some Examples)

Plug-in socket-mount—light-duty package with plastic housing—armored version in hardened package—extreme environment package
Integral unit with attached faceplate (no legacy meter)—Round unit—Square package (IEC and submeter)
Pole-mount (hi-medium-voltage unit)
Wallmount (interior)

Design Philosophy
Configurable Intelligent Meter Platform leverages modules and software of UNI-PLEX platform with set of published interface specifications (APIs) for hardware and software
Same communications and expansion cards used for xIP meter and C2k2 (see separate 2COMM series Requirements Specification RQS-006-003)
Back-end software treats Intelligent Meter as a standard “meter object” in IOCS schema with XML and WebServices interfaces enabling massive scalability
Complies with open standards and supports defined hardware and software interfaces to enable third parties to supply components that may be integrated into the xIP platform of hardware and software, and that can interoperate with the xIP meter components, and to access and communicate the information and control capabilities provided by the xIP devices.
   Data is fully encrypted and protected
“Distributed backplane” interconnection supports a variety of standardized communications modules that can be mixed and matched according to a utility's specific implementation requirements. Note that the “distributed backplane” in this case describes a series of boards and connectors tailored to fit within the xIP housing
   Supports legacy communications interconnects, protocols and utility meter-reading and billing procedures already in place, while providing on-demand data for other utility use
   Adapts to possible changes in future communications and other requirements via plug-in interface cards
   Can integrate optional plug-in C2k2 Core Module to provide automation, energy management and other monitoring and control functions (see separate C2k2 Requirements Specification RQS-006-002)

### Purpose

The goal of the UNI-PLEX series of products, and of the xIP meter in particular, is to provide a versatile and expandable embedded computing solution that addresses present and future information requirements of utilities. The xIP meter is designed to be flexible, adaptable, and able to interface with existing and future communications and automation technologies, with capabilities including (among others):
Remote meter reads and AMR (scheduled intervals and on-demand)
Power quality monitoring
Outage detection and alerts
Tamper alerts
Timer and scheduling functions
Measures and records local temperature at same intervals as meter data
Remote connect/disconnect—Load Limiting
Integration with other utility and end-user systems and equipment
Integration with external sensors
Metering for broadband access and VoIP services

Basic Requirements (Including but not Limited to):

Polyphase (1, 2 or 3-phase) meter, 200 amps per leg, with provision to add external current transformers (CTs) for larger capacities
US version compatible with currently used sockets and other mounting configurations
Basic meter function is provided on a single PC board (meter module), with provision to install a series of plug-in modules for two-way communications (local as well as wide-area), data management and automation functionality
Modular “stack” design enables future expansion and addition of new modules without opening of calibrated meter enclosure
Front face of xIP meter basic module contains socket connectors, so that the xIP meter can be installed as an interbase between the existing socket and the legacy meter. This design permits the existing the “legacy meter” to be removed from its socket, xIP meter installed, and “legacy meter” to be reinstalled on top of xIP meter, thus enabling staged utility deployments. Utility can continue to use legacy meter for billing purposes, while receiving data from xIP meter for system analysis and network management.
Simultaneous read capability supplies data logs confirming the accuracy of xIP meter vs. legacy meter, which may be useful for regulatory filings and other approvals. After approval of xIP meter is secured for billing use, or at whatever point the utility decides to do so, the legacy meter can be removed, and the xIP meter faceplate with LCD read-out installed and secured (see drawing).
Plug-in slots are available for both local (LAN) and wide-area (WAN) communications.
At least one slot is designed to include PLC communications, and is therefore interfaced with the powerline; the other is for purely RF communications. The standard module that goes into the PLC slot may also contain RF capability. All communications modules should conform to the GPX 2COMM specification (see separate document RQS-006-003). Support for communications media described in Section 12.
Remote connect/disconnect module with safety mechanism—Enable prepaid capability without card
Real time clock—All data time-stamped—Time signal available to other systems
Supports both Network and Standard Residential meter configurations
15-year minimum life
Supports TOU with downloadable rate tables
Supports real-time transactions and active trading between provider and end-user
Capable of Net Metering for use with Distributed Generation
carries both Bar Code Labels and RFID Tag—corresponds to embedded meter ID enables utility applications such as Demand Response and AMR
long-range antenna option for use with automotive telemetry

Proprietary Features

Modular design based upon configurable, componentized building blocks
Support of legacy meter—plugs into legacy meter sockets and enables the continued use of the legacy meter
read of legacy meter triggers simultaneous read of xIP meter for comparative analysis (“true-up”)—either manual or electronic
Reduced time to market by leveraging existing meter certifications and regulatory approvals
Provides outage detection and notification overlay to legacy system
Provides local reliability function by monitoring line frequency and responding locally and immediately to anomalies
Full automation capability using optional C2k2 providing both local access and control as well as secure remote access
Provides a range of communications paths, with automatic failover and emergency messaging
Software and configuration upgradeable over the network
remotely-downloadable software configuration for schedules, rate tables and other parameters
Interchangeable communications interfaces with standard and published card and connection specifications, electrical interface and software protocol and communications APIs
Provides multiple communications options for both LAN and WAN connections with fail-over back-up and simultaneous/gated operation
Provides real-time or near real-time data collection, alerts, and connect/disconnect control
Automation function through easily-integrated C2k2 Core module (optional) with protocol transport
Integrated with GPX IOCS hback-end Web Services interfaces and Energy eServices Portals through standardized and secure communications protocols
abstracts meter data for use by other systems
Security and encryption detailed in separate RQS
Fully expandable and adaptable with standard, published APIs for hardware and software and multiple protocol support
Standard form-factor and connectors for third-part add-ons and interfaces
Include audio in meter generator for alarms etc.
Supports “pinging” the meter over the network at regular intervals or on demand, as well as meter “heartbeat” functions
Functions include “event bracketing” to measure response to events such as a demand response request
May use existing meter circuit boards (Echelon, Kaifa, Sensus, Elster, Landis+Gyr, Eaton, etc.) and C2k2 as plug-ins, with additional computer resources in outboard enclosure if required
Remote connect/disconnect module as provided by Ekstrom or Greuner
C2k2 next generation board designed to fit into a tubular xIP meter enclosure Multiple communications media with automatic fail-over and mesh backup for reliability
Support for sensors such as temperature, air quality, particulates, vibration, etc.
Dedicated sensor interfaces
automotive telemetry and service data
environmental and other sensors
Pole-mounting configuration for monitoring characteristics of transformers and other equipment on the grid (theft of service, reliability, outage management, etc.)—non-socketed enclosure with mounting bracket designed for pole-mount and medium-voltage environment
Automotive interface with ability to separately monitor (and bill) electric vehicle recharging

Input/Out Interfaces—Provided by 2COMM Modules (Some Examples)

Local (LAN) and Wide area network (WAN) as described in 2COM specifications

### Ethernet—10/100 (RJ-45)

### Discrete

Analog I/O with CT support

### Digital I/O

### Relay (N/O-N/C)

### Serial

### USB

### RS-485

### RS-232

### RF

Z-Wave mesh radio (nominal 900 MHz—US and Europe)

### 802.15.4—Zigbee

Telemetry band (nominal 400 MHz—US and Europe) RF
Pager (1-way and 2-way)
ITRON ERT and other manufacturers RF systems (fixed and mobile)
Other software-controlled radios
“Read detector” for drive-by, fixed network and handheld reads

### Power Line Communications

### Echelon PLC—EIA 709.2

### ST Microelectronics PLC

### TWACS PLC

Broadband over Power Line (BPL)
Intellon chipset-based
DS2 chipset-based
Telephone communications
dial-up modem

### Cellular or Cellemetry

### GSM

### Satellite

Optical—ANSI-standard meter provisioning optical interface may also used to provide authentication for local service personnel.

Displays (Some Examples)

Basic xIP meter main unit

### Status/Diagnostic LEDs

Small LCD on side
Add-on front panel with large LCD display to meet revenue meter user-interface requirements (“UIM Module”)
UIM contains contacts to complete circuit in retrofit with Legacy meter and also safety interlock when changing COMM modules etc.

Mechanical Accessories (Some Examples)

Mounting brackets:
Pole-mounting brackets

### For use as Sub-meter

Socket-less back with terminals for use as A-base adapter or direct-wire submeter enclosures—multiple meter boards in a wall-mounting enclosure for MDU and similar uses

Protocols (Some Examples)

### ANSI Meter (US)

### DNP3 (US)

### ModBus (US)

### BACnet (US)

### M-Bus (Europe)

In the preceding specification, the present invention has been described with reference to specific exemplary embodiments thereof. It will, however, be evident that various modifications and changes may be made thereunto without departing from the broader spirit and scope of the present invention as set forth in the claims that follow. The specification and drawings are accordingly to be regarded in an illustrative rather than restrictive sense.

Sensors (Some Examples)

### Temperature

### Humidity

Wind speed and direction
Short circuits (ozone)
Electric Meters with rapid sampling

### Cameras

Waveform analyzers

What is claimed is:

1. A system to continuously monitor and control transformers located in an electrical distribution system and related conditions that will operate even in the event of power failure on the electric grid, consisting of:
a. one or more sensors (that will measure selected parameters at the transformer, including temperature, voltage, current, frequency waveforms, power quality measurements, RF emissions, as well as environmental conditions in the vicinity of the transformer
b. Communications modules that will receive and transmit data from the sensors to a computer
c. Algorithms within the computer that will analyze the data from the sensors to determine and store data concerning:
i. the operating health and efficiency of the transformer measuring sags, transients, momentary or sustained outages, and other anomalies
ii. the amount of electricity being delivered by the transformer
iii. the amount of electricity being delivered by the transformer compared with the total amount of electricity consumption measured by electric meters connected to the transformer to detect losses or theft
iv. anomalous waveforms and other exceptional conditions that may be observed by the sensors that may indicate potential threats from tampering, malicious software inserted into the power system or other threats
v. records of past threats and anomalies for analysis and to enable the system to issue proactive instructions to address new threats detected,

2. A communications system that will automatically receive and transmit data describing conditions detected by the sensors in the sensor network, including emergency conditions assessed in real-time
a. The system in claim 2 where the Communications system is uninterruptible and will operate even in the event of power failure on the electric grid by the inclusion of a rechargeable continuous power source, consisting of an energy storage device such as a battery or super-capacitor, which can recharge by drawing power from the electric grid, or in the event of power failure on the electric grid, from a renewable power source such as solar PV, small wind turbine, fuel cell or similar device. An electronic control disconnects the system from connection to the grid for safety purposes, but is configured to enable the system of claim 2 to continue to operate, so that failure conditions and existing conditions at and around the device will continue to be transmitted to service personnel and first responders that will enable them to assess the reason for failure, tools required, and other equipment to enhance safety by enabling them to prepare for conditions they will encounter onsite.

3. A device that measures parameters associated with a transformer on the power grid, including but not limited to temperature, emitted gases, frequency, voltage, current, phase shift and other power quality parameters, and other internal and external conditions affecting the transformer in order to control the output of electricity from the electric grid, input of locally generated power to the electric grid, and other controllable conditions, and to preserve stability in the electric grid
a. The system of claim 3 where the measurement of some of the electrical parameters is made by sampling the power line at rapid intervals in order to detect and record anomalies that may be linked to malicious software that can attack operation of the power system, specific devices or users connected thereto;
b. The system of claim 3 including a device that will measure the temperature of the transformer to maintain an adequate “cool-down cycle” by providing a signal that can be used to instruct electric vehicle chargers and other major loads not to turn-on and draw power through the transformer until adequate cooling has been achieved. A computer may “stagger” or schedule the activation of these loads at separate intervals in order to not overload the transformer.
c. The system of claim 3 where a formula is applied to certain parameters in order to calculate a quantity of “incentive points” to be awarded to users connected to that distribution transformer
